(19) United States
(12) Patent Application Publication
(10) Pub. No.: US 2023/0132149 A1
(43) Pub. Date: Apr. 27, 2023

(54) ULTRA NARROW BANDGAP NON-FULLERENE-ACCEPTOR BASED ORGANIC ELECTRONICS

(71) Applicant: The Regents of the University of California, Oakland, CA (US)

(72) Inventors: Guillermo C. Bazan, Santa Barbara, CA (US); Seyeong Song, Santa Barbara, CA (US); Ziyue Zhu, Goleta, CA (US); Hengbin Wang, Santa Barbara, CA (US)

(73) Assignee: The Regents of the University of California, Oakland, CA (US)

(21) Appl. No.: 17/870,628

(22) Filed: Jul. 21, 2022

Related U.S. Application Data
(60) Provisional application No. 63/224,097, filed on Jul. 21, 2021.

(51) Int. Cl. H10K 10/46; H10K 85/60; H10K 85/10

(52) U.S. Cl. CPC H01L 51/0566; H01L 51/0071; H01L 51/0064; H01L 51/0068; H01L 51/0074; H01L 51/0036

(57) ABSTRACT

Ultra-narrow bandgap Non Fullerene Acceptors (NFAs) comprising an A-D-A′-D-A structure or an A-D-A′-D′-A′-D-A structure were designed, synthesized, and characterized (where A, A′ are organic acceptor moieties and D and D′ are organic donor moieties). Exemplary NFA materials have narrow bandgap (0.86 eV-0.99 eV). Photovoltaic devices and Near Infrared photodetector devices based on these compositions above were synthesized with controlled amounts of solvents and additives. A photodetector having a specific detectivity of 2.41×10¹² Jones (D*) at a wavelength of 1040 nm was achieved.

### CROSS-REFERENCE TO RELATED APPLICATIONS

This application claims the benefit under 35 U.S.C. Section 119(e) of co-pending and commonly assigned U.S. Provisional Application Ser. No. 63/224,097, filed on Jul. 21, 2021, by Guillermo Bazan, Seyeong Song, Ziyue Zhu, and Hengbin Wang, entitled “ULTRA NARROW BANDGAP NON-FULLERENE ACCEPTOR-BASED ORGANIC ELECTRONICS,” attorneys' docket number G&C 30794.0801USP1 (UC 2021-876-1), which application is incorporated by reference herein.

### BACKGROUND OF THE INVENTION

### 1. Field of the Invention

The present disclosure relates to organic compositions useful for absorbing electromagnetic radiation and devices (e.g., photodetectors and solar cells) comprising the same.

### 2. Description of the Related Art

The active materials in organic optoelectronic devices have been rapidly developed so as to achieve high performance in combination with high-transmittance for next-generation integrated applications.^{[1-4]} In particular, non-fullerene acceptors (NFAs) absorbing at near infrared (NIR) wavelengths have recently received considerable attention due to their potential application in thin-film-transistors, solar cells and sensors. Furthermore, the range of light absorption is selectable by tuning the bandgap of materials.^{[5-7]} Applications of transparent light sensors include the Internet-of-Things (IoT) generation for vehicle windows, building smart exteriors, and E-Skin health devices.^{[8-9]}

However, commercial applications require extension of the spectrum of NIR absorbing materials. Further research is needed to extend the benefits of non-fullerene solar cells, in terms of superior optoelectronic properties, over fullerene-based devices so as to realize more efficient NIR organic photodetectors and solar cells. The present disclosure satisfies this need.

### SUMMARY OF THE INVENTION

Illustrative embodiments of the inventive subject matter according to embodiments of the present invention include, but are not limited to, the following examples.
1. A composition of matter useful as an electron acceptor, comprising:
   an organic semiconducting compound having an A-D-A′-D-A structure or an A-D-A′-D′-A′-D-A structure, wherein:
   D is a first electron donor moiety;
   D′ is a second electron donor moiety;
   A is a first electron acceptor moiety; and
   A′ is a second electron acceptor moiety.
2. The composition of matter of example 1, wherein the organic semiconducting compound has the structure:

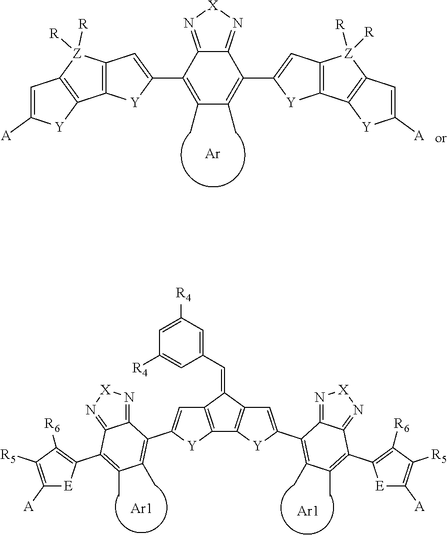

Ar or Ar1 comprise an aromatic functional group or hydrogen,
X is oxygen (O), Sulfur (S), Selenium (Se) or N—R₁ (where N is nitrogen);
Y is O, S, Se, or N—R₂; Z is C, Si, Ge, N or P; E is O, S, Se, or N—R₃; and
each R, R₁, R₂, R₃, R₄, R₅, and R₆ is independently hydrogen or a substituted or non-substituted alkyl, aryl or alkoxy chain.
3. The composition of matter of example 1, wherein the organic semiconducting compound comprises the structure:

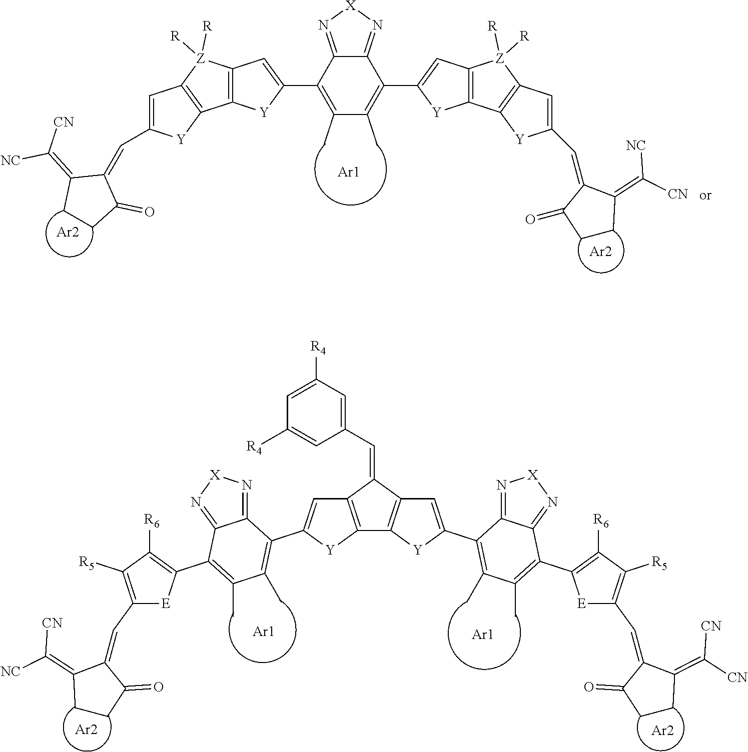

wherein X is O, S, Se or N—R₁, Y is O, S; Z is Carbon (C), silicon (Si), germanium (Ge), N; E is O, S; each R, R₁, R₄, R₅ and R₆ is independently hydrogen or a substituted or non-substituted alkyl, aryl or alkoxy chain; and each Ar1 and Ar2 is independently a substituted or non-substituted aromatic functional group comprising an electron withdrawing aromatic functional group.
4. The composition of matter of example 3, wherein each Ar2 is independently one of the following:

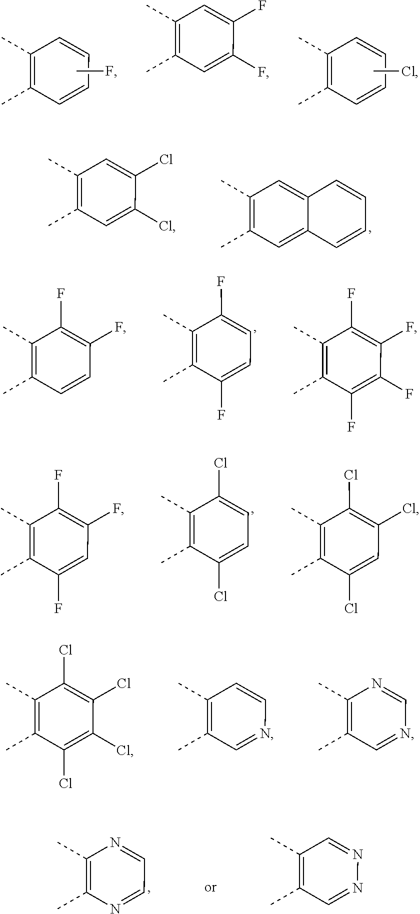

5. The composition of matter of example 1, having the A-D-A′-D′-A′-D-A structure wherein:
   A′ is:

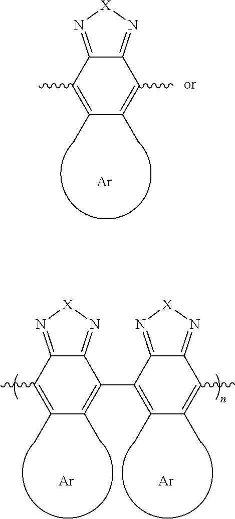

D′ is:

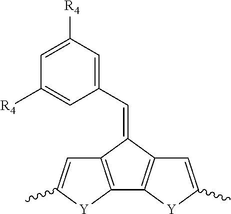

Ar is one of the following:

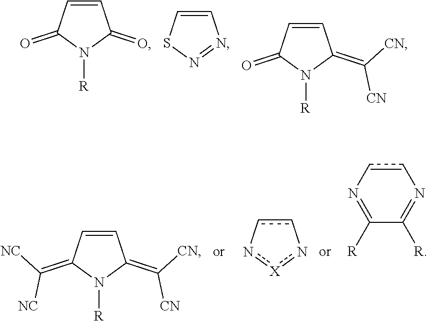

D is independently one of the following:

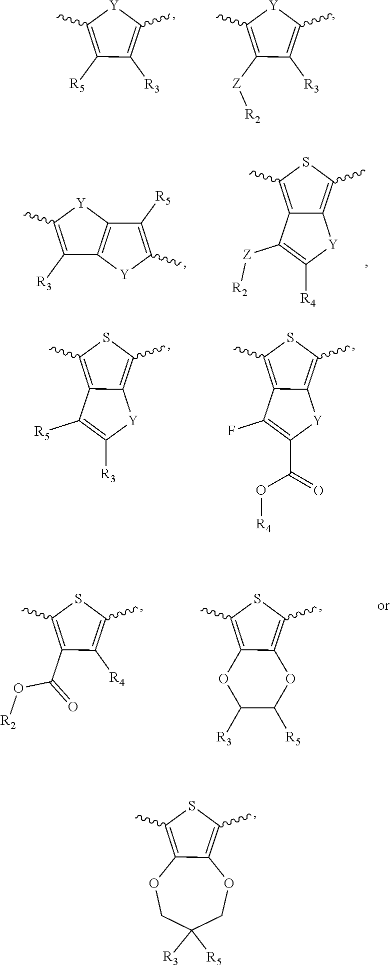

where each R, R₂, R₃, R₄, R₅ is independently hydrogen or a substituted or non-substituted alkyl, aryl or alkoxy chain.
6. The composition of matter of example 1, wherein the organic semiconducting compound has the structure:

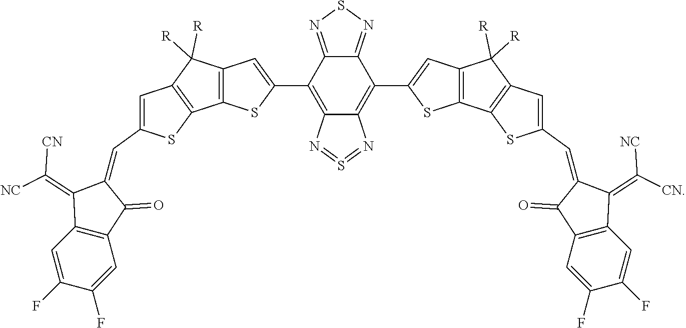

wherein each R is independently hydrogen or a substituted or non-substituted alkyl, aryl or alkoxy chain.
7. The composition of matter of example 1, wherein the organic semiconducting compound has the structure:

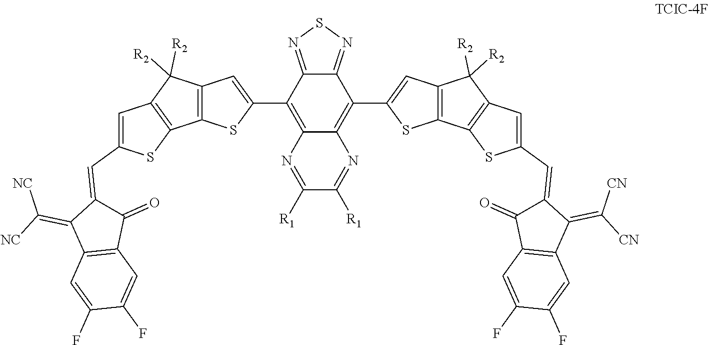

wherein each R₁ and R₂ is independently hydrogen or a substituted or non-substituted alkyl, aryl or alkoxy chain.
8. The composition of matter of example 1, wherein the organic semiconducting compound is:

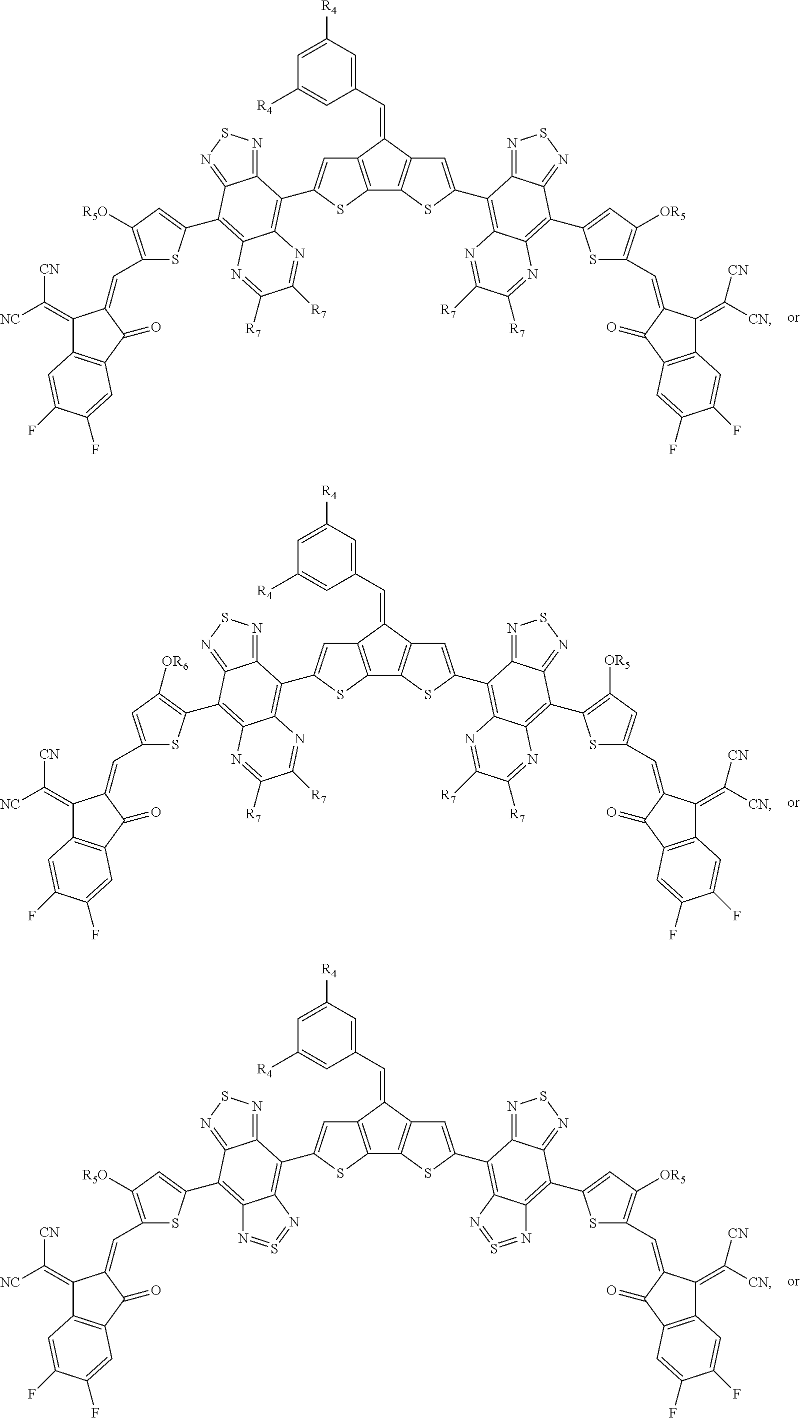

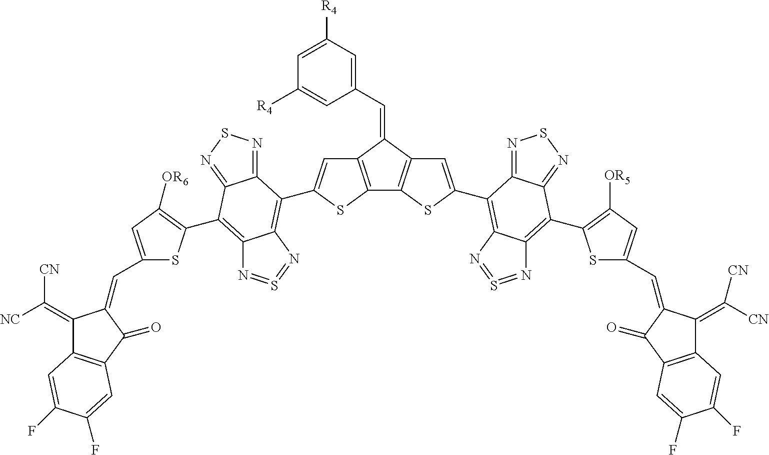

where each R₄ and R₇ is independently hydrogen or a substituted or non-substituted alkyl, aryl or alkoxy chain; and each R₅ and R₆ is independently hydrogen or a substituted or non-substituted alkyl or aryl chain.
9. The composition of matter of example 1, further comprising an organic semiconducting donor combined with the electron acceptor.
10. The composition of matter of example 9, wherein the organic semiconducting donor comprises:
   a semiconducting compound of the structure (and isomers thereof):

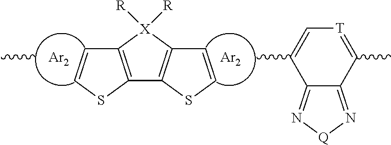

wherein:

each Ar₂ is independently a substituted or non-substituted aromatic functional group, or Ar₂ is nothing and the valence of the ring is completed with hydrogen;

each Q is independently O, S Se, or N—R₄;

each R and R₄ is independently hydrogen or a substituted or non-substituted alkyl, aryl, alkoxy or thioether chain;

T is N, C—F, or C—Cl, and

X is C, Si, Ge, N or P or

the semiconducting compound of the structure:

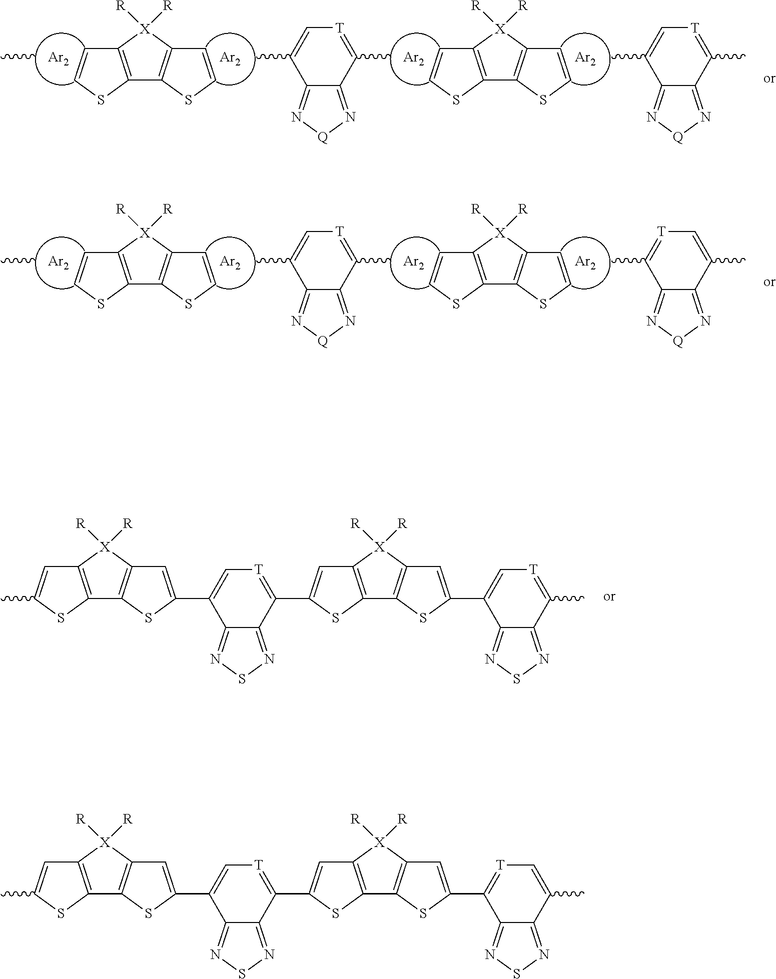

wherein:

each Ar₂ is independently a substituted or non-substituted aromatic functional group, or Ar₂ is nothing and the valence of the ring is completed with hydrogen;

each Q is independently O, S Se, or N—R₄;

each R and R₄ is independently hydrogen or a substituted or non-substituted alkyl, aryl, alkoxy or thioether chain;

T is N, C—F, or C—Cl; and

X is C, Si, Ge, N or phosphorus (P),

or the semiconducting compound of the structure:

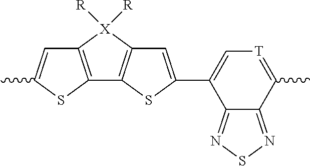

wherein:

each R is independently hydrogen or a substituted or non-substituted alkyl, aryl, alkoxy or thioether chain;

T is N, C—F, or C—Cl; and

X is C, Si, Ge, N or P,

or the organic semiconducting donor comprises the structure:

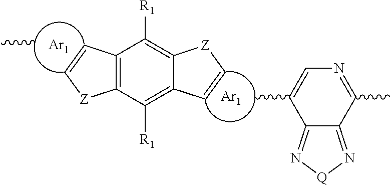

wherein:

each Ar₁ is independently a substituted or non-substituted aromatic functional group, or each Ar₁ is nothing and the valence of the ring is completed with hydrogen.

each Z is independently O, S, Se, or N—R₄;

each R₁, R₄ is independently hydrogen or a substituted or non-substituted alkyl, aryl, alkoxy or thioether chain; and

each Q is independently O, S Se, or N—R₄, or

the organic semiconducting donor comprises the structure:

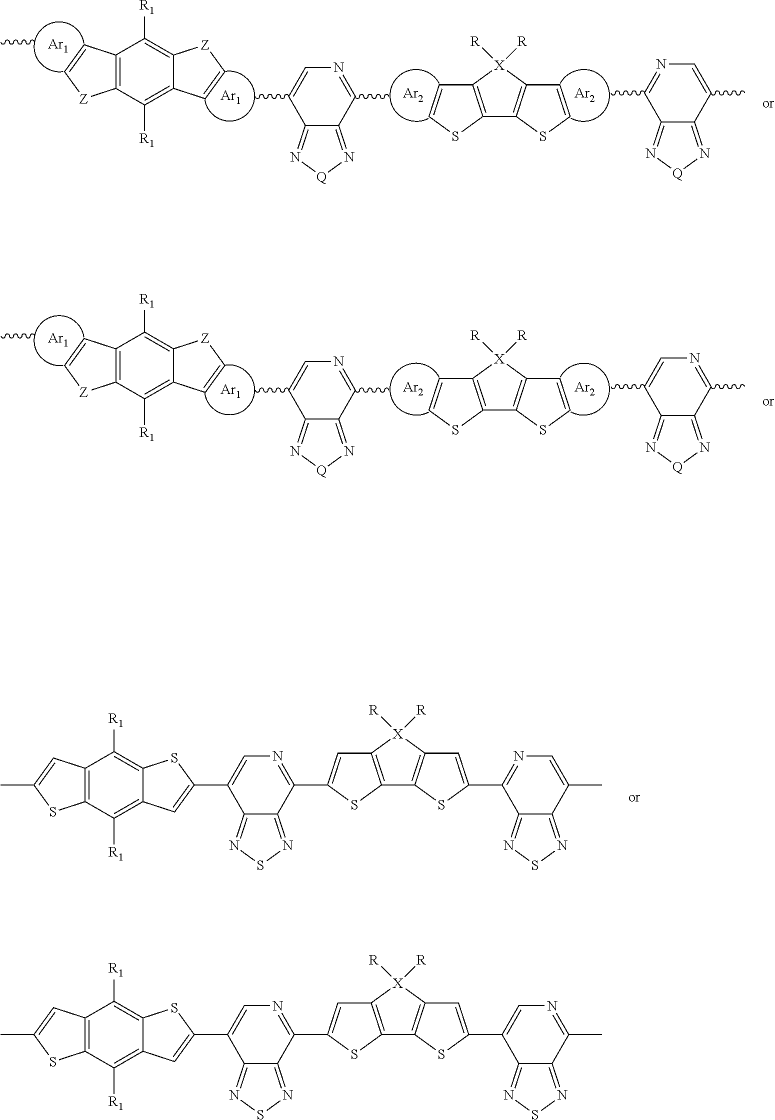

wherein:
each Ar₁ is independently a substituted or non-substituted aromatic functional group, or each Ar₁ is nothing and the valence of the ring is completed with hydrogen.

each Z is independently O, S, Se, or N—R₄;
each R₁, R₄ is independently hydrogen or a substituted or non-substituted alkyl, aryl, alkoxy or thioether chain; and

each Q is independently O, S Se, or N—R₄, and S is sulfur.
11. The composition of matter of example 10, wherein the electron acceptor has a bandgap less than or equal to the bandgap of the organic semiconducting donor.
12. The composition of matter of example 11, wherein the organic semiconducting donor comprises a semiconducting polymer.
13. The composition of matter of example 9, 11, or 12, wherein the organic semiconducting donor comprises a semiconducting polymer having the structure:

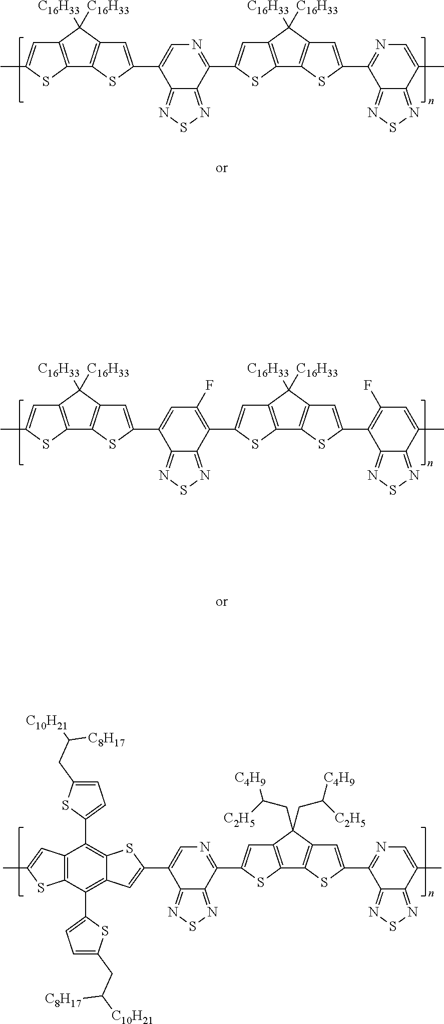

14. The composition of matter of example 9, wherein the organic semiconducting donor comprises:

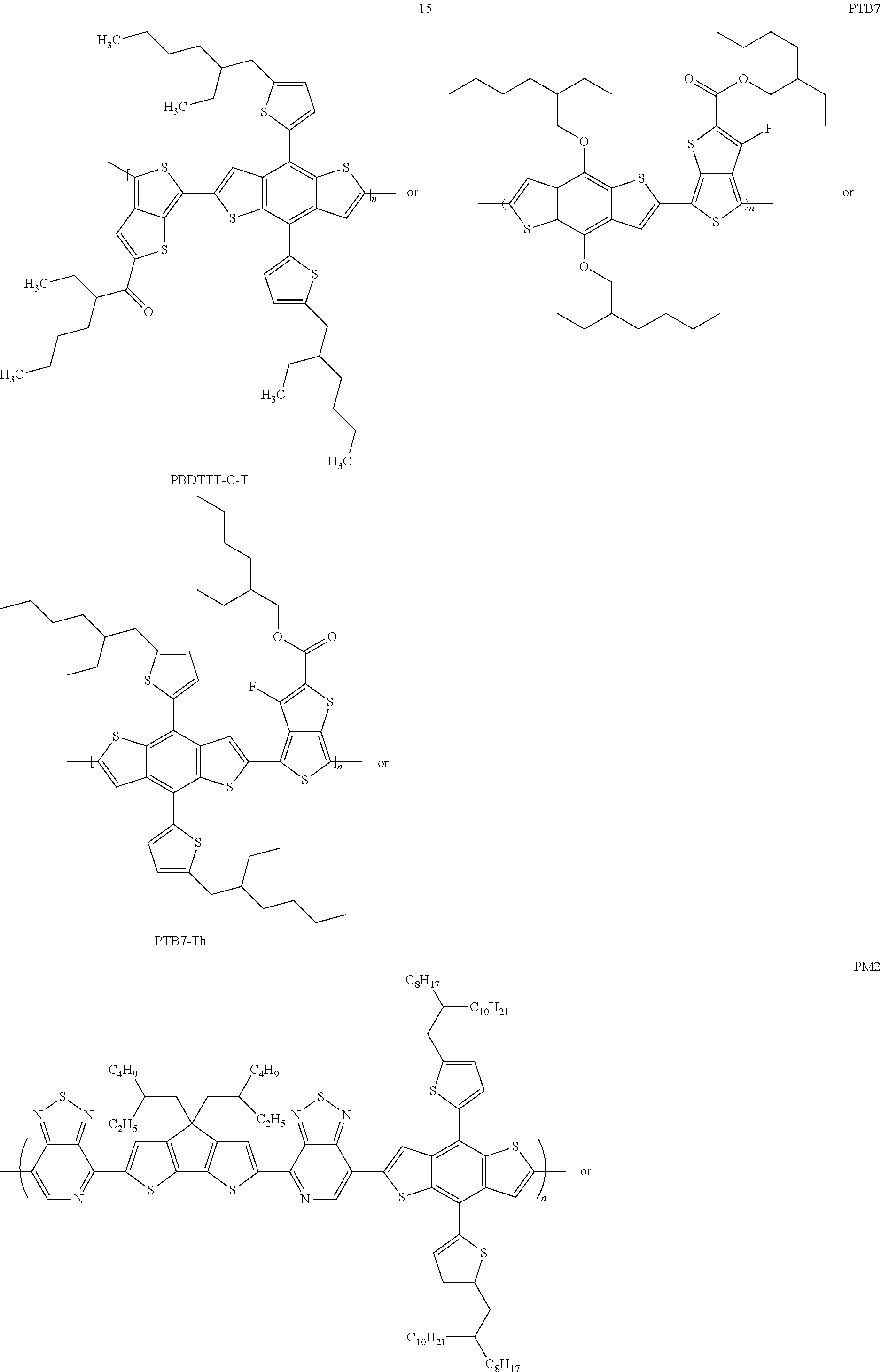

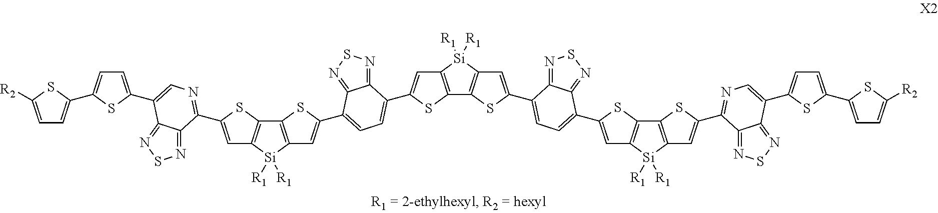

15. A film comprising the composition of matter of example 9, having an absorptivity of at least 0.7 across the entire wavelength range of 1000-1200 nm, the electron acceptor has a bandgap less than 1.0 eV and the donor compound has a bandgap less than 1.45 eV.
16. A device comprising a heterojunction between the electron acceptor and the organic semiconducting donor compound of example 9.
17. A photodetector or solar cell device comprising the composition of matter of example 9, further comprising:
an active region comprising the organic semiconducting donor and the electron acceptor, wherein electron hole pairs comprising holes and electrons are generated in the active region in response to electromagnetic radiation incident on the active region, the electrons are collected in the electron acceptor and are transmitted through to a cathode, and the holes are collected in the organic donor compound and transmitted through to an anode;
the cathode coupled to the acceptor to receive the electrons; and

the anode coupled to the donor to receive the holes; and such that

the device outputs current in response to the electromagnetic radiation.
18. The device of example 17, wherein:

the device comprises the photodetector having an external quantum efficiency (EQE) above 2%, a responsivity of at least 0.01 A/W, and a specific detectivity of at least 10¹¹ Jones across the entire wavelength range of 800-1200 nm of the electromagnetic radiation when the anode is biased at 0V with respect to the cathode.
19. The device of any of example 18, wherein the photodetector comprises an infrared photodetector, comprising:

a first electrode comprising the cathode;

a first carrier transport layer;

the active region comprising the composition of matter, wherein the first carrier transport layer is between the first electrode and the active region;

a second carrier transport layer, wherein the active region is between the first carrier transport layer and the second carrier transport layer; and

the second electrode comprising the anode on the second carrier transport layer.
20. An organic device, comprising:

an active region comprising the electron acceptor of example 1, wherein the active region outputs electrical current in response to absorbing electromagnetic radiation.

In one or more examples, the A-D-A′-D-A molecular structure of Non Fullerene Acceptor (NFA) has been tailored to achieve an enhanced intra-molecular charge transfer (ICT) effect resulting in an ultra-narrow bandgap of <1.0 eV useful for NIR absorber applications. In one or more examples, polymers including PM2, PTB7-Th and PBDTTT-C-T were chosen as the narrow bandgap donor material to combine with the NFAs. The NIR materials including PM2 donor and the NFAs exhibit NIR absorption (in a film) with narrow optical bandgaps of 1.41 eV (PM2), 0.86 eV (BCIC-4F), 0.99 eV (TCIC-4F) and 0.98 eV (TCIC-4Cl), respectively. Various compositions of donor:BCIC-4F and donor:TCIC-4X (X═F or Cl) were fabricated and characterized as NIR photon detecting devices. The resulting donor-acceptor blend consisting only of narrow bandgap materials is thereby characterized by a strong absorption of photons in the near infrared (NIR) region, resulting in an estimated value for specific detectivity of 1.6×10¹² Jones at 1050 nm (for the PM2:TCIC-4F based device).

### BRIEF DESCRIPTION OF THE DRAWINGS

Referring now to the drawings in which like reference numbers represent corresponding parts throughout:

FIG. 1A. Molecular design of A-D-A′-D-A non fullerene acceptor structures and some candidate A′ and A units, where the side chains were simplified to methyl or ethyl groups for DFT calculation. ICT effect can be modulated with A and A′.

FIG. 1B. Examples of narrow bandgap A-D-A′-D-A non-fullerene acceptors with various A′ units, and their HOMO/LUMO and bandgaps predicted by DFT calculation (E^{opt} is the experimental optical bandgap).

FIG. 1C. Synthetic pathway of BBT centered narrow bandgap non-fullerene acceptors led to fused BBT center units.

FIG. 1D and FIG. 1E. Synthetic route for BCIC-4F (FIG. 1D) and TCIC-4X (X═F or Cl) (FIG. 1E).

FIG. 1F. Various ultra-narrow bandgap NFA derivatives can be achieved by the synthesis starting from the important di-amine intermediate.

FIG. 1G. Optical properties of original non-fullerene acceptors (NFAs) ((i) BCIC-4F, (ii) TCIC 4F and (iii) TCIC-4Cl.

FIG. 2A Chemical structure of non-fullerene acceptors (NFAs) BCIC-4F, TCIC-4F and donor polymer PM2, for optoelectronic device architectures shown in FIG. 2B and wherein FIG. 2C shows the band diagram of the materials.

FIG. 2D. Example donor small molecule and polymers for use in combination with NFAs described herein.

FIG. 2E. Table 2. Example photovoltaic performance of devices based on PM2:NFAs measured under simulated 100 mW cm⁻² AM 1.5G illumination and photodetector performance estimated from dark current and external quantum efficiency (EQE).

FIGS. 3A-3E. Example device characterization: FIG. 3A shows J-V curve, FIG. 3B shows EQE spectra, FIG. 3C shows dark current, FIG. 3D shows responsivity and FIG. 3E shows specific detectivity.

FIG. 4. Table 4. Example device performance of solar cells based on BCIC-4F measured under simulated 100 mW cm⁻² AM 1.5G illumination and photodetector performance estimated from dark current and external quantum efficiency (EQE).

FIG. 5. Table 5. Example performances of solar cells based on TCIC-4F measured under simulated 100 mW cm⁻² AM 1.5G illumination and photodetector performance estimated from dark current and external quantum efficiency (EQE).

FIG. 6A. Table 6a. Example performances of Organic Solar Cells (OSCs) based on TCIC-4F NFA measured under simulated 100 mW cm⁻² AM 1.5G illumination and Organic Photodetectors (OPDs) performances estimated from dark current and external quantum efficiency (EQE),

FIG. 6B Table 6b. Example performances of OSCs based on TCIC-4F and TCIC-4Cl measured under simulated 100 mW cm⁻² AM 1.5G illumination and OPDs performances estimated from dark current and external quantum efficiency (EQE).

FIGS. 7A-7M. Example solar cell and photodetector device performance of TCIC-4F based devices: Dark and photo current curves of PM2:TCIC-4F devices (FIG. 7A); EQE curve of PM2:TCIC-4F device at 0V bias (FIG. 7B); Responsivity curve of PM2:TCIC-4F device at 0V bias (FIG. 7C); Specific detectivity curve of PM2:TCIC-4F device at 0V bias (FIG. 7D); Dark and photo current curves of PTB7:TCIC-4F devices (FIG. 7E); EQE curves of PTB7:TCIC-4F device at 0V and −1V biases (FIG. 7F); Responsivity curves of PTB7:TCIC-4F device at 0V and −1V biases (FIG. 7G); Specific detectivity curves of PTB7:TCIC-4F device at 0V and −1V biases (FIG. 7H); Dark and photo current curves of PBDTTT-CT:TCIC-4F devices (FIG. 7I); EQE curves of PBDTTT-CT:TCIC-4F device at 0V and −1V biases (FIG. 7J); Responsivity curves of PBDTTT-CT:TCIC-4F device at 0V and −1V biases (FIG. 7K); Specific detectivity curves of PBDTTT-CT:TCIC-4F device at 0V and −1V biases (FIG. 7L); Dark current curves of PM2:TCIC-4F, PTB7:TCIC-4F and PBDTTT-CT:TCIC-4F devices (FIG. 7M).

FIG. 7N: Table 8. Space charge limited (SCLC) electron and hole mobilities of various TCIC-4F based devices.

FIGS. 7O-7R. Example solar cell and photodetector device performance of TCIC-4F and TCIC-4Cl based devices, wherein FIG. 7O shows dark current curves of PTB7:TCIC-4F and PTB7:TCIC-4Cl devices; FIG. 7P shows EQE curves of PTB7:TCIC-4F and PTB7:TCIC-4Cl devices at 0V and −2V bias; FIG. 7Q shows responsivity curves of PTB7:TCIC-4F and PTB7:TCIC-4Cl devices at 0V and −2V bias; FIG. 7R shows specific detectivity curves of PTB7:TCIC-4F and PTB7:TCIC-4Cl devices at 0V and −2V bias.

FIGS. 8A-8B. Surface morphology of (FIG. 8A) PTB7:TCIC-4F film and (FIG. 8B) PBDTTT-C-T:TCIC-4F film by AFM. The film size is 4×4 (μm²).

FIGS. 8C-8G. More examples of PTB7:TCIC-4F based device data: J-V curve, dark current and EQE at various D/A ratio and various negative biases.

FIGS. 9A-9B. Two dimensional (2D) image of Grazing-Incidence Wide-Angle X-ray Scattering (GIWAXS) and plotted line of scattering vector in q_{xy} and in q_{z} direction of PM2, BCIC-4F and TCIC-4F.

FIG. 9C-9E ¹H NMR spectra of compound BCIC-4F (FIG. 9C), TCIC-4F (FIG. 9D) and TCIC-4Cl (FIG. 9E).

FIG. 10. Flowchart illustrating a method of synthesizing a device.

FIG. 11. Example device structure.

### DETAILED DESCRIPTION OF THE INVENTION

In the following description of the preferred embodiment, reference is made to the accompanying drawings that form a part hereof, and in which is shown by way of illustrationa specific embodiment in which the invention may be practiced. It is to be understood that other embodiments may be utilized and structural changes may be made without departing from the scope of the present invention.

### Technical Description

### Example Compositions

1. Molecular Design, Synthesis and Characterization of NIR NFAs Cast in Films

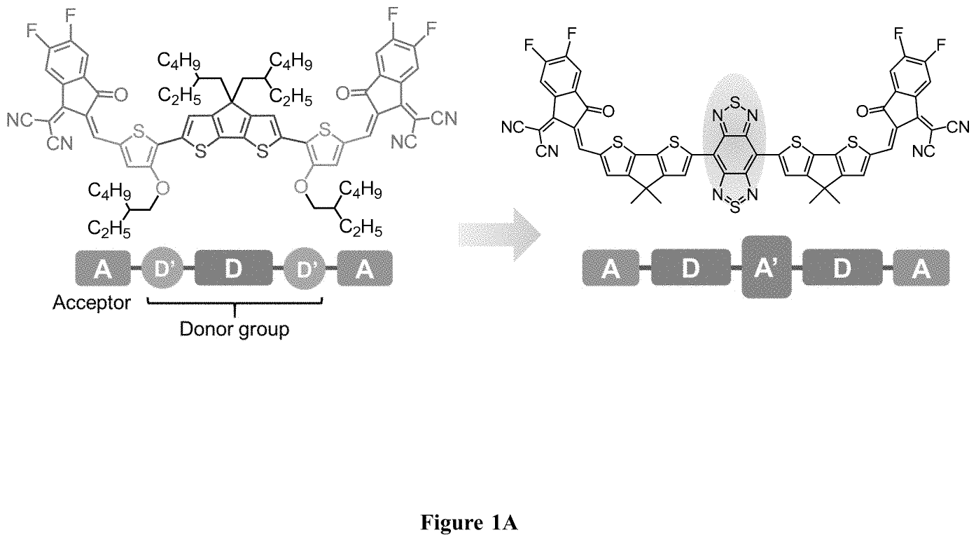

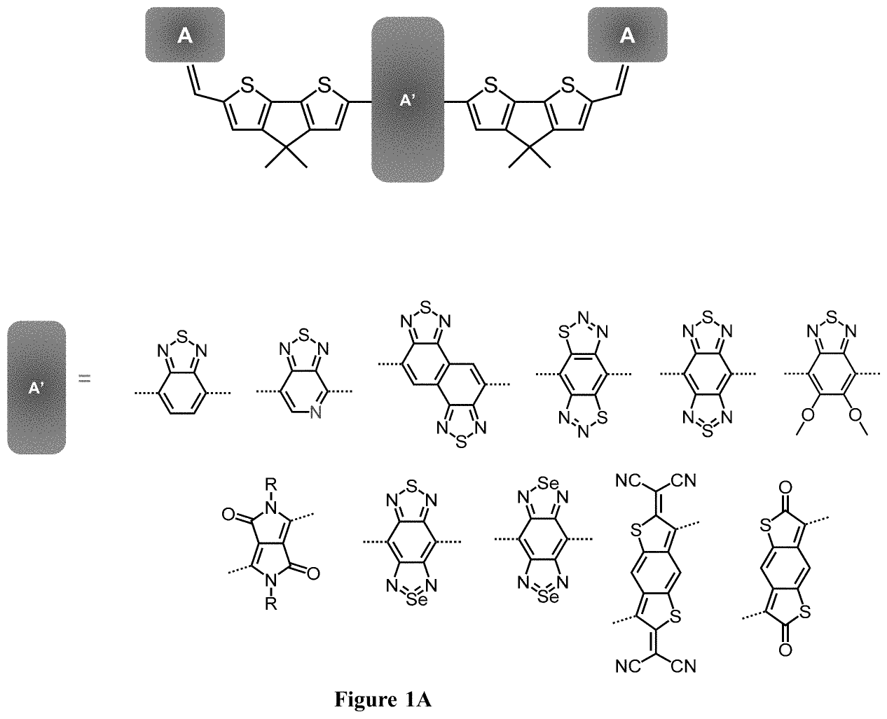

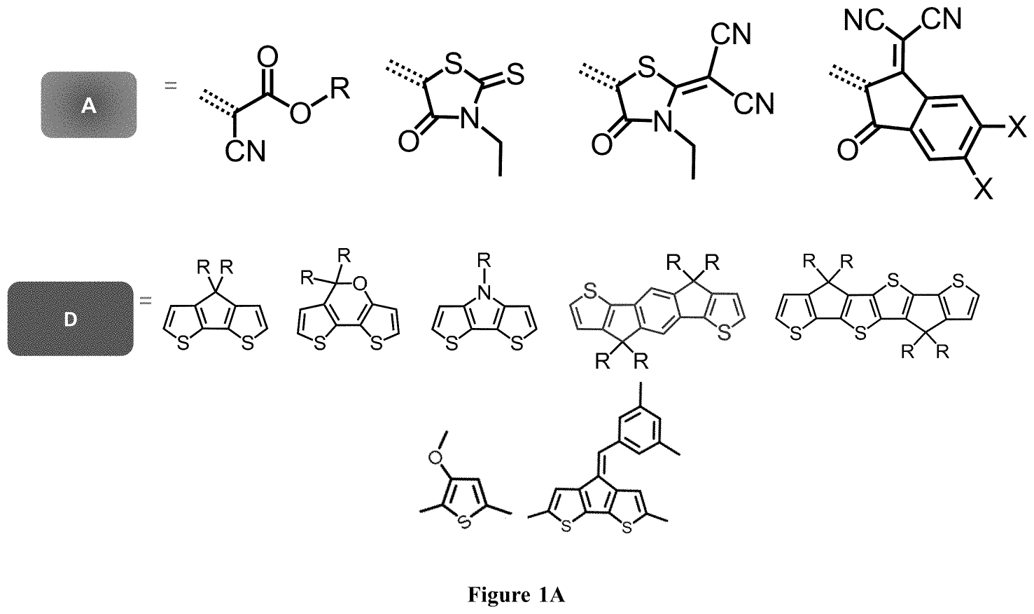

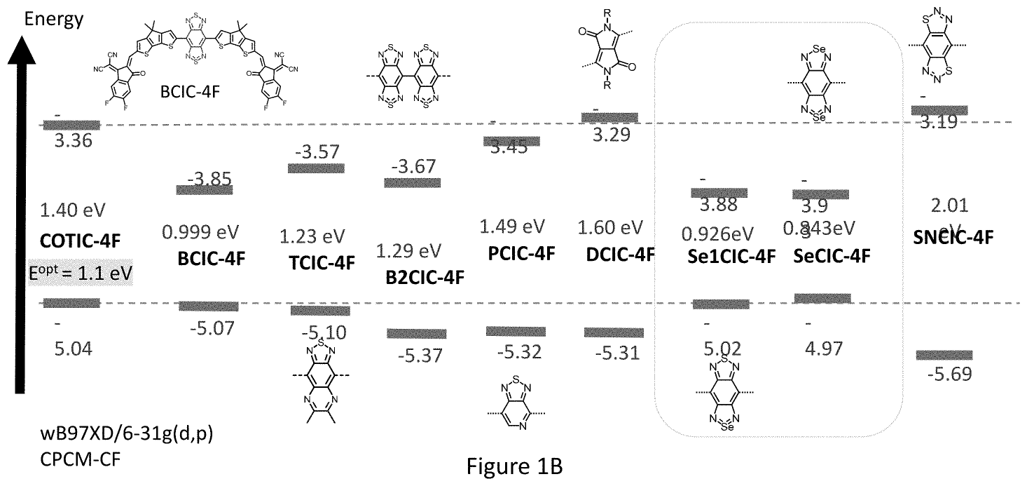

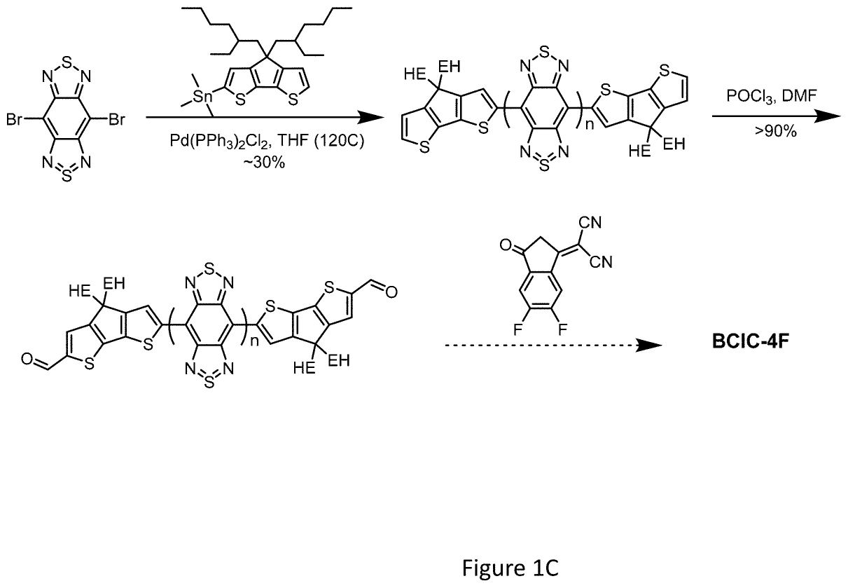

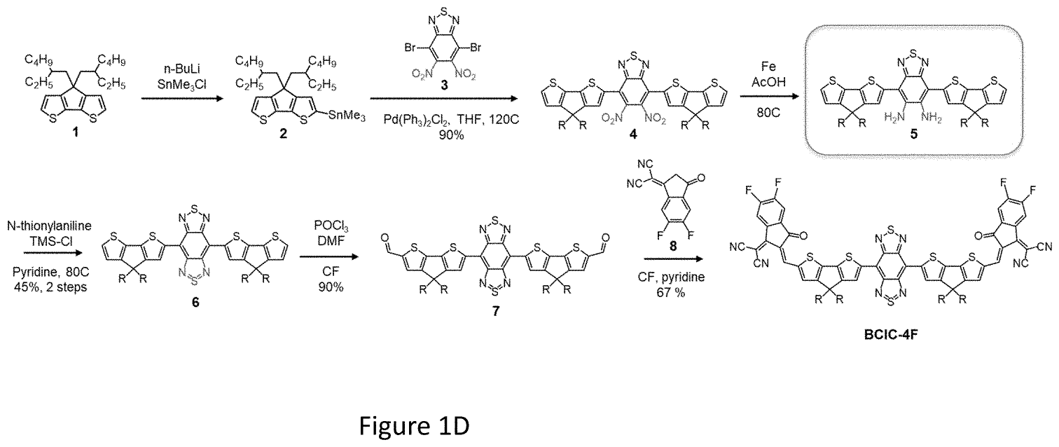

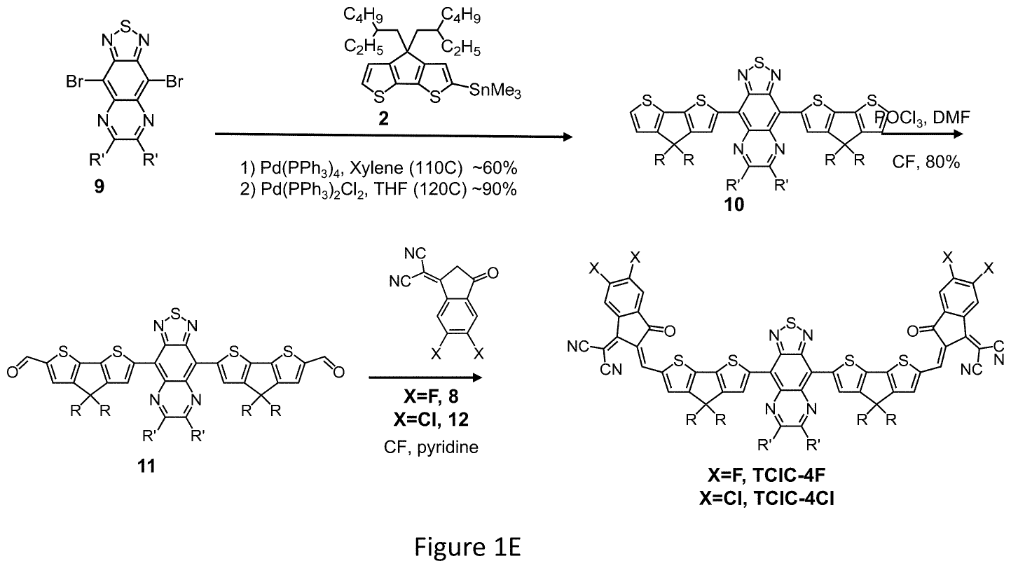

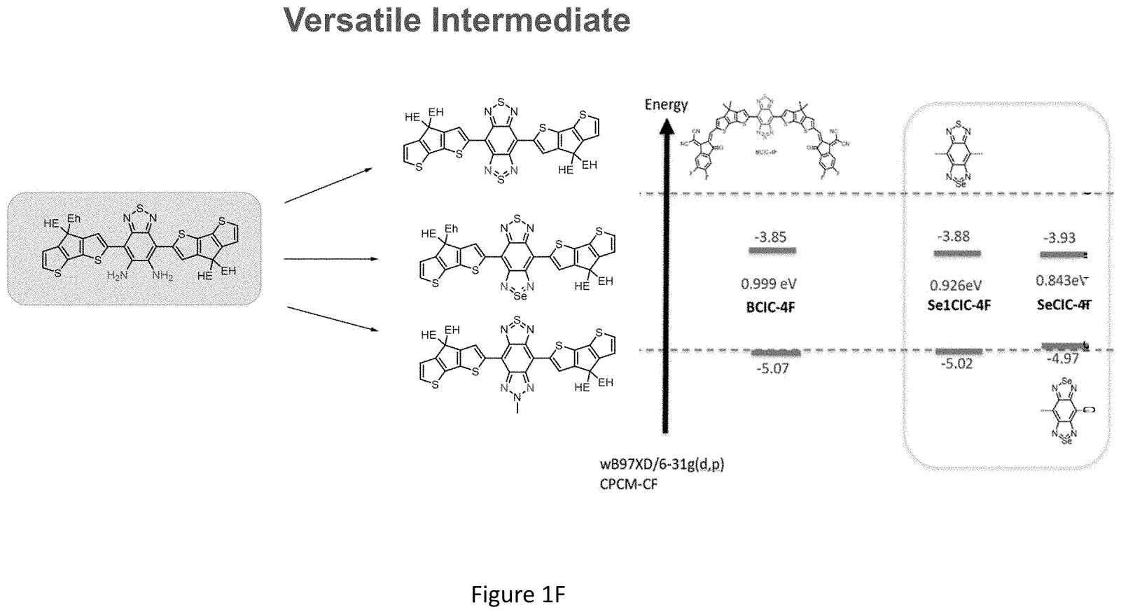

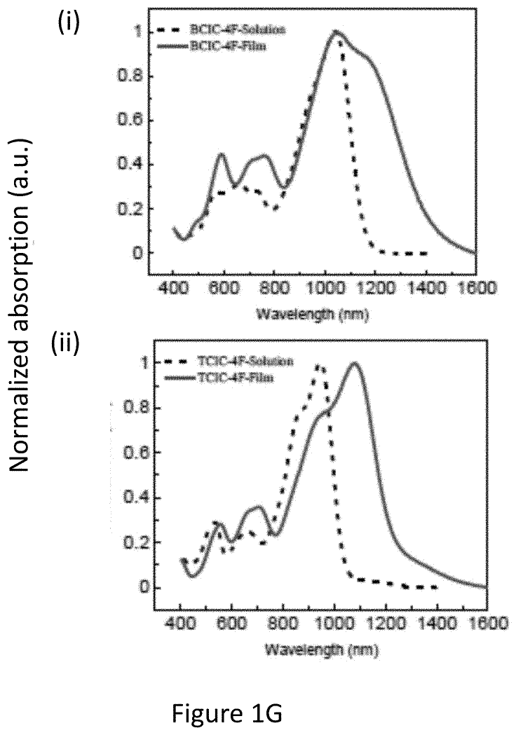

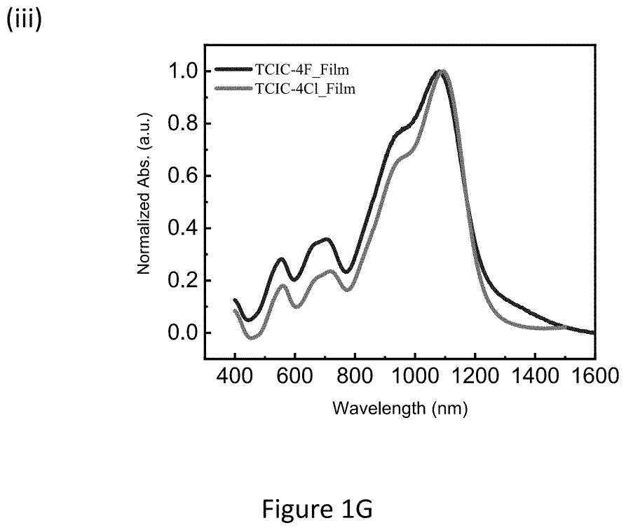

The present disclosure reports on newly designed non-fullerene acceptor (NFA) materials utilizing the A-D-A′-D-A molecular structure tailored to promote the enhanced intra-molecular charge transfer (ICT) effect and thereby achieve ultra-narrow bandgap <1.0 eV NIR absorbers. The new NFAs were rationally designed and their molecular properties (HOMO, LUMO, optical gap, oscillator strength etc.) were determined by employing quantum chemistry calculations using density functional (DFT) calculations with the semi-empirically tuned ωB97XD/6-31G (d,p) functional and basis set where the bulky side chains were simplified to methyl or ethyl groups. The general principle of molecular design and DFT calculated frontier energy level results are shown in FIGS. 1A and 1B. As shown in FIG. 1B, bandgaps of the NFAs highly depend on the structure and electron withdrawing capability of the center acceptor unit. BBT (benzo[1,2-c:4,5-c′]bis[1,2,5]thiadiazole) centered NFAs (e.g. BCIC-4F) have potentially the narrowest bandgap that might be lower than 1.0 eV. TQ (thiadiazolo[3,4-g]quinoxaline) centered NFAs (e.g. TCIC-4F) also have a narrower bandgap than the benchmark NFA COTIC-4F.

The synthetic routes for the two targeted molecules are summarized in FIGS. 1D and 1E. The target molecule BCIC-4F (FIG. 1D) was synthesized through Stille coupling of compound 2 and 4,7-dibromo-5,6-dinitrobenzo[c][1,2,5]thiadiazole (compound 3). After the reduction of the nitro-group (which gave compound 5) and cyclization of benzo[1,2-c:4,5-c′]bis[1,2,5]thiadiazole (BBT) unit (which gave compound 6), a Vilsmeier reaction (which gave compound 7) and Knoevenagel condensation reaction were applied and the target compound BCIC-4F was obtained. When 4,8-dibromobenzo[1,2-c:4,5-c′]bis[1,2,5]thiadiazole was used to couple directly with compound 2, homocoupling of 4,8-dibromobenzo[1,2-c:4,5-c′]bis[1,2,5]thiadiazole can occur, leading to narrow bandgap non-fullerene acceptors with various numbers of center BBT units (FIG. 1C). As shown in FIG. 1F, more potential ultra-narrow bandgap NFAs derivatives could be achieved using a synthesis starting from the important di-amine intermediate in FIG. 1D.

FIG. 1E further illustrates the other type of NIR NFA (TCIC-4X (X═F or Cl) was prepared using a similar method starting from the Stille coupling of compound 2 and 4,9-dibromo-6,7-bis(4-((2-decyltetradecyl)oxy)phenyl)-[1,2,5]thiadiazolo[3,4-g]quinoxaline (compound 9).

To further examine the materials' optical properties, BCIC-4F, TCIC-4F and TCIC-4Cl chloroform (CF) solutions and thin-films (cast from the solutions of NFA (10 mg/mL) in chloroform (CF) at 1000 rpm) were measured by UV-Vis-NIR spectroscopy (FIG. 1G). All NFAs showed broad and strong absorption in the near IR region of 800 nm to 1200 nm according to the absorption profiles. TCIC-4F has a solution absorption peak at 928 nm and BCIC-4F has the peak at 1032 nm. In the thin-film UV-Vis spectra, the absorption extended beyond 1500 nm.

BCIC-4F is characterized by two main absorption peaks where the second peak lies around 1200 nm, and the TCIC-4F and TCIC-4Cl have a solid-state absorption peak at 1086 nm and 1095 nm respectively. With the onset absorption wavelength obtained from the absorption profile around 1200 nm, the optical gaps for TCIC-4F, TCIC-4Cl and BCIC-4F were estimated as 0.99 eV, 0.98 eV and 0.86 eV, respectively. TCIC-4F showed the maximum absorption peaks of around 1100 nm in NIR region.

A cyclic Voltammetry (CV) experiment was conducted using a CHI-730B electrochemistry workstation with the three-electrodes system consisting of glassy carbon disk, Pt wire, and Ag wire electrode which serve as the working electrode, counter electrode, and pseudo reference electrode, respectively. The measurement was performed in 0.1M tetrabutylammonium hexafluorophosphate (n-Bu₄NPF₆)-anhydrous acetonitrile solution at the potential scan rate of 40-100 mV s⁻¹. Thin films of samples were deposited onto the glassy carbon working electrode from its 3-5 mg mL⁻¹ chloroform solution. The electrochemical onsets were determined at the position where the current starts to differ from the baseline. The potential of Ag pseudo reference electrode was internally calibrated relative to Fc/Fc⁺ couple (−4.88 eV vs. vacuum). The HOMO level measured by CV for BCIC-4F is −5.4 eV and the calculated LUMO level is −4.5 eV. The HOMO level measured by CV for TCIC-4F is −5.6 eV and the calculated LUMO level is −4.6 eV.

TABLE 1
Optical and electrochemical properties of BCIC-4F and TCIC-4F

| NFA | E_{g}^{opt} (eV)^{a} | E_{HOMO} (eV)^{b} | E_{LUMO} (eV)^{c} |
|---|---|---|---|
| BCIC-4F | 0.86 | −5.40 | −4.50 |
| TCIC-4F | 0.99 | −5.60 | −4.60 |

^{a}Optical band gap calculated from the absorption edge of thin film.
^{b}HOMO energy level estimated from the onset oxidation potential.
^{c}LUMO energy level estimated from the CVmeasured HOMO level and optical gap.

2. Device Fabrication and Characterization Method

In a first example, the NIR donor polymer PM2 with an optical band gap (E^{opt}) of 1.41 eV was selected to fabricate solar cell and photodetector devices with the newly designed ultra-narrow bandgap NFAs.

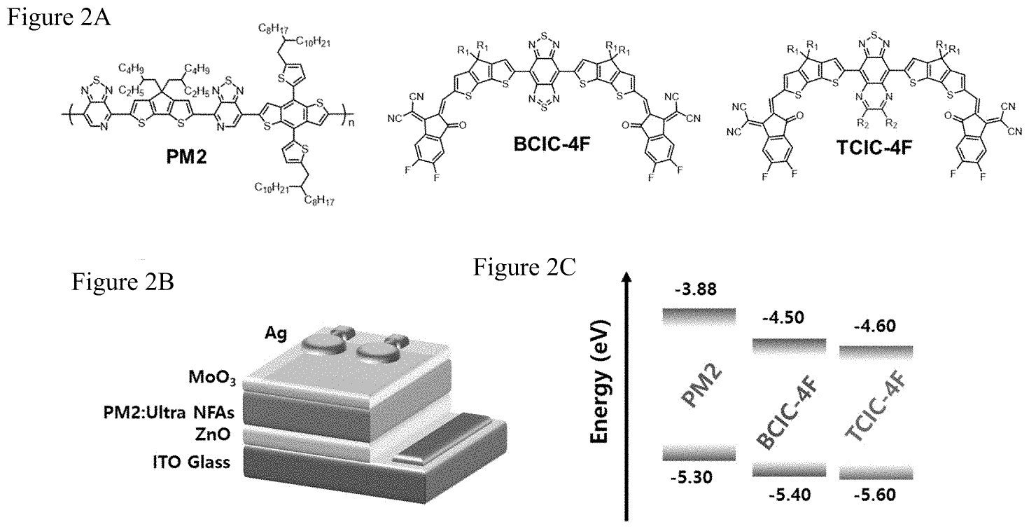

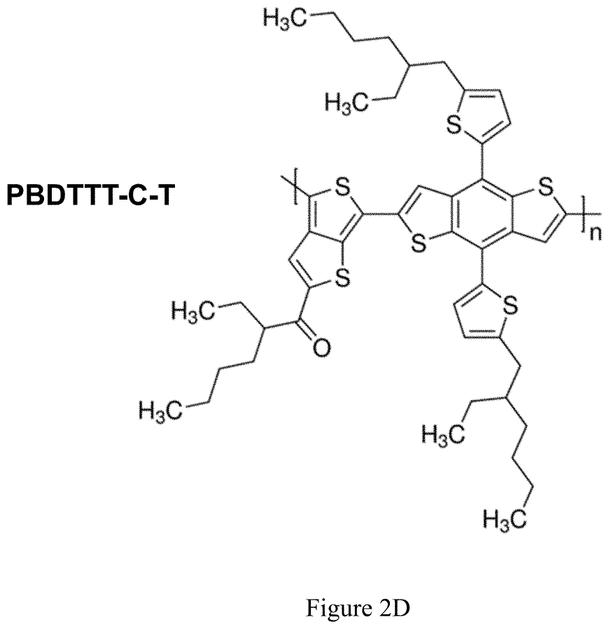

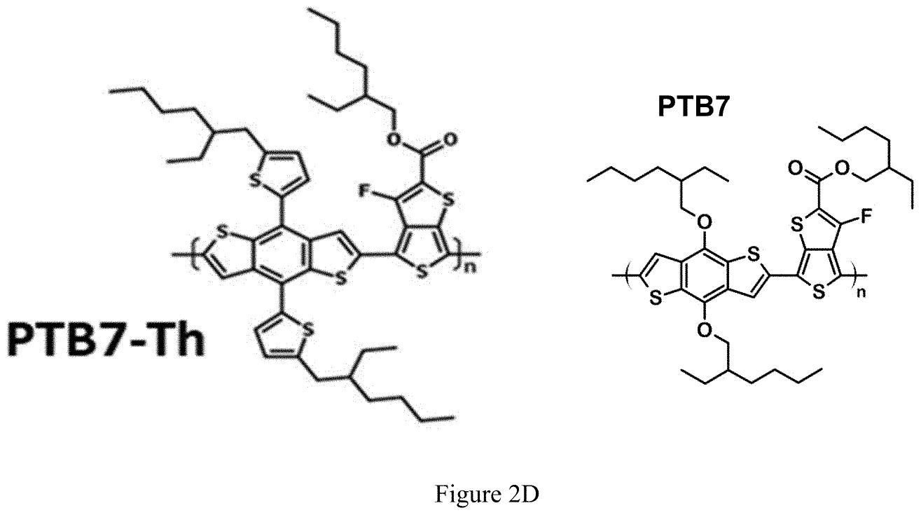

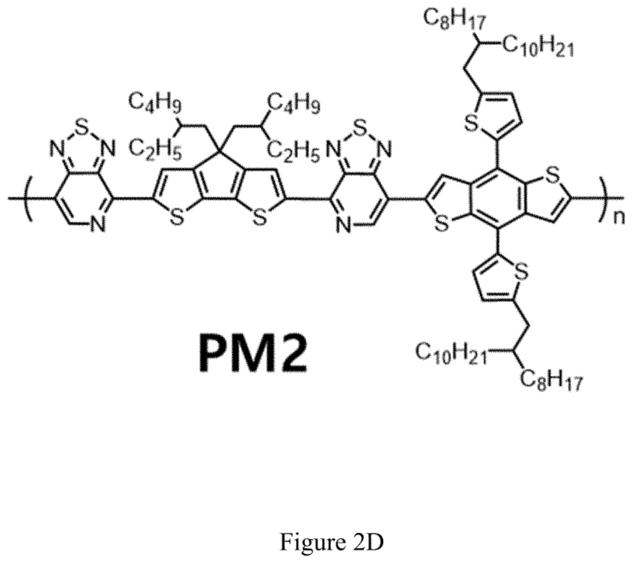

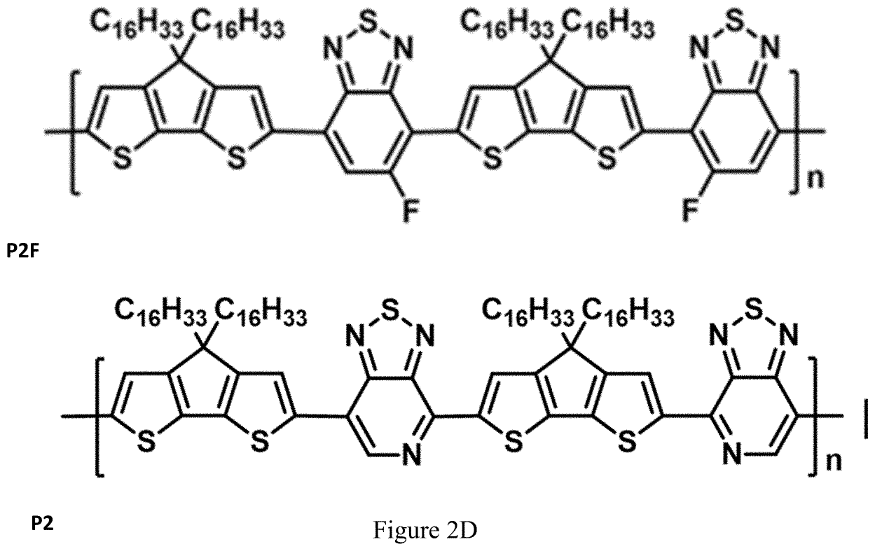

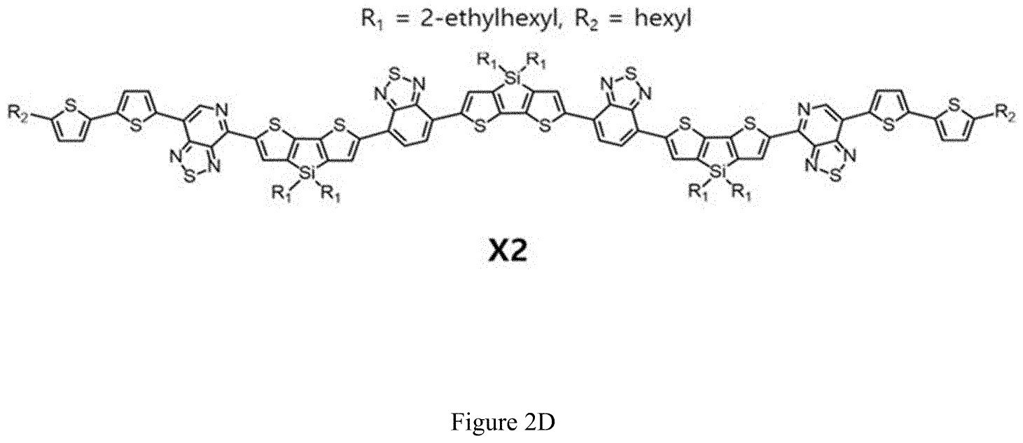

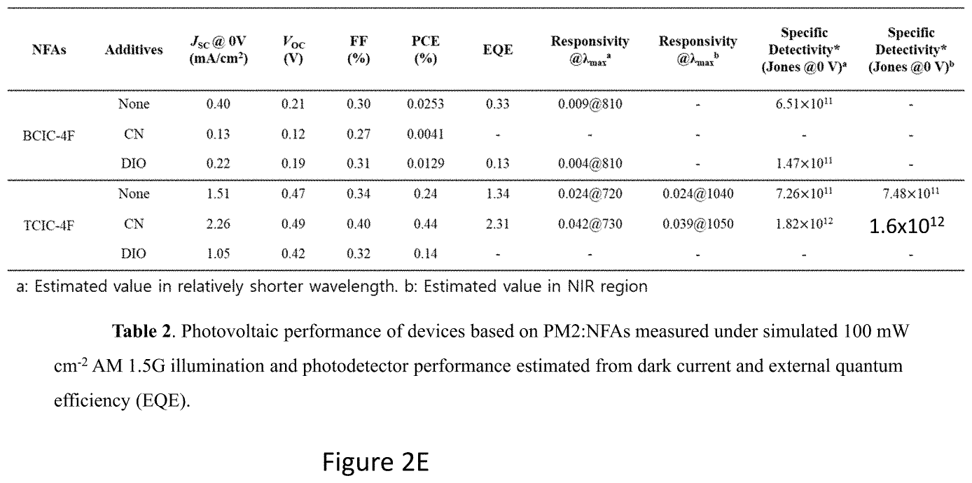

The electronic property and absorption spectra of devices comprising the NIR NFAs and NIR donor were measured. FIG. 2A illustrates the molecular structures of the donor material PM2 and acceptors BCIC-4F and TCIC-4F used in the device architecture, FIG. 2B illustrates the device architecture, and FIG. 2C illustrates the band diagram of the donor and NFAs. Because the compositions (PM2 and NFA) consist of only narrow bandgap materials (in a D:A blend), strong absorption of photons in the NIR region by the devices and high transparency in the visible light region can be expected.

Some example devices based on blends of PM2:BCIC-4F and PM2:TCIC-4F were fabricated in an inverted device structure of indium-tin-oxide (ITO)/zinc oxide (ZnO)/NIR D:A/MoO₃/Ag, as illustrated in FIG. 2B. The typical procedures of device fabrication were as follows. First, the ITO-coated glass substrates were cleaned with detergent, then ultra-sonicated in acetone and isopropyl alcohol, and subsequently dried in an oven at 100° C. Then, the cleaned ITO substrates were ultraviolet-ozone treated for 15 min to remove tiny organic residues. The zinc oxide (ZnO) solution was prepared using mixture of diethyl zinc solution in toluene and tetrahydrofuran (THF) (1:5, v/v %) and the ZnO film (ca. 30 nm thick) was spin-coated at 3000 or 4000 rpm for 20 s or 30 s and annealed at 110° C. or 150° C. for 5-10 min. The blend solutions of PM2:NFAs was dissolved in chlorobenzene, which are with and without processing additives such as 1,8-diiodooctane or 1-chloronaphthalene, wherein the typical ratio of donor to acceptor was 1:1, 1:1.5 or 1:2 (D:A w/w) and the typical concentration of the solutions was 10-25 mg/ml. These solutions were spin-coated at 2000 to 5000 rpm for film optimization in a nitrogen-filled glove box. The devices were pumped down in vacuum (<10⁻⁶ torr), and the MoO₃/Ag (typically 5 nm/90 nm thick) electrode was deposited by thermal evaporation.

Light-detecting characteristics measurements were carried out in the glove box using a solar simulator equipped with a Keithley 2635A source measurement unit. J-V curves were measured under AM 1.5G illumination at 100 mW cm⁻². EQE measurements were conducted in ambient air condition using an EQE system.

3. Device Characterization and Analysis

### a. Definitions

External quantum efficiency (EQE), the ratio of the number of charge carriers collected by the device to the number of photons from incident light, was measured at 0 V to −5 V bias. Dark currents of the OPD devices were measured to calculate photodetector characterizations (e.g., responsivity and specific detectivity). Generally, Responsivity and specific detectivity(D*) are well-known figures of merit for photodetector. Responsivity is defined as photocurrent per incident unit of optical power, in other words, electrical output of photon input, which can be obtained from equation (1):

$$R = η \frac{q λ}{hv} \qquad ( 1 )$$

Specific detectivity (D*) is the sensitivity to monochromatic radiation at the wavelength for which the sensitivity is the highest. Larger D* means increased ability to detect a weak signal which is comparable with the detector's noise level. D* is given by equation (2):

$$D *= \frac{R}{\sqrt{2 {qJ}_{D}}} \qquad ( 2 )$$

where hv=photon energy, q=elementary charge, η=quantum efficiency, λ=wavelength, J_{D}=the dark current density.

### b. Results

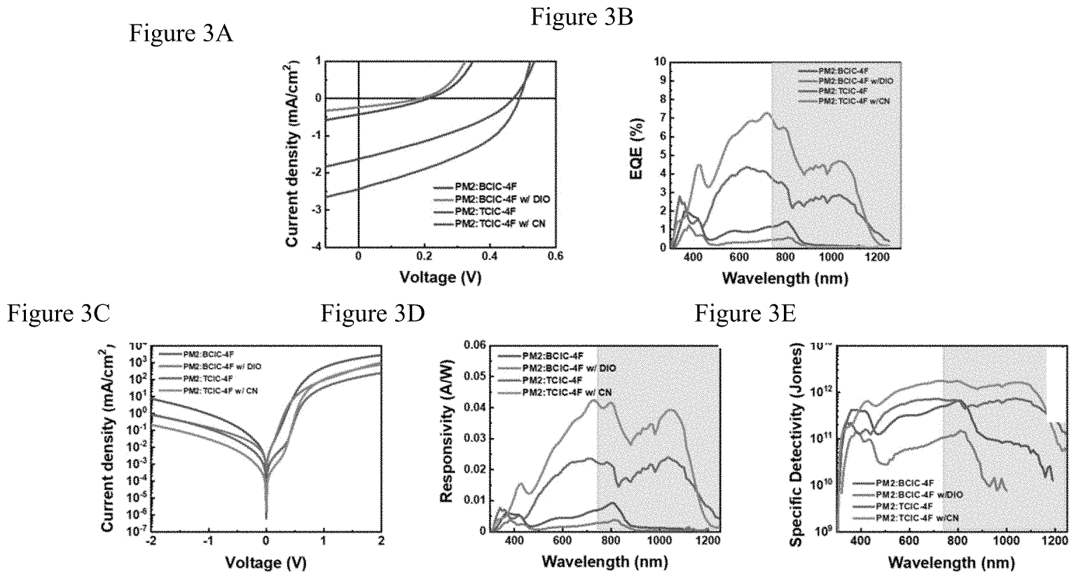

Table 2 in FIG. 2E lists the performance data for both bulk heterojunction organic photovoltaic (OPV) and OPD devices using PM2 as the electron donor and BCIC-4F or TCIC-4F as the electron acceptor, and FIG. 3 shows the corresponding J-V curves, EQE spectra, spectra of responsivity and specific detectivity, and dark current of the devices. PM2:BCIC-4F-based organic solar cells have a short circuit current density (J_{sc}) of less than 1 mA/cm² under 1 sun irradiation and an drastic drop of EQE response beyond 900 nm.

While the photodiode comprising a PM2:TCIC-4F blend system without additives has a J_{sc} of 1.51 mA/cm², a higher value of J_{sc} (2.26 mA/cm²) was obtained for the photodiode comprising a blend with 2% (v/v) 1-chloronaphthalene processing additive. Thus, the PM2:TCIC-4F based devices are characterized by two meaningful peaks at around 720-730 nm and around 1040-1050 nm as shown in their EQE spectra, which probably arise from the maximum absorption of PM2 and TCIC-4F, respectively. The PM2:BCIC-4F based device has just one maximum EQE peak at around 810 nm (at a longer wavelength as compared to the PM2:TCIC-4F based device). Maximum responsivities under photovoltaic mode (0 V bias) of 0.009 A/W and 0.042/0.039 A/W were determined for PM2:BCIC-4F, and PM2:TCIC-4F based devices at wavelengths of 810 nm and 730 nm/1050 nm, respectively. In addition, the maximum specific detectivity (D*, Jones) measured for PM2:BCIC-4F is 6.51×10¹¹ Jones at the 810 nm wavelength, while PM2:TCIC-4F showed 1.82×10¹² and 1.60×10¹² Jones at each EQE peak wavelength.

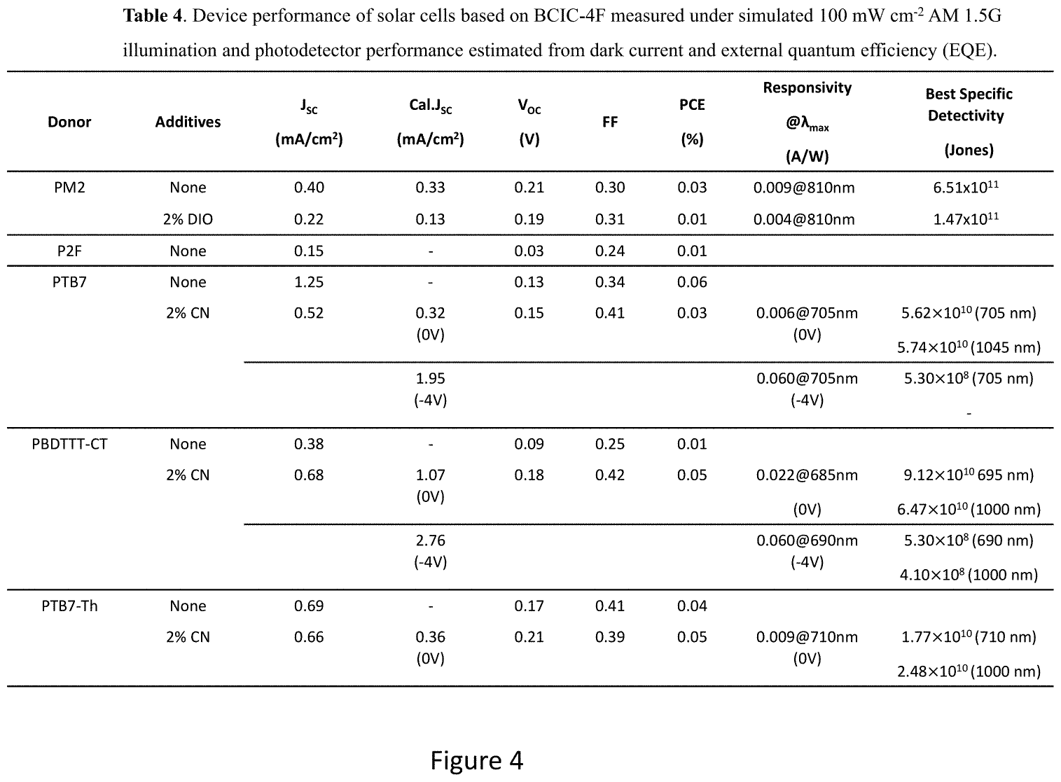

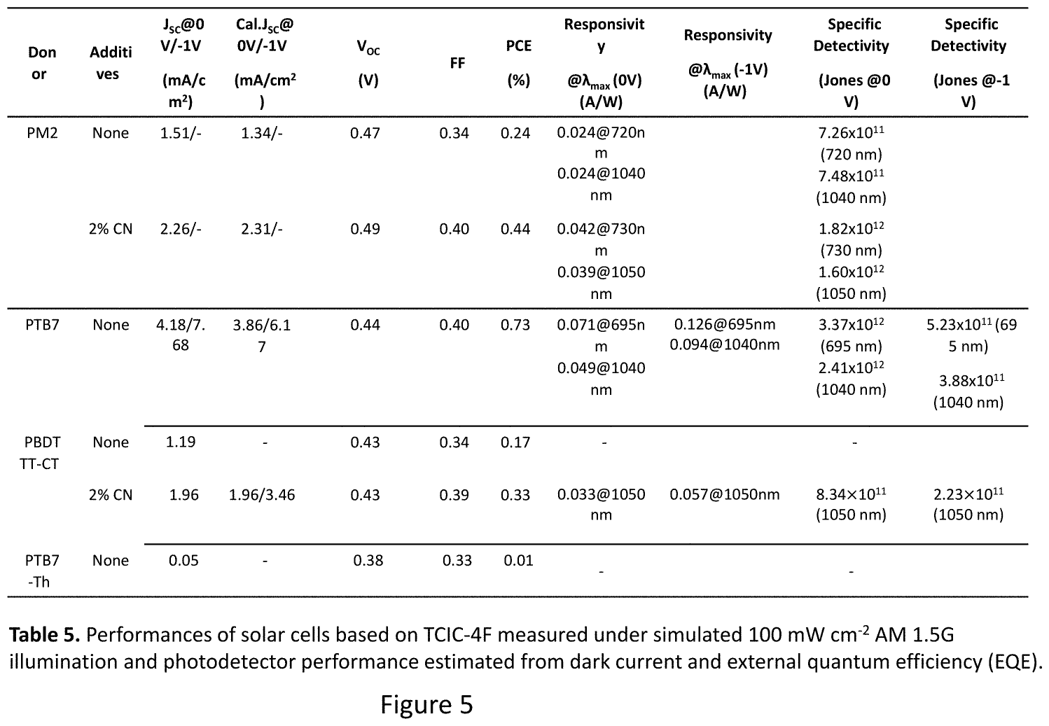

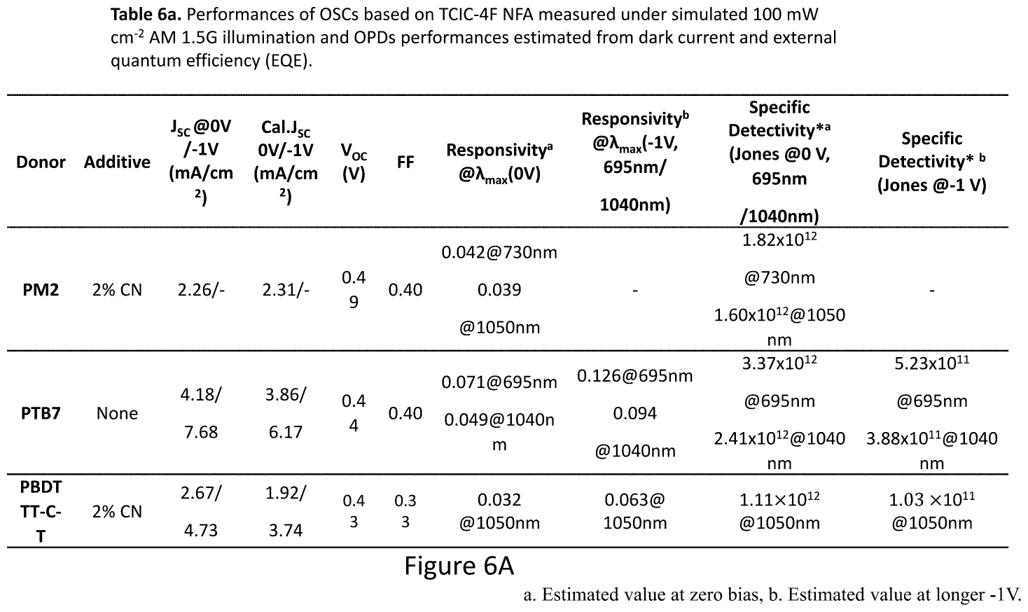

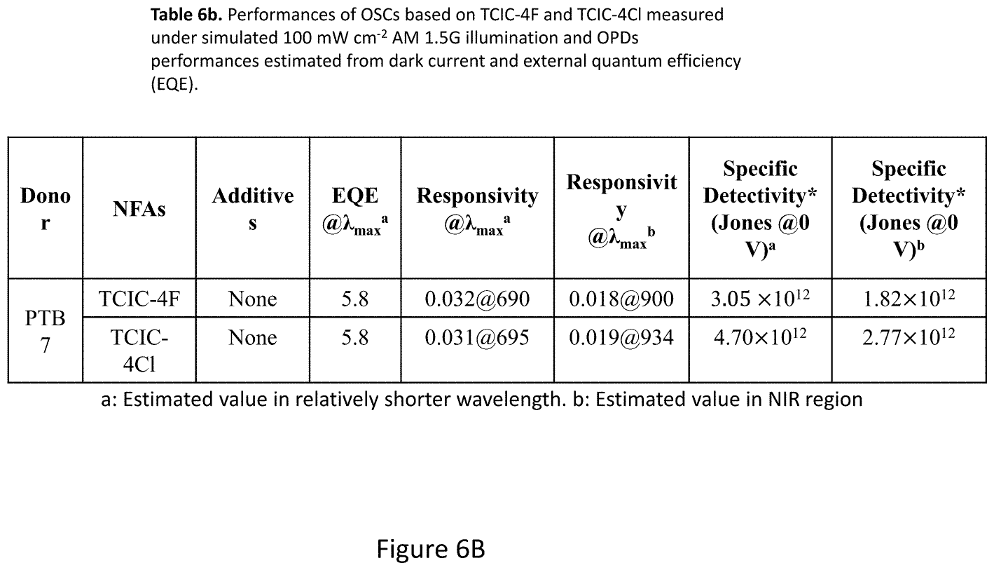

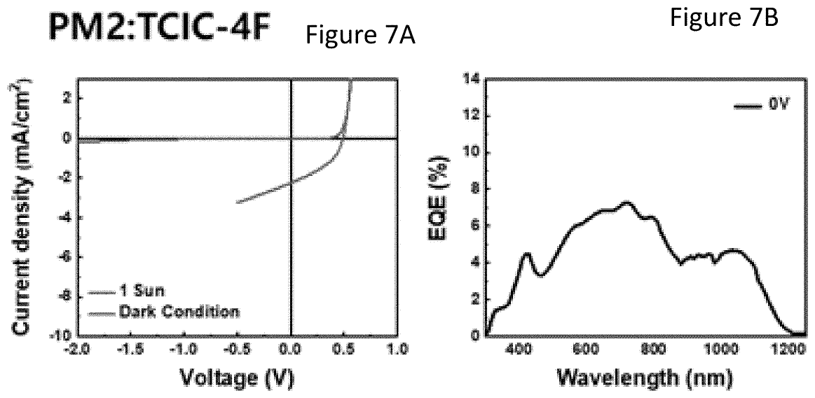

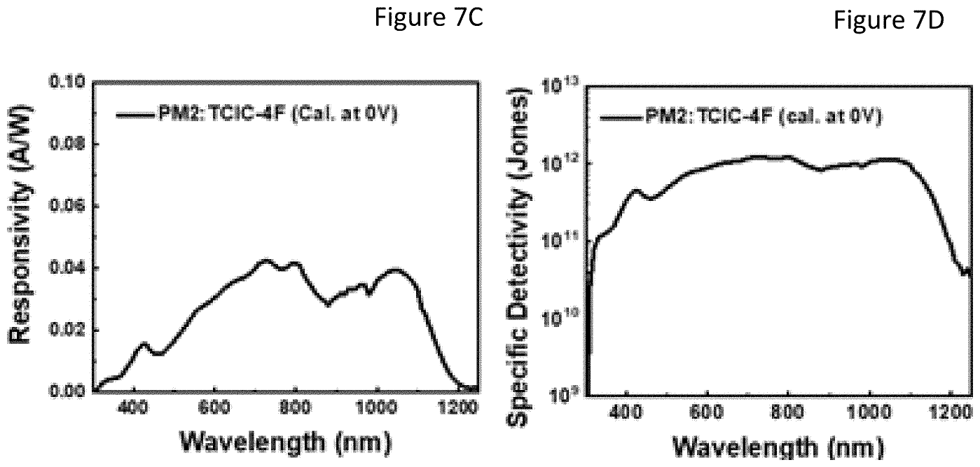

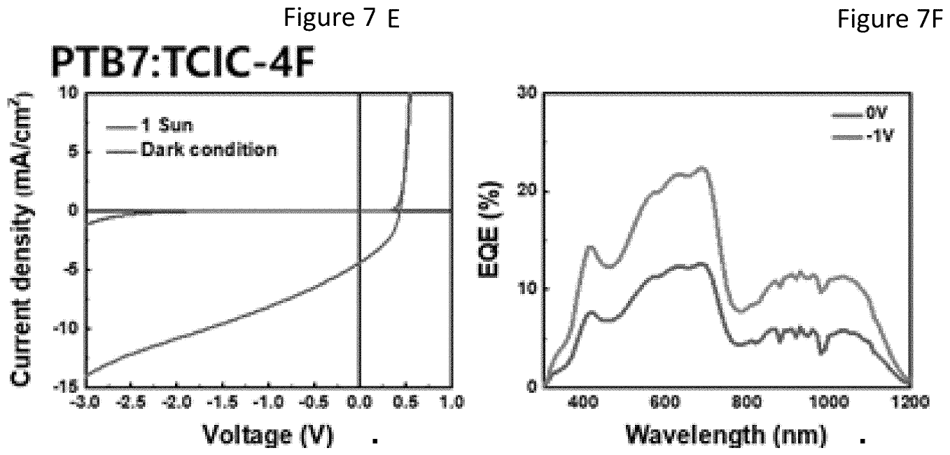

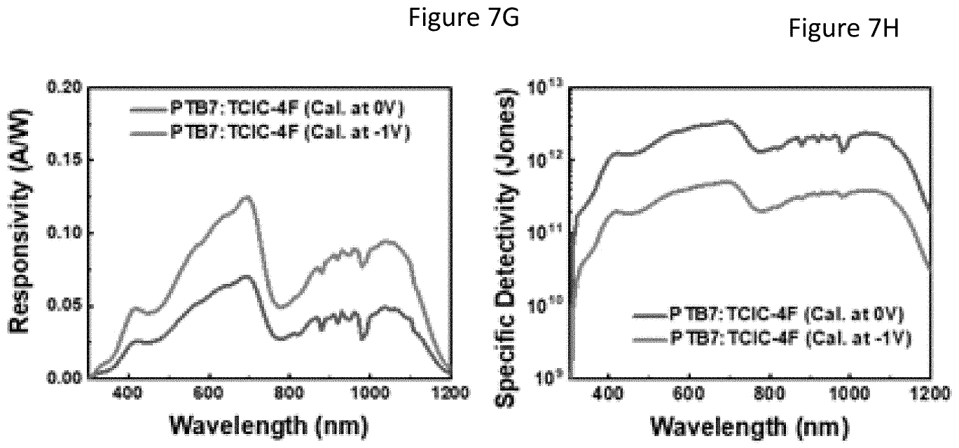

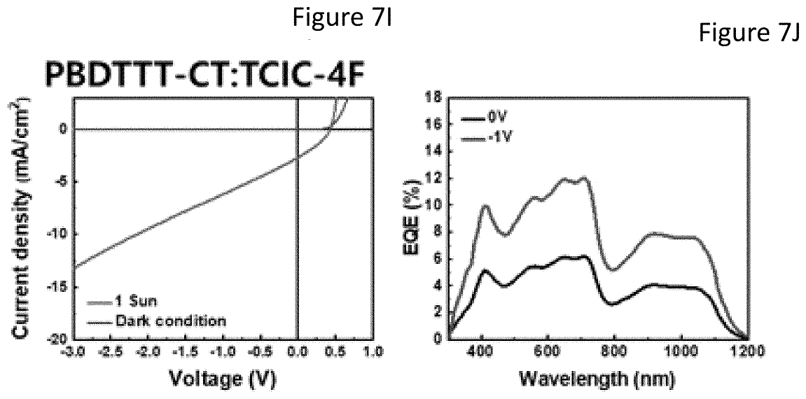

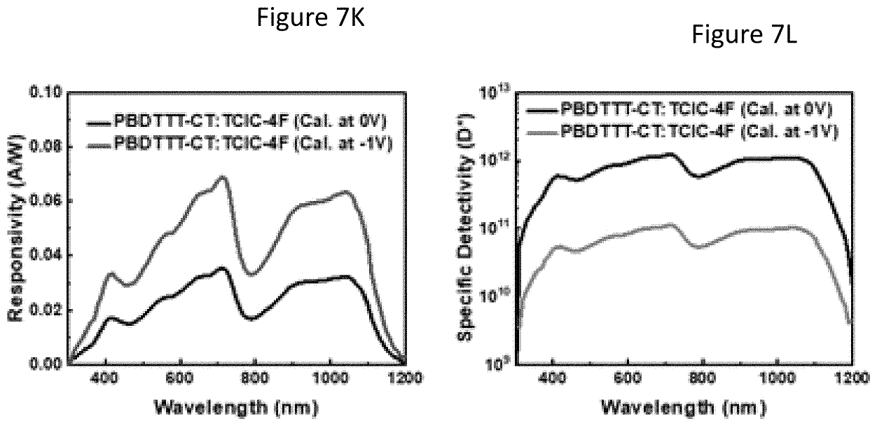

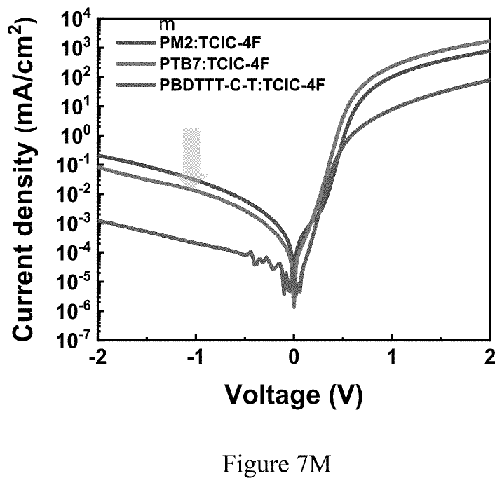

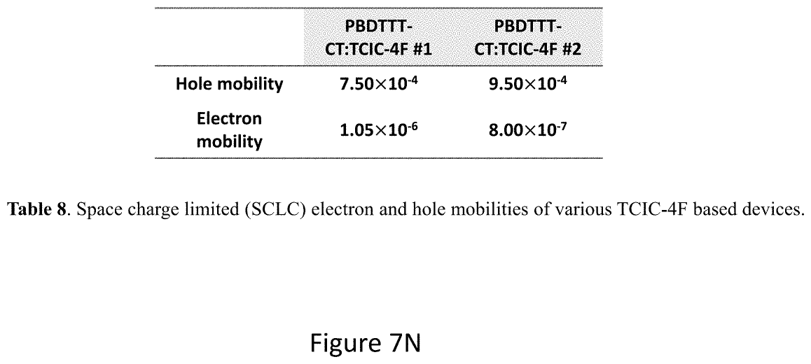

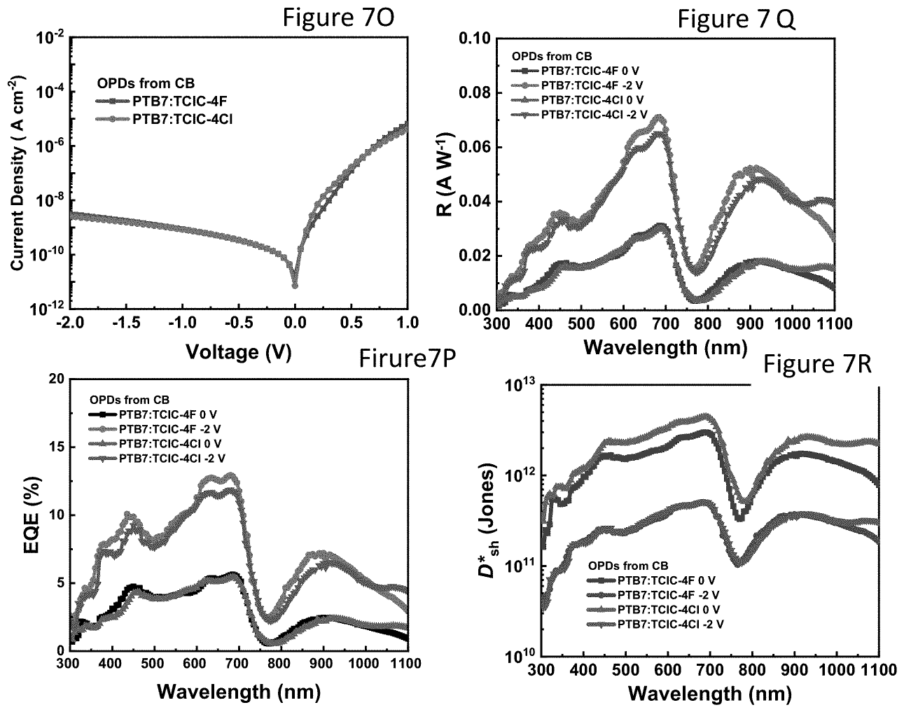

Donor polymers P2, P2F, PTB7, PTB7-Th and PBDTTT-C-T (FIG. 2D) with various HOMO/LUMO levels and bandgaps were selected to further enhance photocurrent in the visible to NIR region of the OPD devices when combined with the NFAs BCIC-4F, TCIC-4F and TCIC-4Cl. In addition, we studied the relationship between energy offset (ΔLUMO_{A}/ΔLUMO_{D} and ΔHOMO_{A}/ΔHOMO_{D}) and OPD performance. Performance of BCIC-4F based devices are summarized in Table 4 (FIG. 4). Performance of TCIC-4F and TCIC-4Cl based devices are summarized in Table 5 (FIG. 5), Table 6a and 6b (FIGS. 6A-6B) and FIGS. 7A-7R.

PTB7:TCIC-4F and PBDTTT-C-T:TCIC-4F based OPDs were evaluated in both self-power mode (performance at zero bias) and in reverse bias mode (performance at −1V). As shown in Table 7, donor polymer PTB7 has −5.15 eV HOMO energy level and −3.31 eV LUMO energy level, while donor polymer PBDTTT-C-T has −5.11 eV HOMO energy level and −3.25 eV LUMO energy level.

| Donor | E_{G} (eV) | E_{HOMO} (eV) | E_{LUMO} (eV) |
|---|---|---|---|
| PBDTTT-CT^{a} | 1.86 | −5.11 | −3.25 |
| PTB7^{a} | 1.84 | −5.15 | −3.31 |
| PTB7-Th^{b} | 1.58 | −5.24 | −3.66 |
| P2F^{c} | 1.25 | −5.03 | −3.78 |
| P2^{d} | 1.12 | −5.16 | −3.70 |
| PM2^{d} | 1.42 | −5.30 | −3.88 |

Table 7. Optical and electrochemical properties of various donor polymers for this invention. HOMO, LUMO and band gaps of various donor polymers from
^{a}https://www.sigmaaldrich.com/US/en;
^{b}https://www.ossila.com/products/pce10;
^{c}U.S. Pat. No. 10,316,135;
^{d}International Patent Application No. PCT/US20/39963. Structures of the polymers are listed in FIG. 2D.

PM2:TCIC-4F based organic solar cells with 2% (v/v) chloronaphthalene (CN) additive showed 0.44% of power conversion efficiency (PCE) with J_{sc} of 2.26 mA/cm², Voc of 0.49 V and FF of 0.40 under 1 sun irradiation. On the other hand, organic solar cells comprising the PTB7:TCIC-4F blend system showed 0.73% PCE resulting from 4.18 mA/cm² (J_{sc}) and 0.44 V (V_{oc}) and a FT of 0.40. Peak responsivities under photovoltaic mode (0 V bias) were calculated as 0.042 A/W for the PM2:TCIC-4F device at around 730 nm wavelength, and 0.071 A/W for PTB7:TCIC-4F-based device at around 695 nm wavelength. The devices also showed peak responsivities of 0.039 A/W (PM2:TCIC-4F) and 0.049 A/W (PTB7:TCIC-4F) at around 1040-1050 nm wavelengths. It is possible that the peak responsivities at shorter wavelengths are more related to donor polymer absorption and the peak responsivities at longer wavelength (1050 nm) are related to photocurrent from TCIC-4F absorption. On the other hand, the peak specific detectivities (D*) of the best PM2:TCIC-4F device are 1.82-10¹² Jones at 730 nm and 1.60×10¹² Jones at 1050 nm and 0V bias. PTB7:TCIC-4F devices exhibited peak specific detectivities of 3.37×10¹² Jones at 695 nm and 2.41×10¹² Jones at 1040 nm and 0V bias.

Maximum responsivities around 1040 nm to 1050 nm under self-power mode (0 V) were calculated to be 0.049 A/W and 0.033 A/W for PTB7:TCIC-4F, and PBDTTT-C-T:TCIC-4F based devices, respectively. Responsivities of 0.094 A/W (PTB7:TCIC-4F) and 0.057 A/W (PBDTTT-C-T:TCIC-4F) were achieved at the bias of −1V. FIGS. 7A-R summarize J-V curves, spectra of EQE, responsivities and specific detectivities of PM2:TCIC-4F, PTB7:TCIC-4F, PBDTTT-C-T:TCIC-4F and PTB7:TCIC-4Cl based OSC and OPD devices. For these examples, it is likely that the donor absorption contributed more to the response at shorter wavelengths and response beyond 900 nm is dominantly from absorption by the TCIC-4F. As shown in FIG. 7, spectra of EQE, responsivity and specific detectivity all gave two peak values probably corresponding to the peak absorption of donors and acceptors, respectively. The maximum D* of the PTB7:TCIC-4F device are 2.41×10¹² (at 1040 nm) Jones under 0V bias and 3.88×10¹¹ (1040 nm) Jones under −1 V bias. PBDTTT-C-T:TCIC-4F devices showed the D* of 8.34×10¹¹ (at 1050 nm) Jones under 0 V bias and 2.23×10¹¹ (at 1050 nm) Jones at −1 V bias. PBT7:TCIC-4Cl devices gave a responsivity of 0.019 A/W at 934 nm and a specific detectivity of 2.77×10¹¹ Jones in the NIR region under 0 V bias. Comparing to performance at zero bias, device responsivities increase and specific detectivities drop when a negative bias was applied, which is expected.

Overall, broad EQE, responsivity and specific detectivity response in the 300 nm to 1200 nm region has been achieved. Furthermore, device EQE response over 10%, responsivity over 0.05 A/W and specific detectivity over 10¹² Jones in the near IR region of 900-1100 nm has also been successfully demonstrated. Structural modification of BCIC-4F with longer and bulkier side chains may help improve its miscibility with donor polymers and the device performance.

FIG. 7M plots the dark current of three blend systems (PM2:TCIC-4F, PTB7:TCIC-4F and PBDTTT-C-T:TCIC-4F). Although PBDTTT-C-T:TCIC-4F OPDs showed lower photocurrent density under 1 sun illumination, it showed lower leakage current at reverse bias under dark conditions. For this case, we hypothesize that the larger ΔLUMO_{A}/ΔLUMO_{D} and ΔHOMO_{A}/HOMO_{D} off-set lead to larger electrostatic potential barrier, which reduces charge flow and results in lower dark current at reverse bias.

Hole-only and electron-only devices with PBDTTT-C-T:TCIC-4F active layers were fabricated. Space charge limited current (SCLC) electron and hole mobilities were extracted using the Mott-Gurney equation from the SCLC region and are summarized in Table 8 (FIG. 7N). The average hole and electron mobilities of PBDTTT-C-T:TCIC-4F were 8.5×10⁻⁴ cm²/V·s and 9.3×10⁻⁷ cm²/V·s, respectively. The vertical hole mobility of PBDTTT-C-T:TCIC-4F is higher than electron mobility by two to three orders of magnitude. Balancing charge moving in the devices may further enhance OSC and OPD device performance. For example, electron and hole mobility can be adjusted by the optimization of film morphology and donor to acceptor ratio in the active layer. Hole mobility can be adjusted by control the thickness of MoO₃ buffer layer. Reducing vacancy and removing trap sites in ZnO buffer layer may improve device electrons conduction.

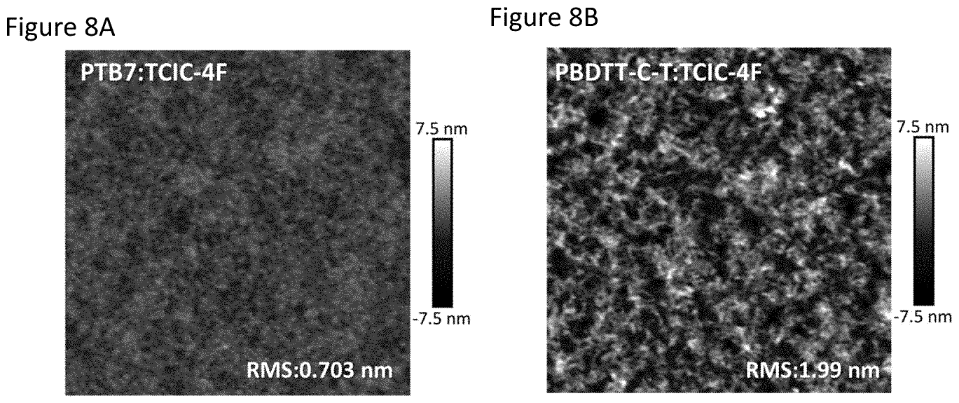

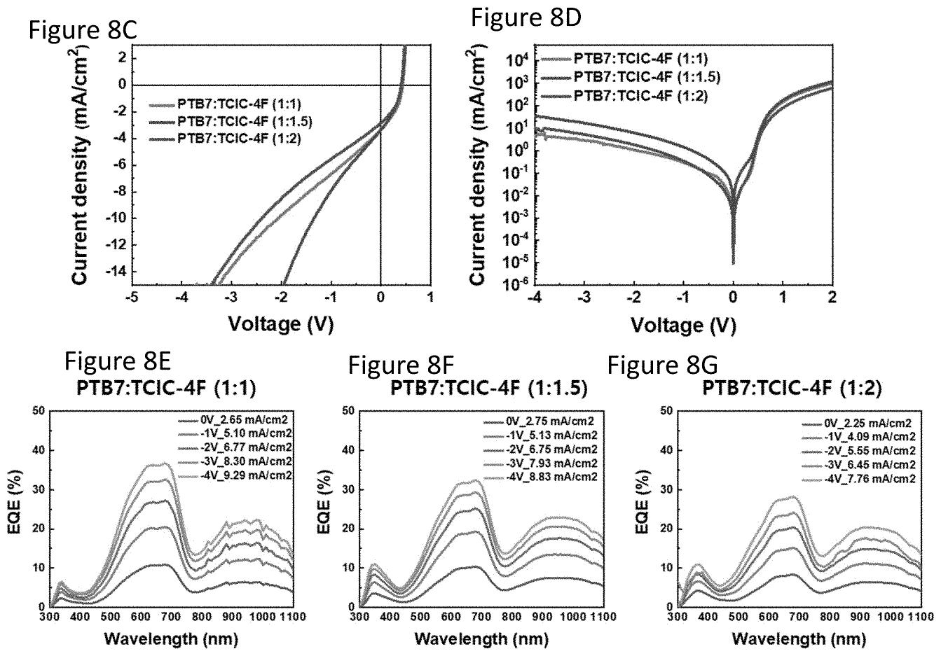

Film morphologies of PTB7:TCIC-4F and PBDTTT-C-T:TCIC-4F blend films prepared under the device fabrication condition were examined by tapping mode Atomic Force Microscope (AFM) (FIG. 8A-8B). PTB7:TCIC-4F films displayed a smooth surface with 0.703 nm roughness in an area of 4×4 μm². In contrast, PBDTTT-C-T:TCIC-4F films showed large clusters with higher roughness of 1.99 nm in an area of 4×4 μm². Film smoothness will likely affect charge extraction and leakage current in the devices.

PTB7:TCIC-4F based OSC and OPD with the device configuration of ITO/Mg—ZnO (15%)/active layer/MoO₃ (25 nm)/Ag and various donor to acceptor ratio (w/w 1:1, 1:1.5, 1.2) were fabricated and evaluated (FIG. 8C-8G). As shown in the J-V characteristics, the current density does not vary significantly as a function of the ratio of donor to NFA (with the J_{SC} being all around 2.9˜3.3 mA/cm²). All three EQE spectra exhibited broad photo electron generation until 1200 nm. Increasing the loading of NFA from 1:1 to 1:1.5 led to a slight increase of EQE at NIR wavelengths; further increasing the NFA loading resulted in an EQE drop. Maximum EQE in the NIR region is at around 970 nm in all the spectra. Nevertheless, PTB7:TCIC-4X (X═F and C1) based devices demonstrated high potential for practical applications with over 20% of EQE at −4 V bias in the NIR range of 850˜1050 nm.

4. X-Ray diffraction Characterization

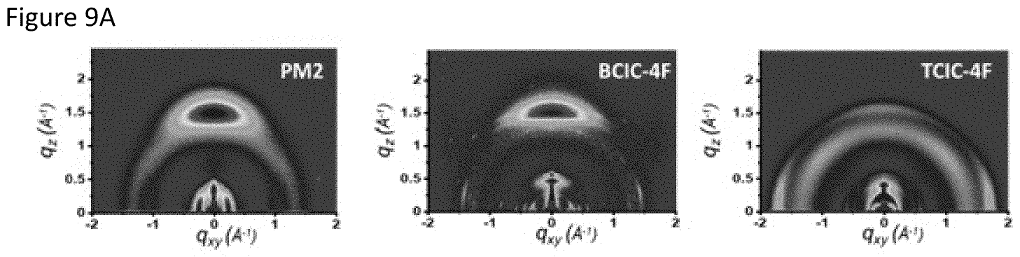

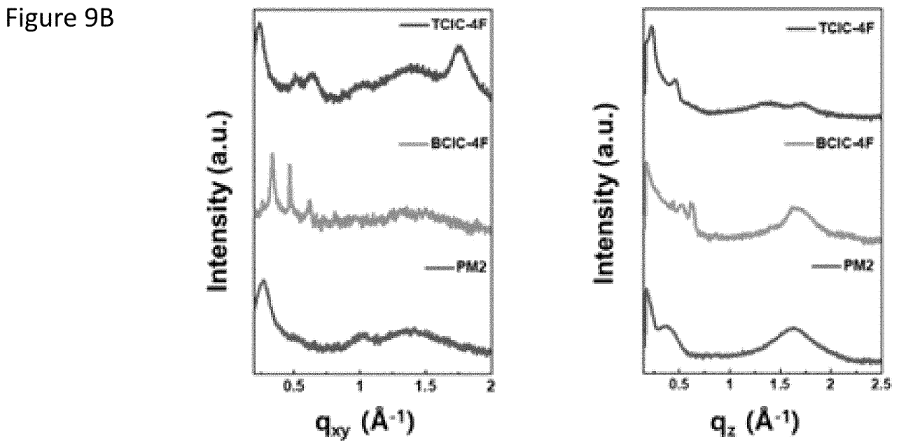

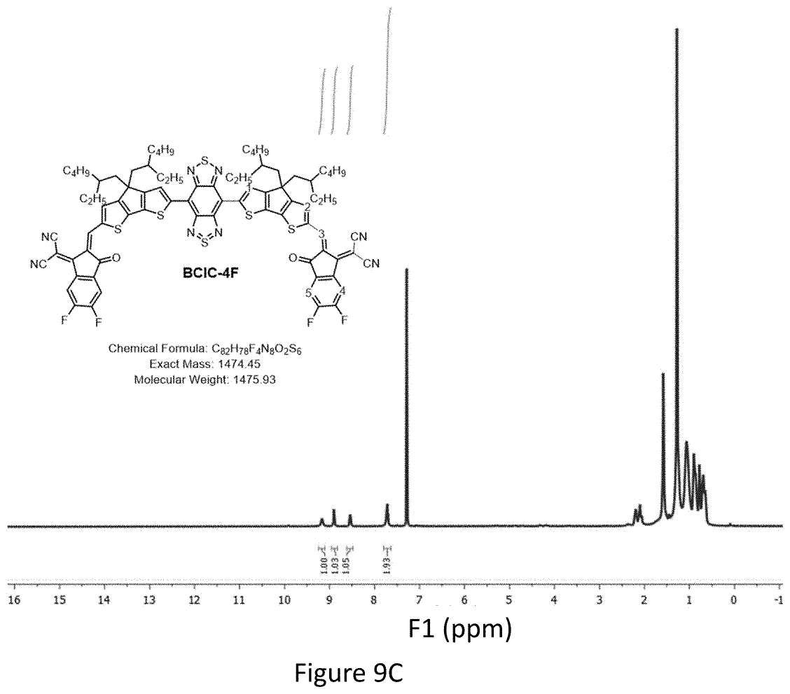

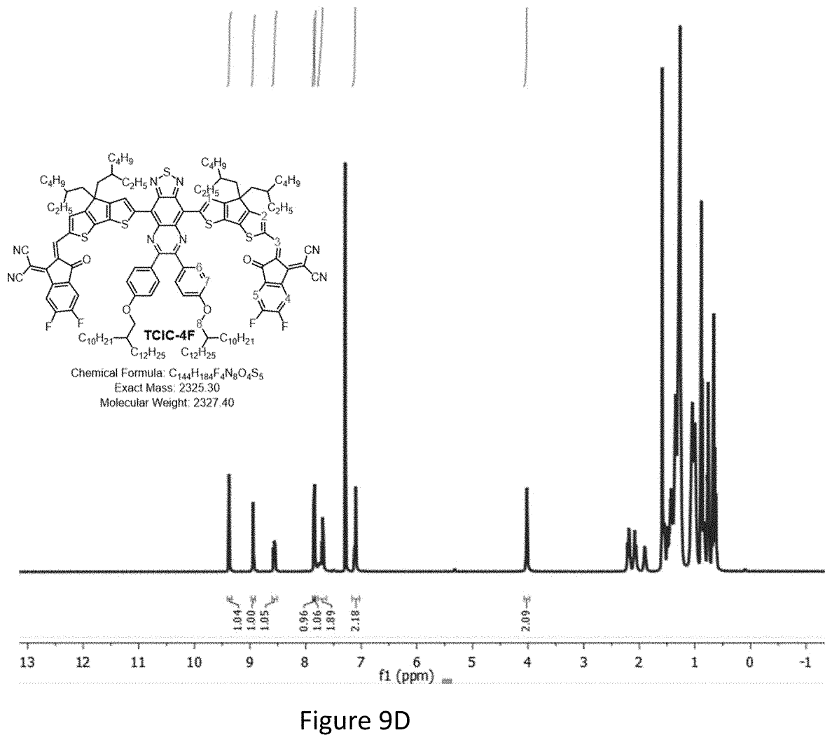

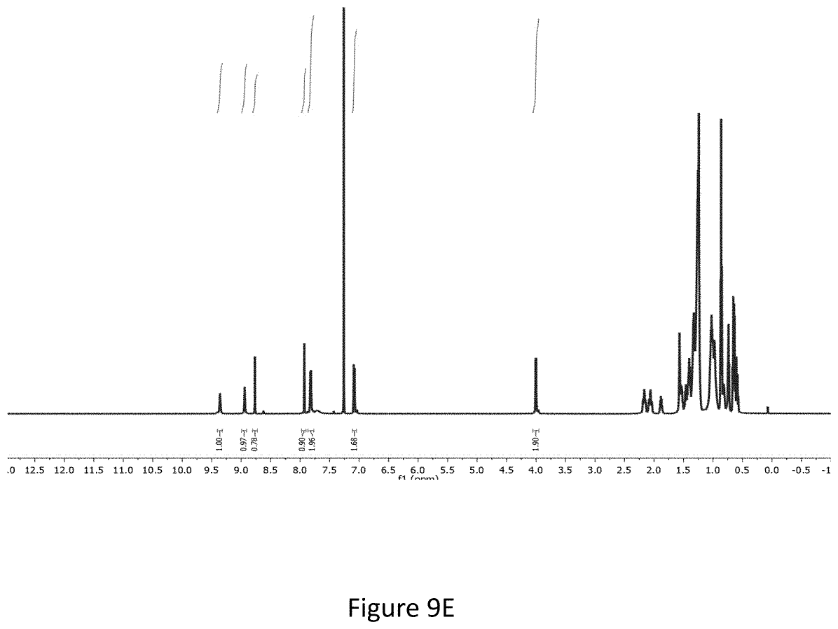

Grazing-incidence wide-angle X-ray scattering (GIWAXS) is sensitive to the crystalline phase and enables the determination of the molecular orientation. To investigate the molecular packing in pure PM2, BCIC-4F and TCIC-4F films, we carried out GIWAXS as shown in FIG. 9. Donor polymer PM2 exhibits a strong peak along the q_{z} axis with scattering vector of 1.62 Å⁻¹, indicating a vertical n-n stacking as a face-on orientation. Pure BCIC-4F film also exhibited face-on orientation with the multi-ordered lamellar stacking on q_{xy} direction. In contrast, pure TCIC-4F film showed strong n-n stacking peak along q_{xy} axis with scattering vector of 1.75 Å⁻¹, which indicates that the horizontal streak (edge-on) was observed.

5. Materials and Methods Used for the Synthesis and Testing of the Example Compositions Discussed in Sections 1-4 Using the Synthetic Route in FIGS. 1D and 1E

Materials All reagents and chemicals were purchased from commercial sources and used without further purification. All anhydrous organic solvents for the synthesis, characterization, and device fabrication steps were purchased from Sigma-Aldrich and TCI. Compounds 3, 8, 9 and 12 were purchased from SunaTech Inc. Compound 1 and 2 were prepared via a modified synthetic condition from literature.^{[1]}

Characterizations of compounds ¹H and ¹³C NMR spectra of intermediate monomers were recorded on a Varian Unity Inova 500 MHz spectrometer in deuterated chloroform solution (CDCl₃) with 0.003% TMS as internal reference. Ultraviolet-Visible-Near-infrared (UV-Vis-NIR) absorption spectra were recorded on a Perkin Elmer Lambda 750 spectrophotometer. For the measurements of thin films, materials were spun coated onto precleaned glass substrates from chloroform solutions (10 mg mL⁻¹). Optical band gap was determined from the absorption onset of the thin film samples.

Grazing incidence wide angle X-ray scattering (GIWAXS) analysis 2D GIWAXS measurements were performed using Beamline 9A at the Pohang Accelerator Laboratory (PAL).

The photon energy is 11.055 keV (λ=1.1214 Å). The angle between the film surface and the incident beam was fixed at 0.12° for all of the samples. The measurements were obtained at scanning intervals of 2θ between 3° and 25°. The 2D GIWAXS images from the films were analyzed according to the relationship between the scattering vector q and the d spacing, q=2π/d. The GIWAXS images shown are normalized with respect to exposure time.

Material Synthesis^{[2-4]}

Compound 4: A mixture of compound 3 (768 mg, 2 mmol), compound 2 (2.7 g, 4.8 mmol), Pd(PPh₃)₄ (47 mg) and anhydrous THF (20 mL) was added into a flame-dried and nitrogen-filled microwave tube in glovebox. The reactant was heated to 120° C. for 24 h. After the mixture was cooled to room temperature, DI water was added, and the mixture was extracted with dichloromethane (50 ml×3). The organic layer was dried over Na₂SO₄ and concentrated in vacuum. The crude product was purified by silica gel column chromatography (n-hexane:DCM, 9:1) to afford 4 as a deep blue solid (1.85 g, 90%). MS (MALDI-TOF): calculated m/z 1027.53; found m/z 1027.8.

¹H NMR for compound 4 (500 MHz, CDCl₃, ppm): δ 7.40 (t, 2H), 7.30 (d, 2H), 6.99 (m, 2H), 1.88-1.99 (m, 8H), 0.86-1.05 (m, 36H), 0.76-0.78 (m, 4H), 0.71-0.75 (m, 8H), 0.60-0.65 (m, 12H).

Compound 5: Compound 4 (740 mg, 0.72 mmol), Fe powder (504 mg, 9 mmol) and 20 mL Acetic Acid were added into a N₂ purged 50 mL round bottom flask. The reaction was heated to 80° C. overnight then cooled to room temperature and diluted with 100 mL DI water. The mixture was extracted with dichloromethane (50 ml×3), dried over K₂CO₃ and concentrated in vacuum to afford 5 as a yellow brown solid that was relatively pure by ¹H NMR and MALDI-TOF and used for the next step without further purification.

¹H NMR for compound 5 (500 MHz, CDCl₃, ppm): δ 7.15-7.28 (m, 2H), 7.17 (d, 2H), 6.97 (m, 2H), 4.48 (br, 4H), 1.90-1.99 (m, 8H), 1.00-1.10 (m, 36H), 0.85-0.90 (m, 4H), 0.71-0.80 (m, 8H), 0.62-0.68 (m, 12H). MS (MALDI-TOF): calculated m/z 966.48; found m/z 966.9.

Compound 6: Compound 5 (450 mg, 0.46 mmol) was dissolved in 5 mL anhydrous pyridine in a microwave tube, N-thionylaniline (131 mg, 0.94 mmol) and TMSCl (290 mg, 2.66 mmol) were added in the glovebox. The reaction was heated to 80° C. and stirred for 24 h. After cooling to room temperature, the reaction was diluted with DI water, extracted with dichloromethane (50 ml×3), dried over Na₂SO₄ and concentrated in vacuum. The crude product was purified by silica gel column chromatography (n-hexane:DCM, 6:1) to afford 6 as a yellow solid (260 mg, 56% for 2 steps).

¹H NMR for compound 6 (500 MHz, CDCl₃, ppm): δ 9.16 (m, 2H), 7.33 (d, 2H), 7.03 (m, 2H), 4.48 (br, 4H), 1.95-2.16 (m, 8H), 0.98-1.04 (m, 36H), 0.93-0.95 (m, 4H), 0.74-0.77 (m, 8H), 0.62-0.68 (m, 12H). MS (MALDI-TOF): calculated m/z 994.42; found m/z 995.6.

Compound 10: A mixture of compound 9 (240 mg, 0.2 mmol), compound 2 (284 mg, 0.5 mmol), Pd(PPh₃)₄ (11 mg) and anhydrous THF (10 mL) was added into a flame-dried and nitrogen-filled microwave tube in glovebox. The reactant was heated to 120° C. overnight. After the mixture cooled to room temperature, DI water was added, and the mixture was extracted with dichloromethane (50 ml×3). The organic layer was dried over Na₂SO₄ and concentrated in vacuum. The crude product was purified by silica gel column chromatography (n-hexane:DCM, 8:1) to afford 10 as a deep green solid (332 mg, 90%).

¹H NMR for compound 10 (500 MHz, CDCl₃, ppm): δ 9.17 (d, 2H), 7.83 (d, 4H), 7.22 (d, 2H), 7.01 (m, 4H), 6.99 (s, 2H), 3.94 (d, 4H) 1.93-2.09 (m, 8H), 1.82-1.87 (m, 6H), 1.2-1.44 (br, 74H), 0.93-1.06 (m, 32H), 0.74-0.89 (m, 26H), 0.60-0.65 (m, 16H). MS (MALDI-TOF): calculated m/z 1845.27; found m/z 1846.3.

The general procedure for the synthesis of bisaldehyde intermediate 7 and 11 is described as follows. To a flame-dried and nitrogen-filled one-neck round-bottom flask, POCl₃ and DMF were added in anhydrous Chloroform (CF) solvent at 0° C. The solution was reacted at 0° C. for 30 min, then a solution of compound 6 (or 10) in CF was added. The reactants were heated to reflux overnight, giving a red solution. The reaction was quenched by DI water and stirred for 30 min at room temperature. The mixture was extracted with ether (50 ml×3), washed by DI water. The organic layer was dried over Na₂SO₄ and concentrated in vacuum. The residue was purified by silica gel column chromatography.

Compound 7: Compound 6 (260 mg, 0.26 mmol), POCl₃ (0.50 mL), DMF (4.01 mL) and 10 mL of CF solvent were used for the reaction. The crude product was purified by using silica gel column chromatography (n-hexane:DCM, 6:4) to afford 7 as a deep yellow solid (260 mg, 94%).

¹H NMR for compound 7 (500 MHz, CDCl₃, ppm): δ 9.91 (s, 2H), 9.21 (m, 2H), 7.66 (t, 2H), 2.02-2.22 (m, 8H), 0.96-1.06 (m, 36H), 0.75-0.78 (m, 8H), 0.61-0.69 (m, 20H).

Compound 11: Compound 10 (266 mg, 0.144 mmol), POCl₃ (0.333 mL), DMF (2.2 mL) and 10 mL of CF solvent were used for the reaction. The crude product was purified by using silica gel column chromatography (n-hexane:DCM, 6:4) to afford 11 as a deep yellow solid (222 mg, 80%).

¹H NMR for compound 11 (500 MHz, CDCl₃, ppm): δ 9.88 (s, 2H), 9.25 (d, 2H), 7.82 (m, 4H), 7.62 (d, 2H), 6.01 (m, 4H), 3.95 (d, 4H) 1.99-2.15 (m, 8H), 1.83-1.87 (m, 6H), 1.26-1.34 (br, 74H), 0.92-1.06 (m, 32H), 0.74-0.89 (m, 26H), 0.55-0.66 (m, 16H).

The general procedure for the synthesis of final products (BCIC-4F, TCIC-4F and TCIC-4Cl) is described as follows. A mixture of bisaldehyde intermediate 7 (or 11), 2-(5,6-difluoro-3-oxo-2,3-dihydro-1H-inden-1-ylidene)malononitrile (compound 8), dry chloroform (20 mL), and pyridine was added into to a flame-dried and nitrogen-filled one-neck round-bottom flask. The flask was purged with N₂ for 20 min and the reactant was heated to 60° C. for 12 h. After the mixture cooled to room temperature, the reaction mixture was concentrated in vacuum. The residue was purified by silica gel column chromatography.

BCIC-4F: Compound 7 (170 mg, 0.162 mmol), compound 8 (124 mg, 0.54 mmol), pyridine (0.2 mL) and 30 mL of anhydrous CF solvent were used for the reaction. The crude product was purified by using silica gel column chromatography (n-hexane:DCM, 1:1) to afford BCIC-4F as a deep blue solid (160 mg, 67%).

¹H NMR for BCIC-4F (500 MHz, CDCl₃, ppm): δ 9.12 (s, 2H), 8.96 (s, 2H), 8.50 (m, 2H), 7.68 (m, 4H) 2.03-2.21 (m, 8H), 1.25 (s, 6H), 1.05 (br, m, 30H), 0.62-0.77 (m, 24H). MS (MALDI-TOF): calculated m/z 1475.93; found m/z 1475.48.

TCIC-4F: Compound 11 (200 mg, 0.103 mmol), compound 8 (80 mg, 0.35 mmol), pyridine (0.2 mL) and 40 mL of anhydrous CF solvent were used for the reaction. The crude product was purified by using silica gel column chromatography (n-hexane:DCM, 1:1) to afford TCIC-4F as a deep purple solid (175 mg, 72%).

¹H NMR for TCIC-4F (500 MHz, CDCl₃, ppm): 9.37 (t, 2H), 8.94 (s, 2H), 8.56 (q, 2H), 7.85 (t, 2H), 7.84 (t, 2H), 7.59 (t, 4H), 7.11 (m, 4H), 4.02 (d, 4H), 2.05-2.22 (m, 8H), 1.88-1.93 (m, 6H), 1.27-1.38 (br, 74H), 0.97-1.09 (m, 32H), 0.82-0.90 (m, 16H), 0.59-0.78 (m, 24H). MS (MALDI-TOF): calculated m/z 2325.3; found m/z 2326.3.

TCIC-4C: Compound 11(60 mg, 0.031 mmol), compound 12 (28 mg, 0.105 mmol), pyridine (0.07 mL) and 10 mL of anhydrous CF solvent were used for the reaction. The crude product was purified by using silica gel column chromatography (n-hexane:DCM, 1:1) to afford TCIC-4Cl as a deep purple solid (58 mg, 78%).

¹H NMR for TCIC-4C (500 MHz, CDCl₃, ppm): 9.36 (t, 2H), 8.94 (s, 2H), 8.77 (q, 2H), 7.93 (t, 2H), 7.83 (t, 2H), 7.81 (t, 4H), 7.08 (m, 4H), 4.00 (d, 4H), 2.01-2.20 (m, 8H), 1.86-1.92 (m, 6H), 1.20-1.37 (br, 74H), 0.91-1.01 (m, 32H), 0.78-0.90 (m, 16H), 0.57-0.67 (m, 24H).

### REFERENCES FOR METHODS SECTION

[1] G. C. Welch, R. C. Bakus, S. J. Teat, G. C. Bazan, J. Am. Chem. Soc. 2013, 135, 2298.
[2] D. G. (Dan) Patel, F. Feng, Y. Ohnishi, K. A. Abboud, S. Hirata, K. S. Schanze, J. R. Reynolds, J. Am. Chem. Soc. 2012, 134, 2599.
[3] H. Yao, Y. Chen, Y. Qin, R. Yu, Y. Cui, B. Yang, S. Li, K. Zhang, J. Hou, Advanced Materials 2016, 28, 8283.

### Example Process Steps

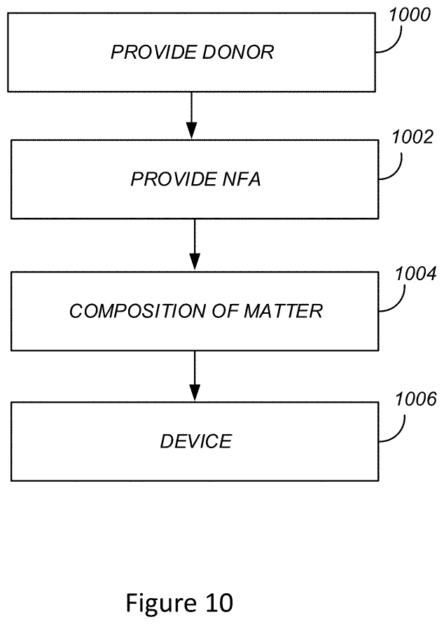

FIG. 10 is a flowchart illustrating a method of making a composition of matter and/or a device.

Block 1000 represents optionally providing one or more donors (e.g., electron donors).

In one or more examples of this invention, the semiconductor donor compound comprises a conjugated main chain section, the conjugated main chain section having a repeating donor unit (D1) comprises a dithiophene structure.

In one or more embodiments, the repeating donor unit of the semiconductor compound comprises the structure:

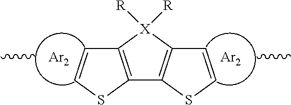

wherein each Ar₂ is independently a substituted or non-substituted aromatic functional group, or each Ar₂ is nothing and the valence of the ring is completed with hydrogen. In some embodiments, the Ar₂ groups can be the same. Each R is independently hydrogen or a substituted or non-substituted alkyl, aryl, alkoxy or thioether chain. In some embodiments, the R groups can be the same. X is C, Si, Ge, N or P. In some embodiments, the R comprising the substituted or non-substituted alkyl, aryl, alkoxy or thioether chain can be a C₆-C₅₀ substituted or non-substituted chain, —(CH₂CH₂O)ₙ (n=2˜20), C₆H₅, —CₙF₍₂ₙ₊₁₎ (n=2˜20), —(CH₂)ₙN(CH₃)₃Br (n=2˜20), 2-ethylhexyl, PhCₘH₂ₘ₊₁ (m=1-20), —(CH₂)ₙN(C₂H₅)₂ (n=2˜20), —(CH₂)ₙSi(CₘH₂ₘ₊₁)₃ (m, n=1 to 20), or —(CH₂)ₙSi(OSi(CₘH₂ₘ₊₁)₃)ₓ (CₚH₂ₚ₊₁)_{y} (m, n, p=1 to 20, x+y=3).

In one or more embodiments, the donor unit comprises:

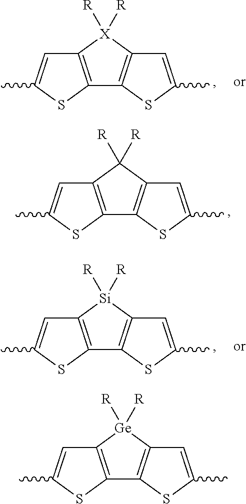

In one or more embodiments, the semiconductor donor compound is a polymer.

In one or more embodiments, the semiconductor compound comprises a conjugated main chain section, the conjugated main chain section having a repeating acceptor unit (A) that comprises the structure:

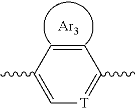

wherein each Ar₃ is independently a substituted or non-substituted aromatic functional group, or each Ar₃ is nothing and the valence of the ring is completed with hydrogen. Each T is N, C—H, C—F or C—Cl.

In one or more embodiments, the semiconductor compound comprises a conjugated main chain section, the conjugated main chain section having an acceptor unit (A) that comprises the structure:

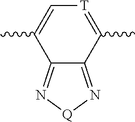

wherein each T is C—H, N, C—F or C—Cl, and Q is O, S, Se or N—R₄, Each R₄ is independently hydrogen or a substituted or non-substituted alkyl or aryl chain.

In one or more embodiments, the acceptor unit comprises:

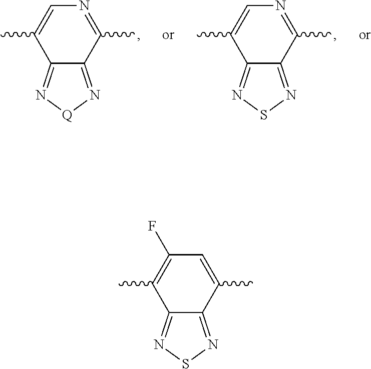

In one or more embodiments, the acceptor unit is regioregularly arranged along the conjugated main chain section.

In one or more embodiments, the semiconductor donor compound is a polymer.

In one or more embodiments, the semiconductor compound comprises a conjugated main chain section, the conjugated main chain section further comprises a second donor unit (D2) that comprises the structure:

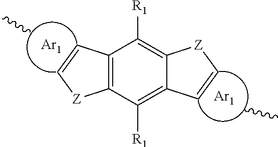

wherein each Ar₁ is independently a substituted or non-substituted aromatic functional group, or each Ar₁ is nothing and the valence of the ring is completed with hydrogen. In some embodiments, the Ar₁ groups can be the same. Each R₁ and R₄ is independently hydrogen or a substituted or non-substituted alkyl, aryl, alkoxy or thioether chain. In some embodiments, the R₁ groups can be the same. Each Z is independently O, S, Se, or N—R₄. In some embodiments, the Z groups can be the same. The R₁ and R₄ comprising the substituted or non-substituted alkyl, aryl, alkoxy or thioether chain can be a C₆-C₅₀ substituted or non-substituted chain, —(CH₂CH₂O)ₙ (n=2˜20), C₆H₅, —CₙF₍₂ₙ₊₁₎ (n=2˜20), —(CH₂)ₙN(CH₃)₃Br (n=2˜20), 2-ethylhexyl, PhCₘH₂ₘ₊₁ (m=1-20), —(CH₂)ₙN(C₂H₅)₂ (n=2˜20), —(CH₂)ₙSi(CₘH₂ₘ₊₁)₃ (m, n=1 to 20), or —(CH₂)ₙSi(OSi(CₘH₂ₘ₊₁)₃)ₓ(CₚH₂ₚ₊₁)_{y} (m, n, p=1 to 20, x+y=3).

In one or more embodiments, the second donor unit comprises:

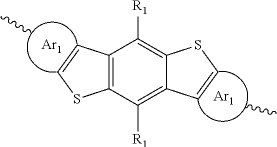

In one or more embodiments, the second donor unit comprises:

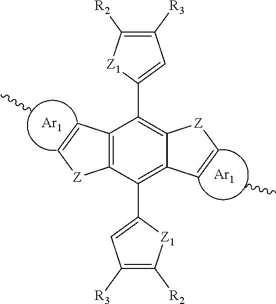

wherein each Ar₁ is independently a substituted or non-substituted aromatic functional group, or each Ar₁ is nothing and the valence of the ring is completed with hydrogen. In some embodiments, the Ar₁ groups can be the same. Each R₂, R₃ and R₄ is independently hydrogen or a substituted or non-substituted alkyl, aryl, alkoxy or thioether chain. In some embodiments, the R₂ groups can be the same. In some embodiments, the R₃ groups can be the same. Each Z and Z₁ is independently O, S, Se, or N—R₄. In some embodiments, the Z groups can be the same. In some embodiments, the Z₁ groups can be the same.

In one or more embodiments, the second donor unit comprises:

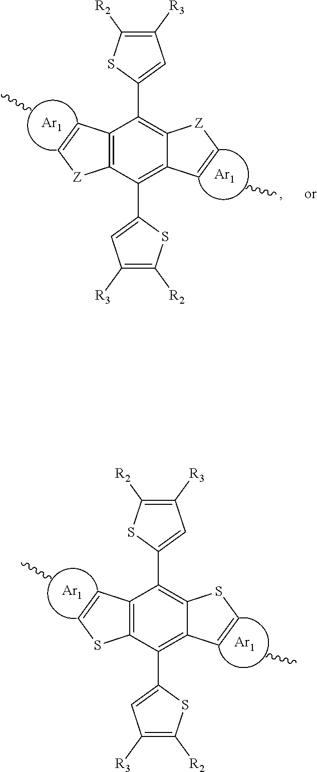

In one or more embodiments, the second donor unit comprises.

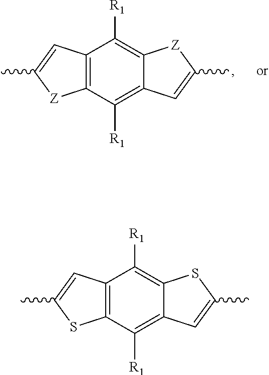

In one or more embodiments, the second donor unit comprises:

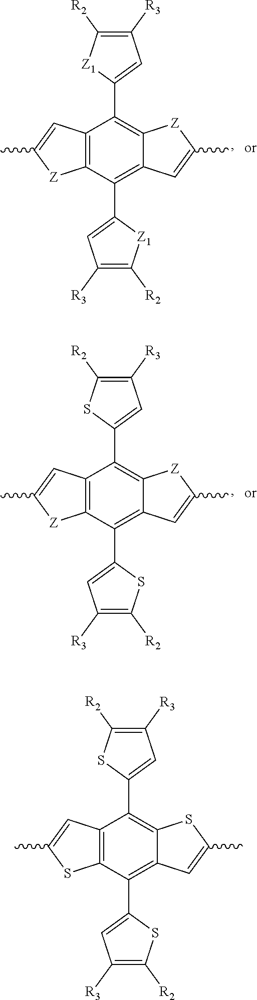

In one or more embodiments, the second donor unit comprises:

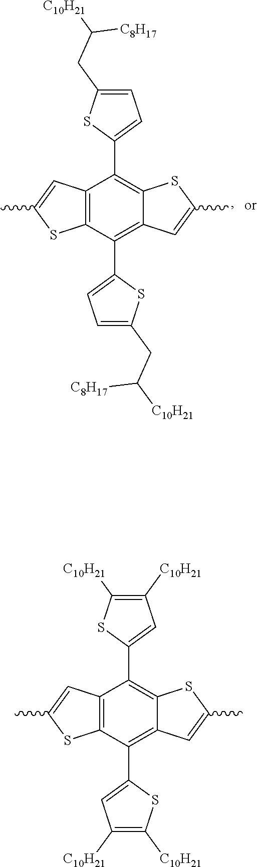

In one or more embodiments, the semiconductor donor compound is a polymer.

In one or more embodiments, the semiconductor donor compound comprises a conjugated main chain section, the conjugated main chain section further comprises a second donor unit (D2) that comprises the structure:

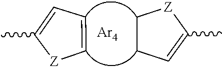

wherein each Ar₄ is independently a substituted or non-substituted aromatic functional group, or each Ar₄ is nothing and the valence of the ring is completed with hydrogen. In some embodiments, the Ar₄ groups can be the same. Each Z is independently O, S, Se, or N—R₄. Each R₄ is independently hydrogen or a substituted or non-substituted alkyl, aryl, alkoxy or thioether chain.

In one or more embodiments, the second donor unit comprises.

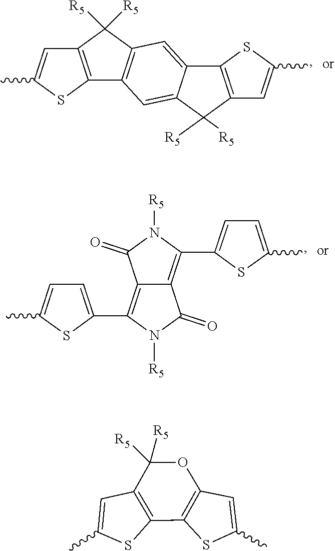

where R5 can be independently hydrogen or a substituted or non-substituted alkyl, aryl, alkoxy or thioether chain, for example. In one or more embodiments, the semiconductor donor compound is a polymer.

In one or more embodiments, the semiconductor compound comprises a conjugated main chain section, the conjugated main chain section having a D1-A structure, where D1 is a first donor unit and A is an acceptor unit (e.g., having the compositions described herein in Block 1000).

In one or more embodiments, the semiconductor compound comprises a conjugated main chain section, the conjugated main chain section having a D1-A structure that comprises the structure:

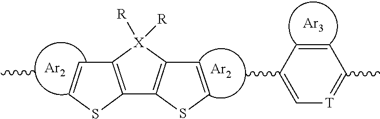

wherein each Ar₂ and Ar₃ is independently a substituted or non-substituted aromatic functional group, or each Ar₂ and Ar₃ is nothing and the valence of the ring is completed with hydrogen. In some embodiments, the Ar₂ groups can be the same. In some embodiments, the Ar₃ groups can be the same. Each R is independently hydrogen or a substituted or non-substituted alkyl, aryl, alkoxy or thioether chain. In some embodiments, the R groups can be the same. X is C, Si, Ge, N or P. T is C—H, N, C—F or C—Cl.

In one or more embodiments, the acceptor unit is regioregularly arranged along the conjugated main chain section.

In one or more embodiments, the conjugated main chain section comprises:

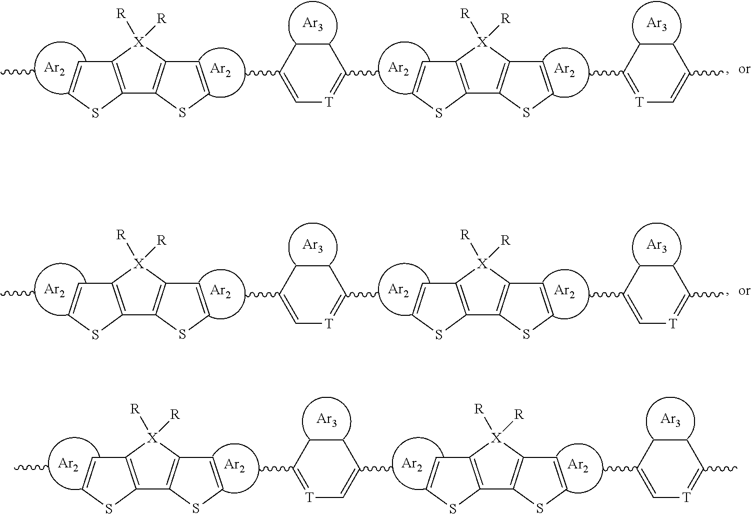

wherein the acceptor unit is regioregularly arranged along the conjugated main chain section as shown in the structure.

In one or more embodiments, the conjugated main chain section comprises:

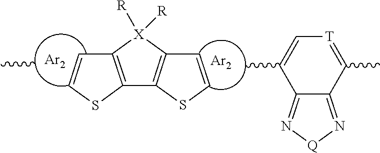

wherein each Ar₂ is independently a substituted or non-substituted aromatic functional group, or each Ar₂ is nothing and the valence of the ring is completed with hydrogen. In some embodiments, the Ar₂ groups can be the same. Each R and R₄ is independently hydrogen or a substituted or non-substituted alkyl, aryl, alkoxy or thioether chain. In some embodiments, the R groups can be the same. X is C, Si, Ge, N or P. T is C—H, N, C—F or C—Cl. Q is O, S, Se or N—R₄.

In one or more embodiments, the conjugated main chain section comprises:

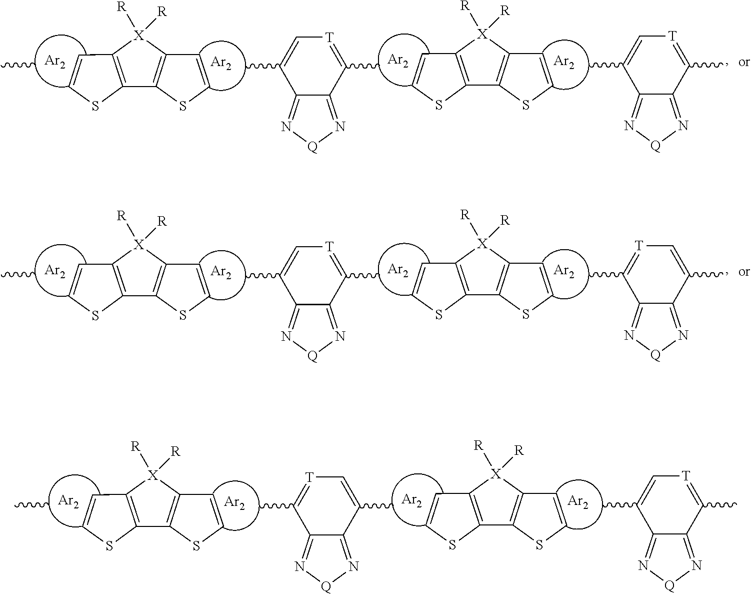

wherein the acceptor unit is regioregularly arranged along the conjugated main chain section as shown in the structure.

In one or more embodiments, the conjugated main chain section comprises:

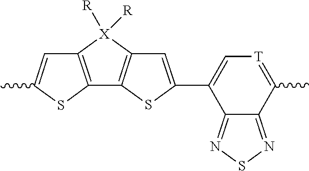

Each R is independently hydrogen or a substituted or non-substituted alkyl, aryl, alkoxy or thioether chain. In some embodiments, the R groups can be the same. X is C, Si, Ge, N or P. T is C—H, N, C—F or C—Cl.

In one or more embodiments, the conjugated main chain section comprises:

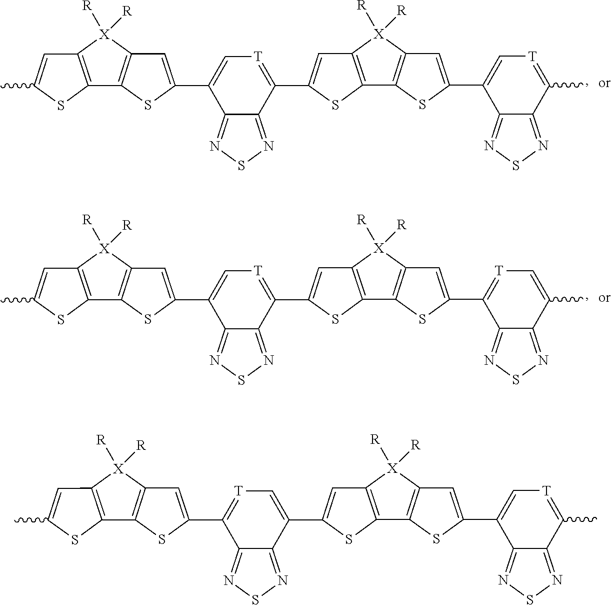

In one or more embodiments, the acceptor unit is regioregularly arranged along the conjugated main chain section.

In one or more embodiments, the conjugated main chain section comprises:

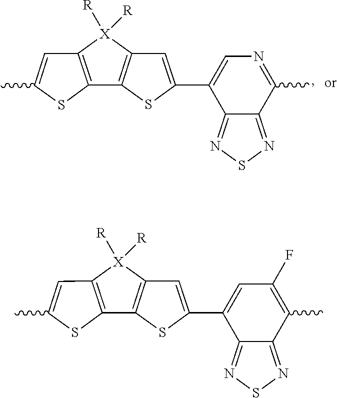

In one or more embodiments, the conjugated main chain section comprises:

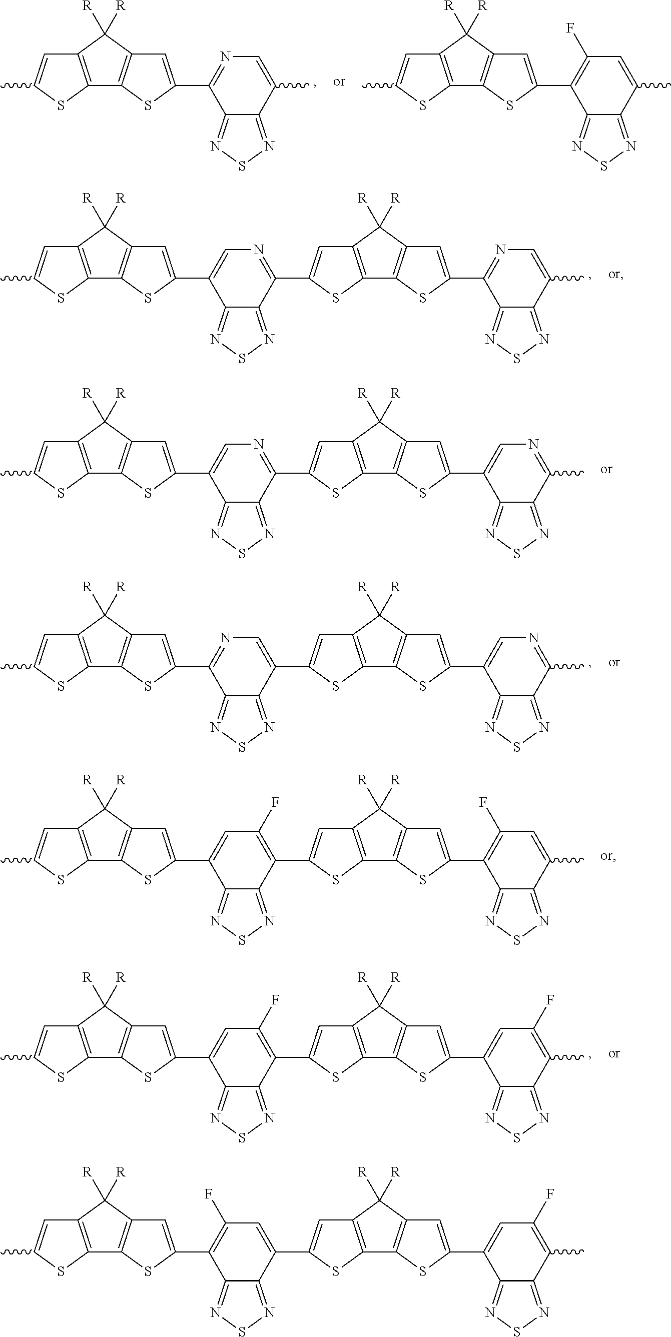

In one or more embodiments, the acceptor unit is regioregularly arranged along the conjugated main chain section.

In one or more embodiments, the semiconductor compound is a semiconductor polymer.

In one or more embodiments, the semiconductor polymer comprises the structure:

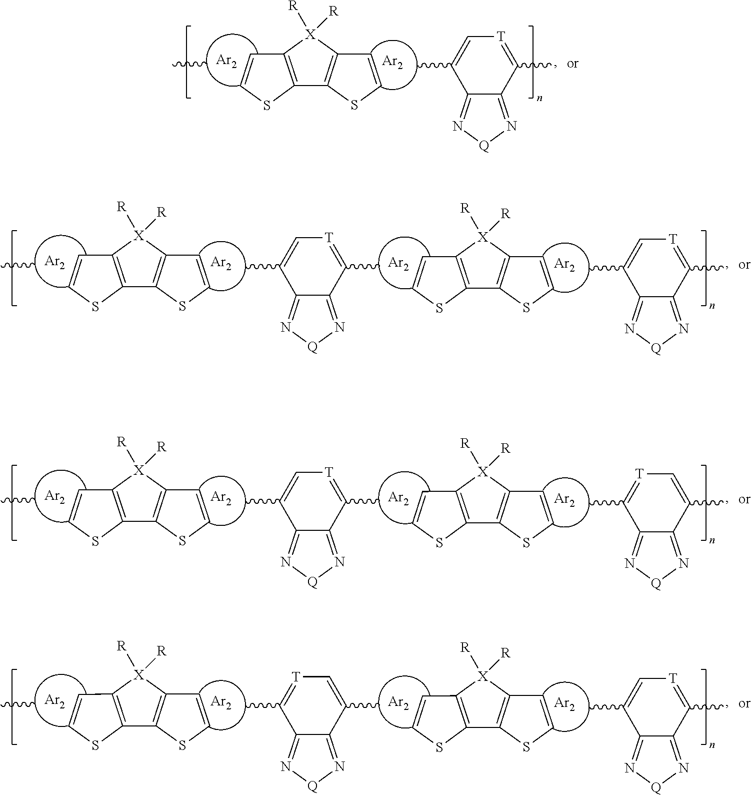

wherein each Ar₂ s independently a substituted or non-substituted aromatic functional group, or each Ar₂ is nothing and the valence of the ring is completed with hydrogen. In some embodiments, the Ar₂ groups can be the same. Each R and R₄ is independently hydrogen or a substituted or non-substituted alkyl, aryl, alkoxy or thioether chain. In some embodiments, the R groups can be the same. X is C, Si, Ge, N or P. T is C—H, N, C—F or C—Cl. Q is O, S, Se or N—R₄. n is an integer.

In one or more embodiments, the acceptor unit is regioregularly arranged along the semiconductor polymer backbone.

In one or more embodiments, the semiconductor polymer comprises the structure:

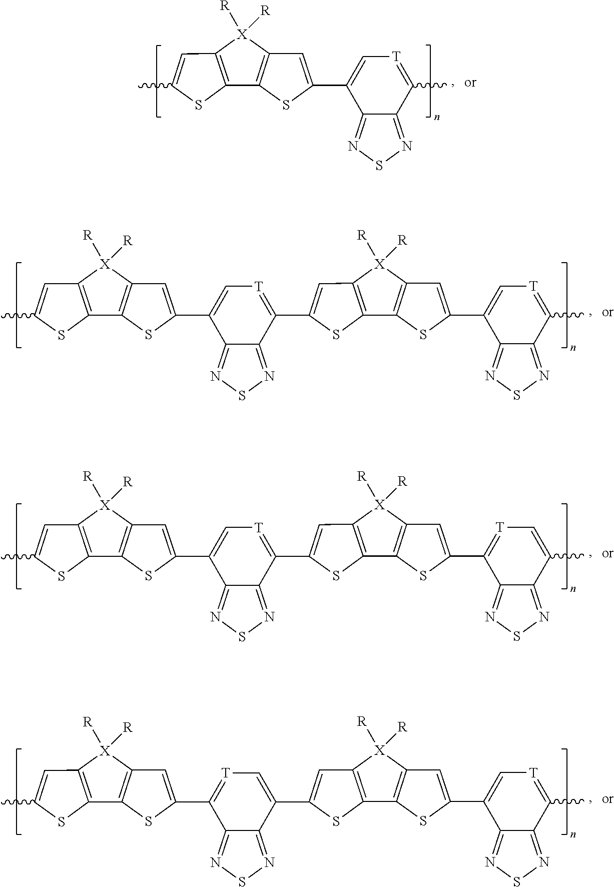

Wherein each R is independently hydrogen or a substituted or non-substituted alkyl, aryl, alkoxy or thioether chain. In some embodiments, the R groups can be the same. X is C, Si, Ge, N or P. T is C—H, N, C—F or C—Cl.

In one or more embodiments, the acceptor unit is regioregularly arranged along the semiconductor polymer backbone.

In one or more embodiments, the semiconductor polymer comprises the structure:

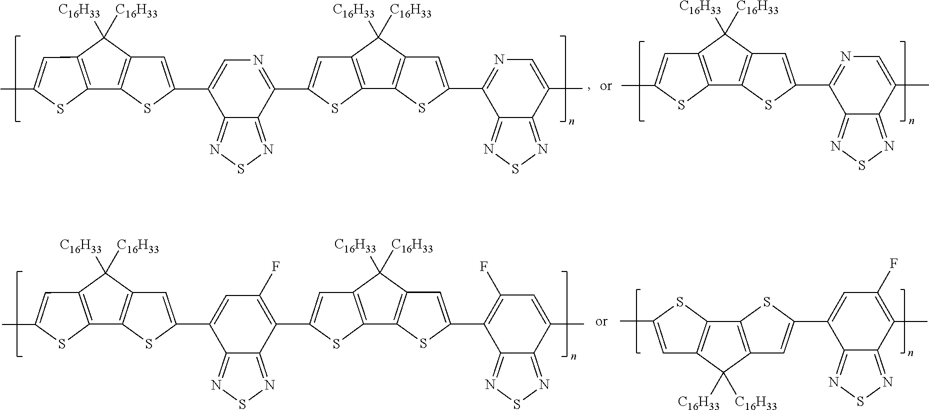

In one or more embodiments, the acceptor unit is regioregularly arranged along the semiconductor polymer backbone.

In one or more embodiments, the semiconducting compound further comprising the structure:

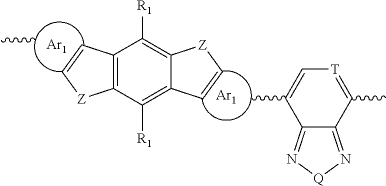

wherein:

each Ar₁ is independently a substituted or non-substituted aromatic functional group, or each Ar₁ is nothing and the valence of the ring is completed with hydrogen. each Z is independently O, S, Se, or N—R₄; each R₁, R₄ is independently hydrogen or a substituted or non-substituted alkyl, aryl, alkoxy or thioether chain. each Q is independently O, S Se, or N—R₄: T is C—H, N, C—F, or C—Cl.

In one or more embodiments, the semiconducting compound further comprising the structure:

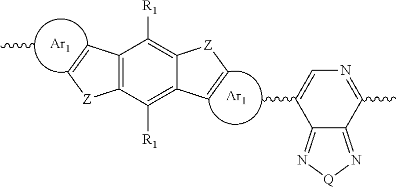

In one or more embodiments, the semiconductor compound comprises a conjugated main chain section, the conjugated main chain section having a DI-A-D2-A structure, while D1 is a first donor unit, D2 is a second donor unit, A is an acceptor unit.

In one or more embodiments, the semiconductor compound comprises a conjugated main chain section, the conjugated main chain section having a D1-A-D2-A structure that comprises the structure:

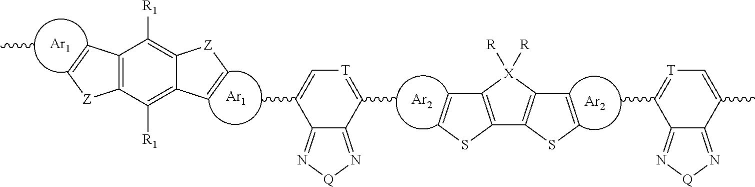

wherein each Ar₁ and Ar₂ is independently a substituted or non-substituted aromatic functional group, or each Ar₁ and Ar₂ is nothing and the valence of the ring is completed with hydrogen. In some embodiments, the Ar₁ groups can be the same. In some embodiments, the Ar₂ groups can be the same. Each R, R₁ and R₄ is independently hydrogen or a substituted or non-substituted alkyl, aryl, alkoxy or thioether chain. In some embodiments, the R groups can be the same. In some embodiments, the R₁ groups can be the same. Each Z is independently O, S, Se, or N—R₄. In some embodiments, the Z groups can be the same. X is C, Si, Ge, N or P; T is C—H, N, C—F, or C—Cl, and Q is O, S, Se or N—R₄. In one or more embodiments, the acceptor unit is regioregularly arranged along the conjugated main chain section as shown in the structure.

In one or more embodiments, the conjugated main chain section comprises:

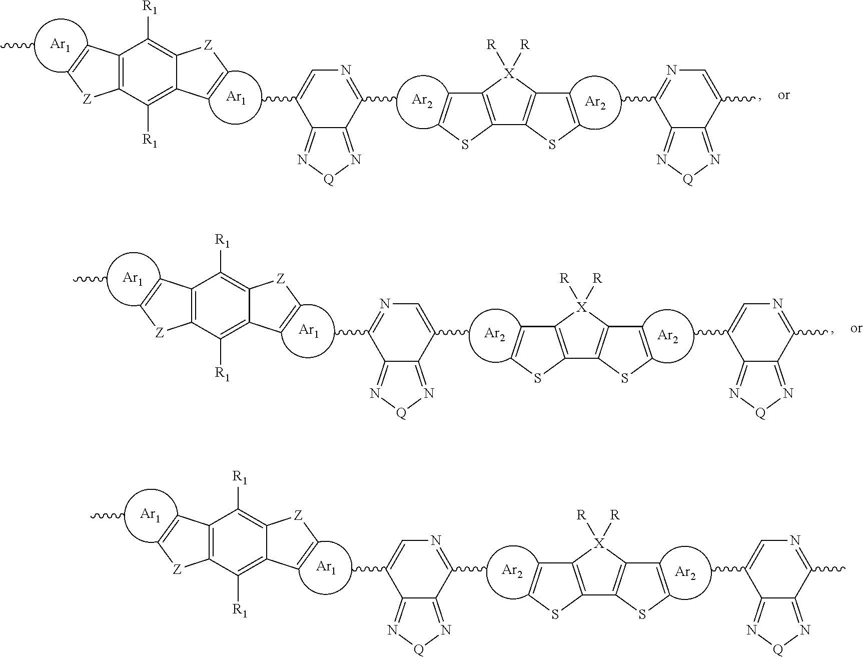

wherein the acceptor unit is regioregularly arranged along the conjugated main chain section as shown in the structure.

In one or more embodiments, the conjugated main chain section comprises:

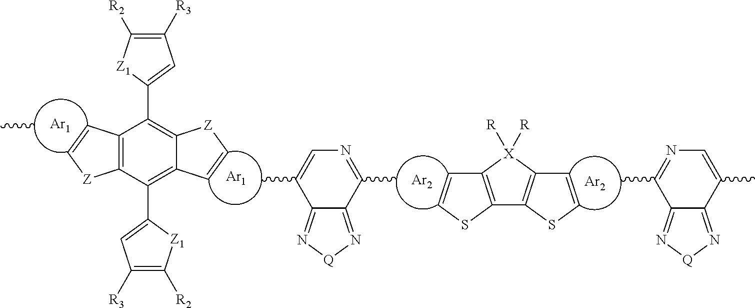

wherein each Ar₁ and Ar₂ is independently a substituted or non-substituted aromatic functional group, or each Ar₁ and Ar₂ is nothing and the valence of the ring is completed with hydrogen. In some embodiments, the Ar₁ groups can be the same. In some embodiments, the Ar₂ groups can be the same. Each R, R₂, R₃ and R₄ is independently hydrogen or a substituted or non-substituted alkyl, aryl, alkoxy or thioether chain. In some embodiments, the R groups can be the same. In some embodiments, the R₂ groups can be the same. In some embodiments, the R₃ groups can be the same. Each Z and Z₁ is independently O, S, Se, or N—R₄. In some embodiments, the Z groups can be the same. In some embodiments, the Z₁ groups can be the same. X is C, Si, Ge, N or P, and Q is O, S, Se or N—R₄. In one or more embodiments, the acceptor unit is regioregularly arranged along the conjugated main chain section as shown in the structure.

In one or more embodiments, the conjugated main chain section comprises:

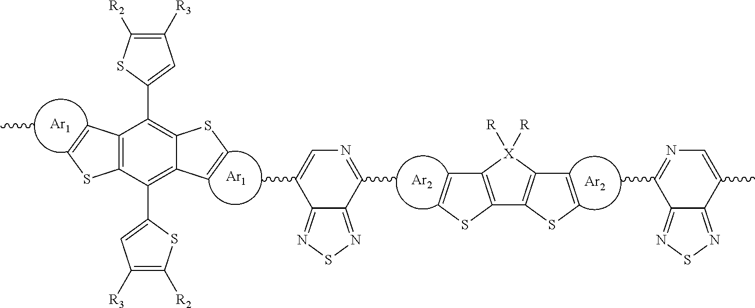

In one or more embodiments, the conjugated main chain section comprises:

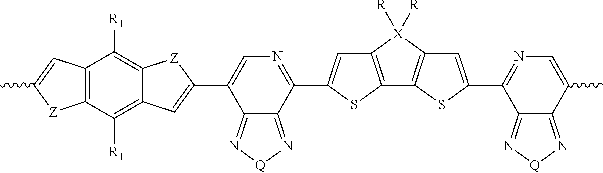

wherein each R, R₁ and R₄ is independently hydrogen or a substituted or non-substituted alkyl, aryl, alkoxy or thioether chain. In some embodiments, the R groups can be the same. In some embodiments, the R₁ groups can be the same. Each Z is independently O, S, Se, or N—R₄. In some embodiments, the Z groups can be the same. X is C, Si, Ge, N or P, and Q is O, S Se, or N—R₄. In one or more embodiments, the acceptor unit is regioregularly arranged along the conjugated main chain section as shown in the structure.

In one or more embodiments, the conjugated main chain section comprises:

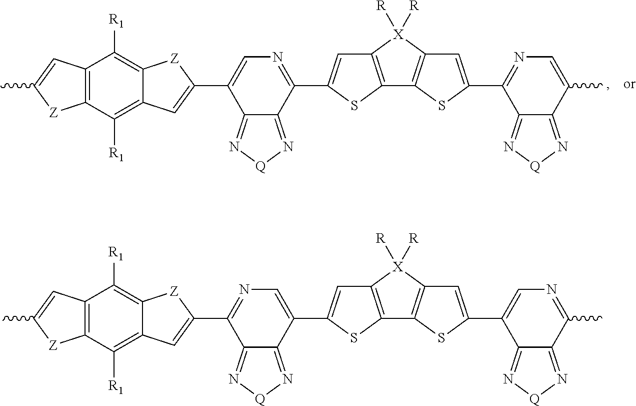

wherein the acceptor unit is regioregularly arranged along the conjugated main chain section as shown in the structure.

In one or more embodiments, the conjugated main chain section comprises:

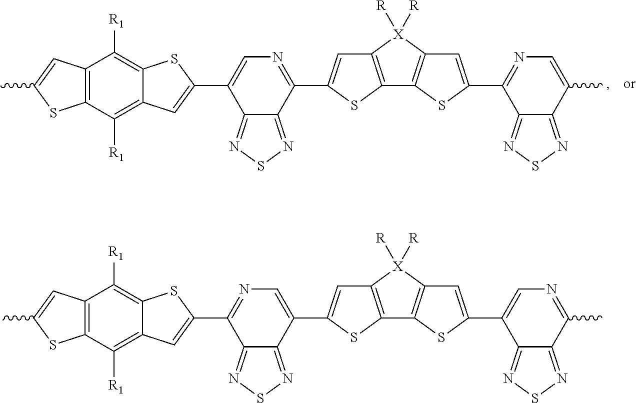

In one or more embodiments, the conjugated main chain section comprises:

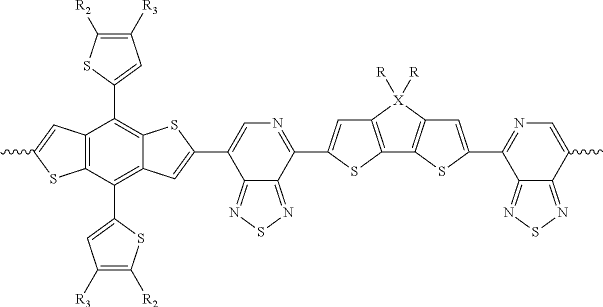

wherein each R, R₂ and R₃ is independently hydrogen or a substituted or non-substituted alkyl, aryl, alkoxy or thioether chain. In some embodiments, the R groups can be the same. In some embodiments, the R₂ groups can be the same. In some embodiments, the R₃ groups can be the same. X is C, Si, Ge, N or P. In one or more embodiments, the acceptor unit is regioregularly arranged along the conjugated main chain section as shown in the structure.

In one or more embodiments, the conjugated main chain section comprises:

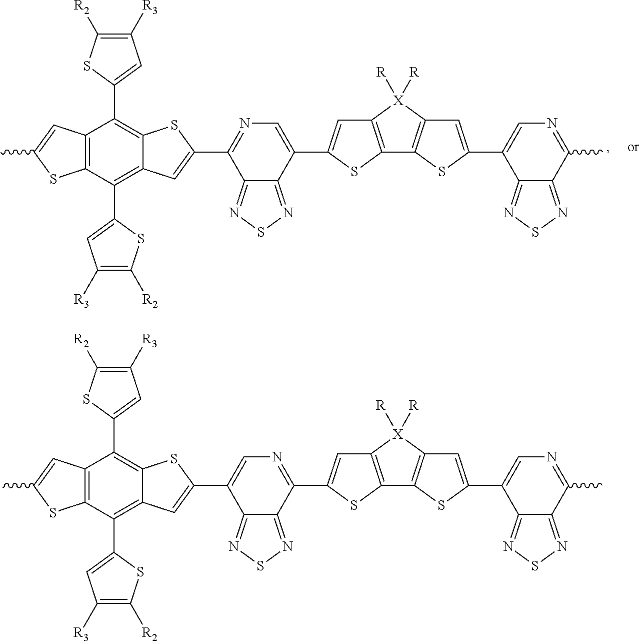

wherein the acceptor unit is regioregularly arranged along the conjugated main chain section as shown in the structure.

In one or more embodiments, the conjugated main chain section comprises:

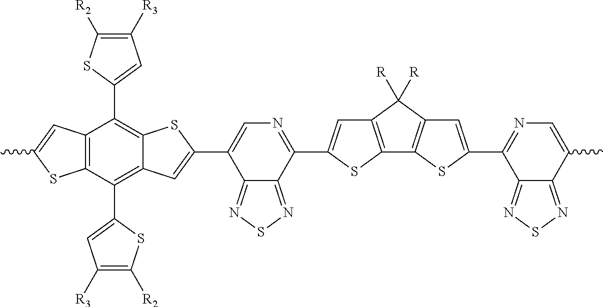

In one or more embodiments, the semiconductor compound is a semiconductor polymer.

In one or more embodiments, the semiconductor polymer comprises.

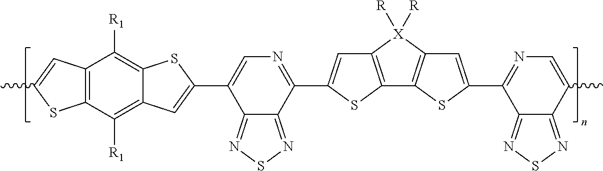

wherein each R and R₁ is independently hydrogen or a substituted or non-substituted alkyl, aryl, alkoxy or thioether chain. In some embodiments, the R groups can be the same. In some embodiments, the R₁ groups can be the same. X is carbon (C), silicon (Si), germanium (Ge), nitrogen (N) or phosphorus (P). In one or more embodiments, the acceptor unit is regioregularly arranged along the conjugated main chain section as shown in the structure.

In one or more embodiments, the semiconductor polymer comprises:

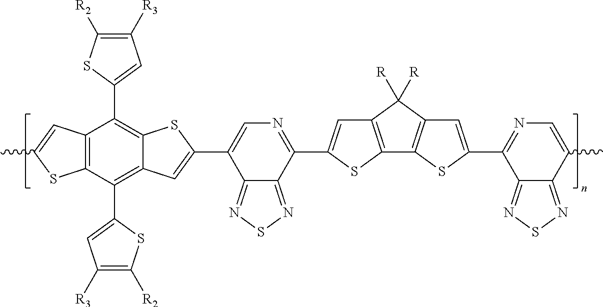

wherein each R, R₂ and R₃ is independently hydrogen or a substituted or non-substituted alkyl, aryl, alkoxy or thioether chain. In some embodiments, the R groups can be the same. In some embodiments, the R₂ groups can be the same. In some embodiments, the R₃ groups can be the same. In one or more embodiments, the acceptor unit is regioregularly arranged along the conjugated main chain section as shown in the structure.

In one or more embodiments, the semiconductor polymer comprises:

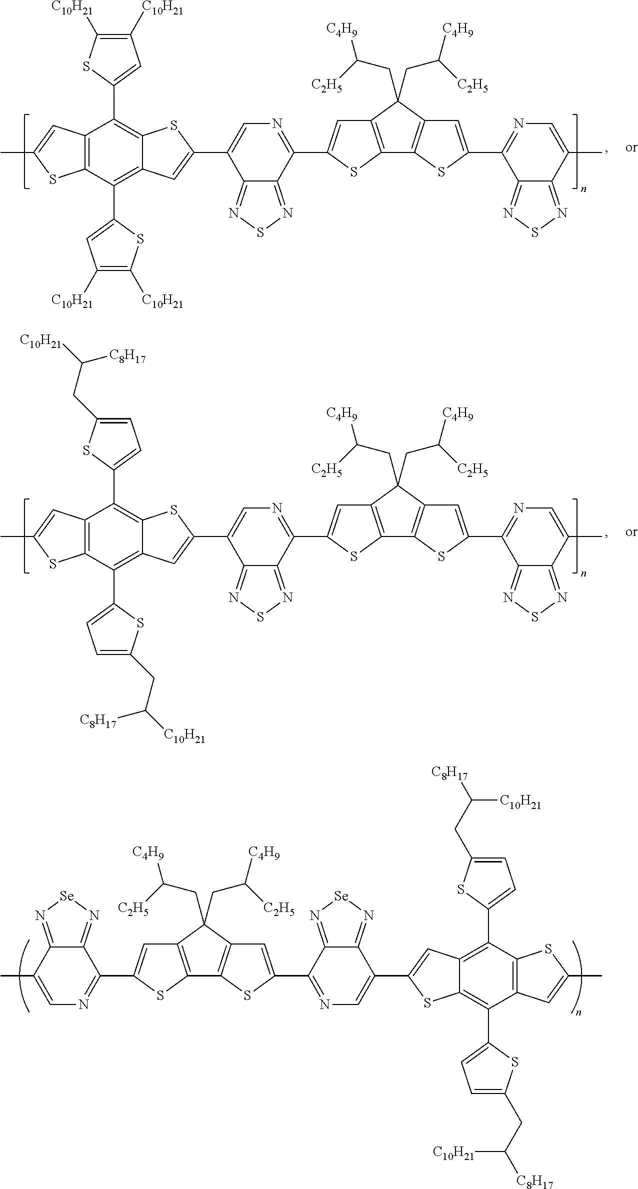

In one or more embodiments, the semiconductor donor polymer comprises a conjugated main chain section, the conjugated main chain section having a repeating unit of D1-A-D2-A structure, while D1 is a first donor unit with strong electron donating capability, D2 is a second donor unit with weaker electron donating capability, A is a strong acceptor unit. Such backbone structures can tune the optical bandgap, HOMO-LUMO levels and yield well-ordered polymer crystallite phases in thin films.

In one or more embodiments, the semiconductor donor compound is a small molecule donor comprises the structure of E-A-(D1-A)ₙ-E, while D1 can be selected from any of the above listed first donor units, and A can be selected from any of the above listed acceptor units. n=1-10. E is a terminal end group which can be independently hydrogen or a substituted or non-substituted alkyl, aryl or alkoxy group.

In one or more embodiment, the small molecule donor comprises the structure of E-A-(D1-A)ₙ-E, while D1 is

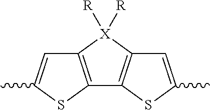

### and A is

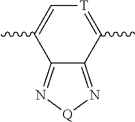

wherein each R and R₄ is independently hydrogen or a substituted or non-substituted alkyl, aryl, alkoxy or thioether chain. X is C, Si, Ge, N or P. T is C—H, N, C—F or C—Cl, and Q is O, S, Se or N—R₄, E is an alkylated bithiophene, n=1, 2, 3, 4 or 5. Each T can be the same or different. Each X can be the same or different.

In one or more embodiment the small molecule donor comprises the structure:

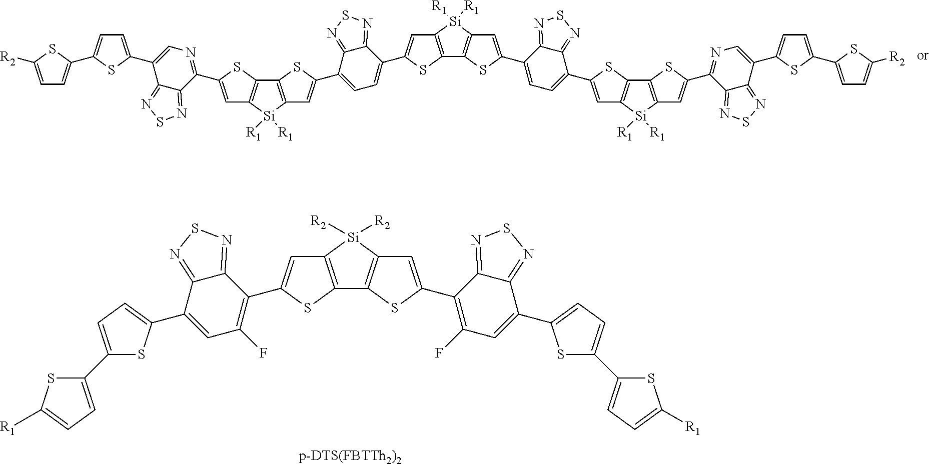

wherein each R₁ and R₂ is independently hydrogen or a substituted or non-substituted alkyl, aryl, alkoxy or thioether chain. In one or more embodiments, R₁ is 2-ethylhexyl, and R₂ is hexyl. In another embodiment, R₂ is 2-ethylhexyl, and R₁ is hexyl.

The R, R₁, R₂, R₃ and R₄ groups can be a linear or branched side-chain comprising a C₃-C₅₀, C₅-C₅₀, C₈-C₅₀, or C₉-C₅₀ substituted or non-substituted alkyl chain. Examples of alkyl chains include isopropyl, sec-butyl, t-butyl, 1,2-dimethylpropyl, 1,1-dimethyl-propyl, 4-methylpentyl, 1-methylpentyl, 2-methylpentyl, 3-methylpentyl, 1,1-dimethylbutyl, 2,2-dimethylbutyl, 3,3-dimethylbutyl, 1,2-dimethylbutyl, 1,3-dimethylbutyl, 1,2,2-trimethylpropyl, 1,1,2-trimethylpropyl, 5-methylhexyl, 1-methylhexyl, 2,2-dimethylpentyl, 3,3-dimethylpentyl, 4,4-dimethylpentyl, 1,2-dimethylpentyl, 1,3-dimethylpentyl, 1,4-dimethylpentyl, 1,2,3-trimethylbutyl, 1,1,2-trimethylbutyl, 1,1,3-trimethylbutyl, 6-methylheptyl, 1-methylheptyl, 1,1,3,3-tetramethylbutyl, 1-, 2-, 3-, 4-, 5-, 6- or 7-methyloctyl, 1-, 2-, 3-, 4- or 5-ethylheptyl, 1-, 2- or 3-propylhexyl, 1-, 2-, 3-, 4-, 5-, 6-, 7- and 8-methylnonyl, 1-, 2-, 3-, 4-, 5- or 6-ethyloctyl, 1-, 2-, 3- or 4-propylheptyl, dimethyloctyl, 1-, 2-, 3-, 4-, 5-, 6-, 7-, 8- or 9-methyldecyl, 1-, 2-, 3-, 4-, 5-, 6- or 7-ethylnonyl, 1-, 2-, 3-, 4- or 5-propyloctyl, 1-, 2- or 3-butylheptyl, 1-pentylhexyl, 1-2-, 3-, 4-, 5-, 6-, 7-, 8-, 9- or 10-methylundecyl, 1-, 2-, 3-, 4-, 5-, 6-, 7- or 8-ethyldecyl, 1-, 2-, 3-4-, 5- or 6-propylnonyl, 1-, 2-, 3- or 4-butyloctyl, 1-, 2-pentylheptyl, branched butyl, pentyl, hexyl, heptyl, octyl, nonyl, decyl, undecyl, dodecyl, tridecyl, tetradecyl, pentadecyl, hexadecyl, heptadecyl, octadecyl, nonoadecyl, eicosyl with one or more branch points at any carbon of the alkyl chain, such as 2 (or 1, or 3, or 4)-ethylhexyl, 2 (or 1, or 3, or 4)-hexyldecyl, 2 (or 1, or 3, or 4)-octyldodecyl, 2 (or 1 or 3, or 4)-butyloctyl, 4 (or 1, or 2, or 3, or 5, or 6)-butyldecyl, 5 (or 1, or 2, or 3, or 4, or 6, or 7)-butylundecyl, 6 (or 1, or 2, or 3, or 4, or 5, or 7, or 8)-butyldodecyl, 12 (or 1, or 2, or 3, or 4, or 5, or 6, or 7, or 8, or 9, or 10, or 11, or 13, or 14)-butyloctadecyl, and the like.

In one or more examples of this invention, the electron donor compounds can be but are not limited to those listed in FIG. 20A-F of U.S. patent application Ser. No. 16/792,000 incorporated by reference herein.

Block 1002 represents providing, synthesizing and/or combining the donor(s) of Block 1000 with, one or more non-fullerene acceptor (NFA), e.g., to form a blend of the one or more donors and the one or more NFAs.

In one or more examples of the present invention, the non-fullerene acceptor (electron acceptor) comprises an A-D-A′-D-A structure, where D is any strong electron donating unit, group or moiety; A and A′ are any strong electron accepting unit, group or moiety, and A and A′ can be the same or different.

In one or more embodiments, D can be, but is not limited to, the following strong electron donating units:

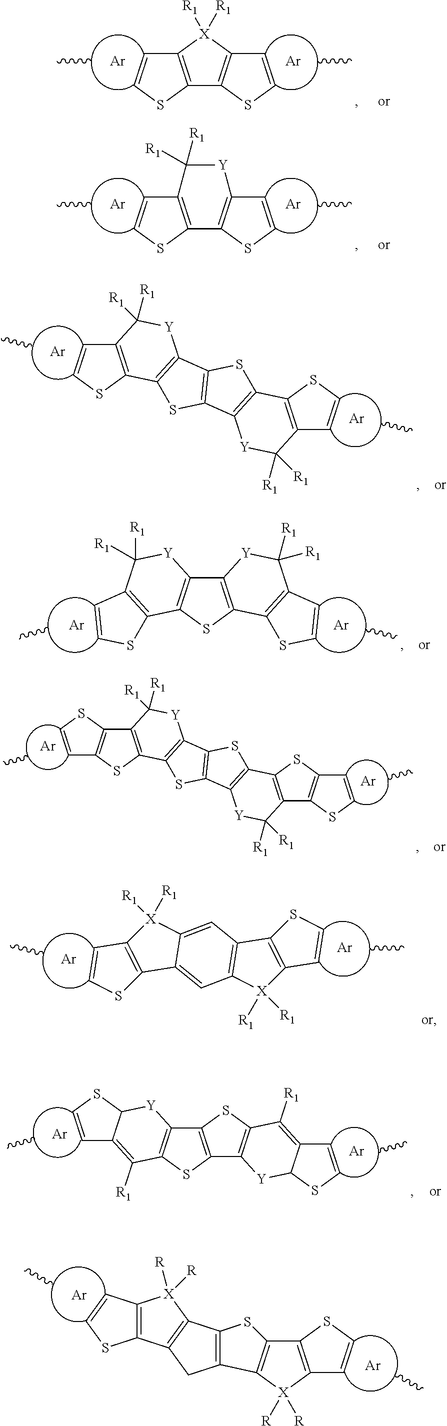

where each R, R₁, R₃ is independently hydrogen or a substituted or non-substituted alkyl, aryl or alkoxy chain; X is C, Si, Ge, N or P; Y is O, S, Se or N—R₃; each Ar is independently a substituted or non-substituted aromatic functional group, or each Ar is independently nothing and the valence of its respective thiophene ring is completed with hydrogen. Each Ar may comprise one, two, three or more 5-membered or 6-membered aromatic rings.

In one or more embodiments, examples of D include, but are not limited to, the following strong electron donating units:

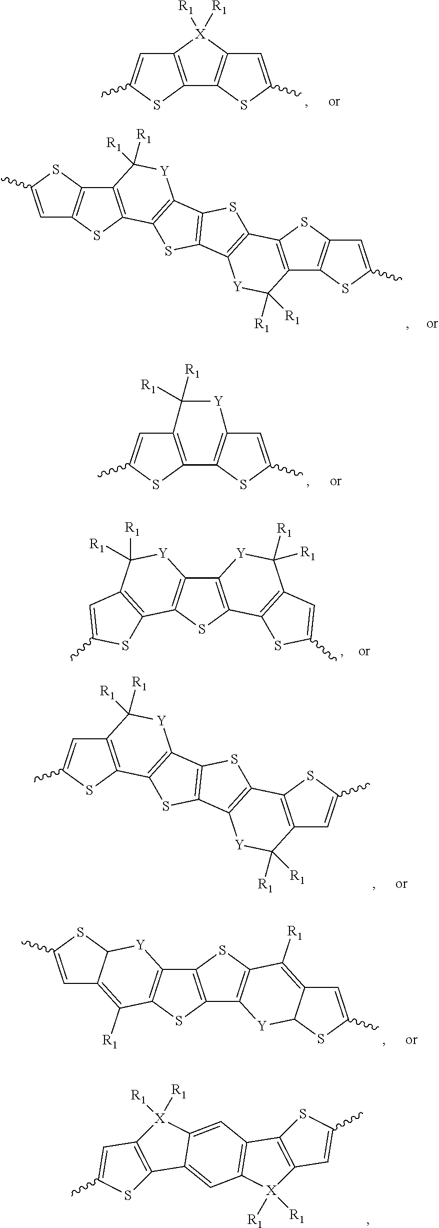

where each R₁, R₃ is independently hydrogen or a substituted or non-substituted alkyl, aryl or alkoxy chain; X is C, Si, Ge, N or P; and Y is O, S, Se or N—R₃.

Further examples of D include, but are not limited to, the following strong electron donating units:

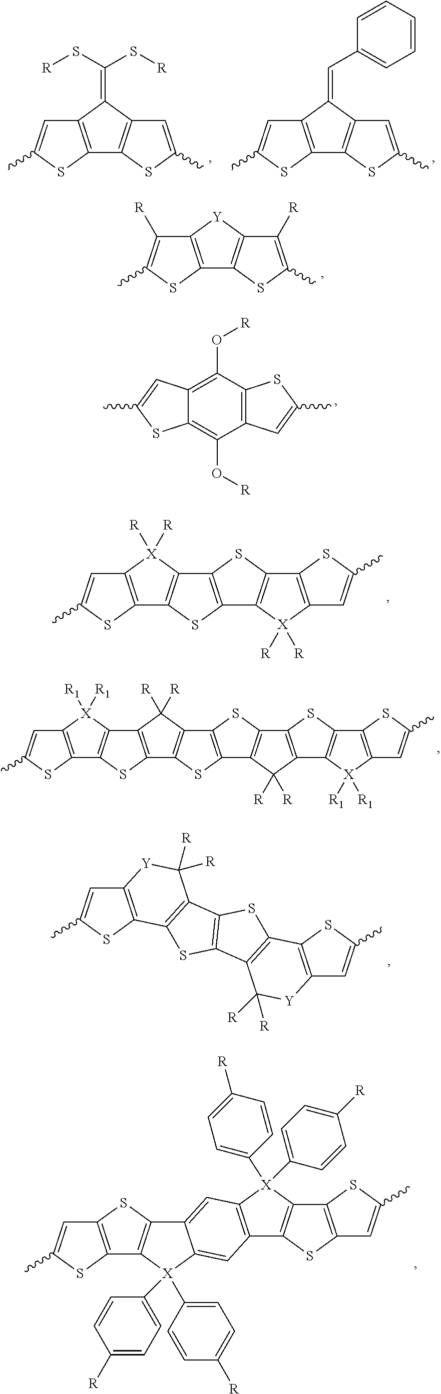

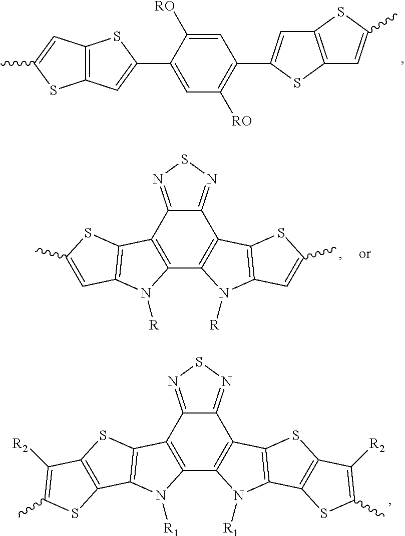

where each R, R₁, R₂, R₃ is independently hydrogen or a substituted or non-substituted alkyl, aryl or alkoxy chain; X is C, Si, Ge, N or P; Y is O, S, Se or N—R₃.

In one or more embodiments, examples of D include, but are not limited to, the following strong electron donating units:

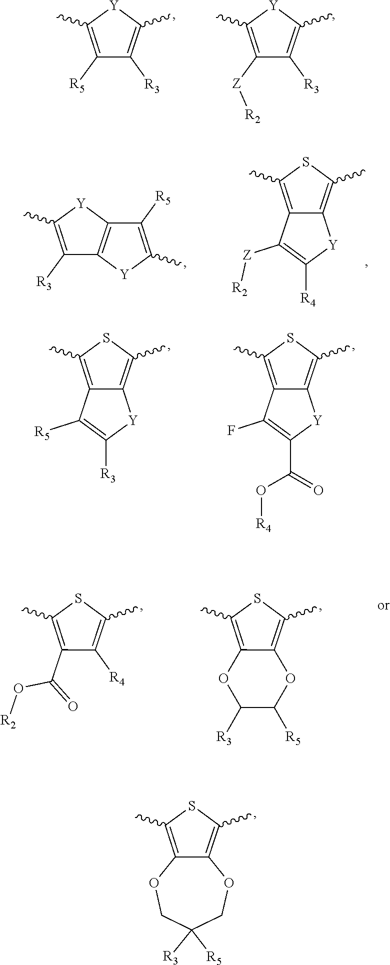

where each R₂, R₃, R₄, R₅, R₆ and R₇ is independently hydrogen or a substituted or non-substituted alkyl, aryl or alkoxy chain; in some embodiments, R₄ is either a hydrogen or the same as Z—R₂; R₅ is either a hydrogen or the same as R₃; Y is O, S, Se, or N—R₆, Z is O, S, Se or N—R₇.

Examples of dithiophene units further include those illustrated in Table B (FIG. 30B) in U.S. Utility patent application Ser. No. 14/426,467, filed on Mar. 6, 2015, by Hsinig-Rong Tseng, Lei Ying, Ben B. Y. Hsu, Christopher J. Takacs, and Guillermo C. Bazan, entitled “FIELD-EFFECT TRANSISTORS BASED ON MACROSCOPICALLY ORIENTED POLYMERS,” Attorney's Docket No. 30794.0514-US-WO (UC REF 2013-030). Further examples of dithiophene units are illustrated in Table 3 of U.S. Utility patent application Ser. No. 15/406,382, filed on Jan. 1, 2017, by Hsing-Rong Tseng, Lei Ying, Ben B. Y. Hsu, Christopher J. Takacs, and Guillermo C. Bazan, entitled “FIELD-EFFECT TRANSISTORS BASED ON MACROSCOPICALLY ORIENTED POLYMERS,” Attorney's Docket No. 30794.643-US-I1 (UC REF 2013-0304), which applications are incorporated by reference herein.

In one or more examples, A can be but not limited to those electron accepting units listed in FIG. 19A-H of U.S. patent application Ser. No. 16/792,000, and those listed in FIGS. 22a-g of U.S. patent application Ser. No. 16/179,294, which applications are incorporated by reference herein.

Examples of A′ include, but are not limited to, the following strong electron accepting units:

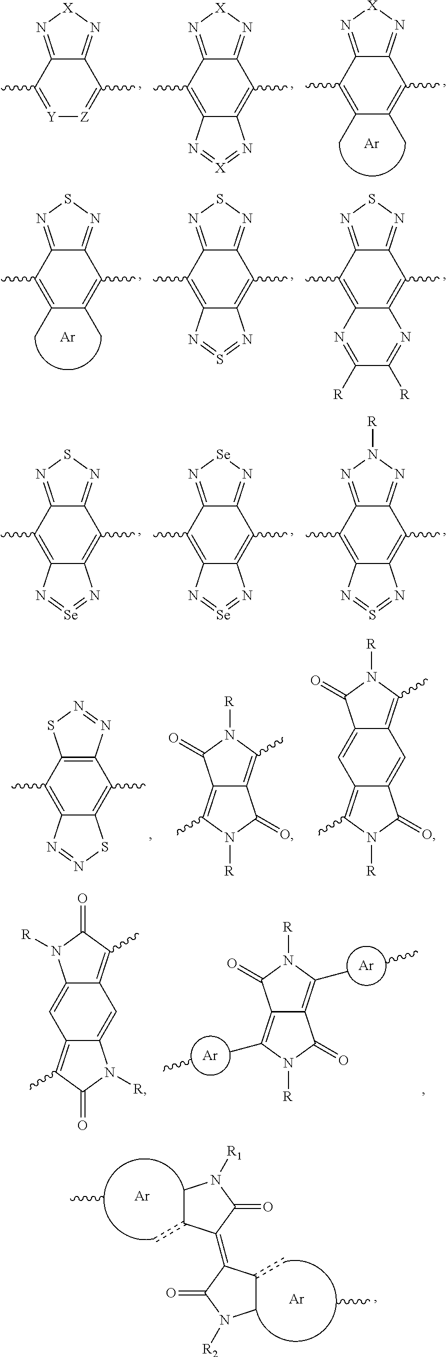

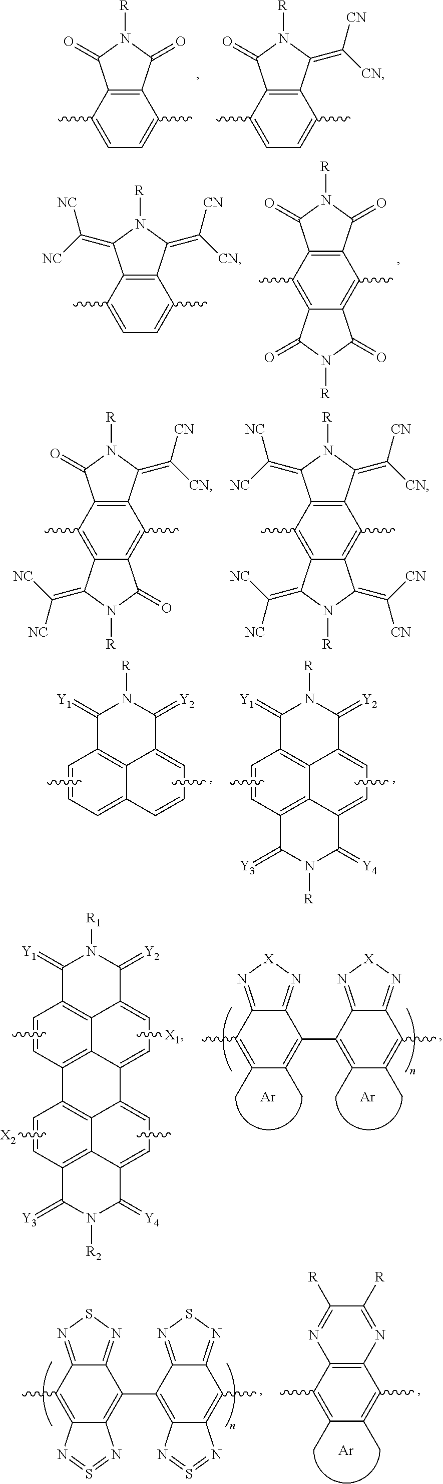

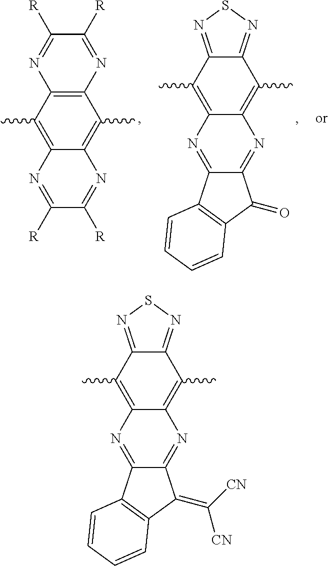

wherein each Y or Z can be CH, CF, CCl, N, C—CN, C—COR, C—COOR, C—OR, C—SR, C—NO₂; each X is O, S, Se or N—R₃; each Ar is independently a substituted or non-substituted aromatic functional group, preferred to be an electron withdrawing aromatic functional group, or each Ar is independently nothing; each X₁ and X₂ is halogen, CN or alkoxy, alkylthio, or N-annulated, or S-annulated; each Y₁, Y₂, Y₃ and Y₄ is S or O; each R, R₁, R₂, and R₃ is independently hydrogen or a substituted or non-substituted alkyl, aryl or alkoxy chain.

In one or more embodiments, the A-D-A′-D-A semiconductor comprises the general structure:

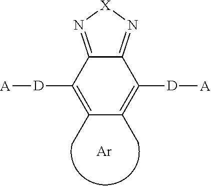

wherein each R₁ is independently hydrogen or a substituted or non-substituted alkyl, aryl or alkoxy chain; X is O, S, Se or N—R₁; each Ar is independently a substituted or non-substituted aromatic functional group, preferred to be an electron withdrawing aromatic functional group, or each Ar is independently nothing and the valence of the adjacent ring is completed with hydrogen. Each Ar may comprise one, two, three or more 5-membered or 6-membered aromatic rings, for example. Each D can be any strong electron donating unit, group or moiety; each A can be any strong electron accepting unit, group or moiety. The two A units in the A-D-A′-D-A semiconductor can be the same or different. The two D units in the A-D-A′-D-A semiconductor can be the same or different. In one or more embodiments, each D can be a dithiophene unit.

In one or more examples, each Ar can be, but is not limited to, the following aromatic units:

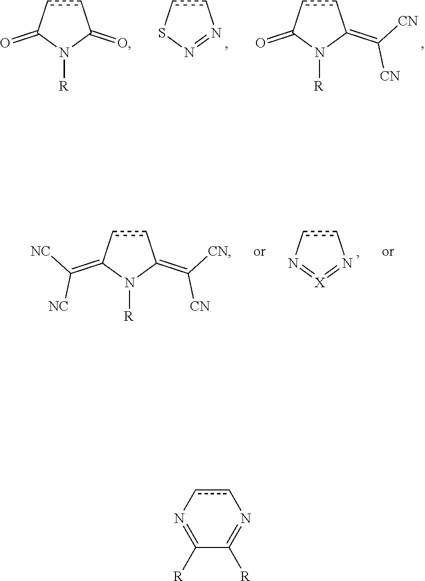

wherein each R is independently hydrogen or a substituted or non-substituted alkyl, aryl or alkoxy chain; X is O, S, Se or N—R₁.

As described above, A is an electron accepting unit (electron acceptor group or moiety). Examples of A include, but are not limited to, those electron accepting units listed in FIG. 19A-H of U.S. patent application Ser. No. 16/792,000, and those listed in FIGS. 22a-g of U.S. patent application Ser. No. 16/179,294, which applications are incorporated by reference herein.

In one or more embodiments, each A can be an electron acceptor group, moiety or unit of the following structure:

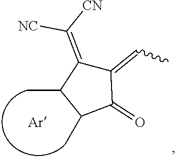

where

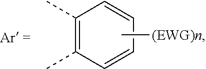

EWG=any electron withdrawing group, examples of EWG including, but not limited to, F, Cl, Br, I, CN, CF₃, NO₂, sulfonate, ketone, ester, n=1, 2, 3 or 4. Examples of Ar′ include, but are not limited to, the following:

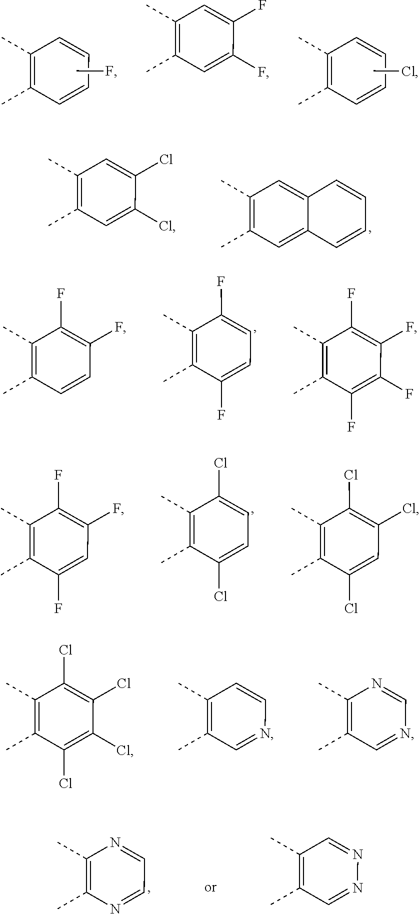

In one or more embodiments, the A-D-A′-D-A semiconductor comprises the general structure:

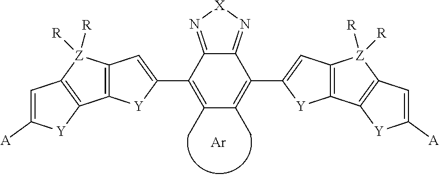

wherein each Ar is independently a substituted or non-substituted aromatic functional group, preferred to be an electron withdrawing aromatic functional group, or each Ar is independently nothing and the valence of the adjacent ring is completed with hydrogen. In one or more examples, each Ar may comprise one, two, three or more 5-membered or 6-membered aromatic rings. X is O, S, Se or N—R₁; Y is O, S, Se, or N—R₂; Z is C, Si, Ge, N or P; Each R, R₁ and R₂ is independently hydrogen or a substituted or non-substituted alkyl, aryl or alkoxy chain; In some embodiments, the R, R₁ and R₂ groups can be the same. The R, R₁ and R₂ comprising the substituted or non-substituted alkyl, aryl or alkoxy chain can be a C₆-C₅₀ substituted or non-substituted alkyl or alkoxy chain, —(CH₂CH₂O)ₙ (n=2˜30), C₆H₅, —CₙF₍₂ₙ₊₁₎ (n=2˜50), —(CH₂)ₙN(CH₃)₃Br (n=2˜50), 2-ethylhexyl, PhCₘH₂ₘ₊₁ (m=1-50), —(CH₂)ₙN(C₂H₅)₂ (n=2˜50), —(CH₂)ₙSi(CₘH₂ₘ₊₁)₃ (m, n=1 to 50), or —(CH₂)ₙSi(OSi(CₘH₂ₘ₊₁)₃)ₓ(CₚH₂ₚ₊₁)_{y} (m, n, p=1 to 50, x+y=3). In one or more examples, R is 2-ethylhexyl. In some more examples, R is n-octyl.

The R, R₁, R₂ and R₃ groups described herein can be a branched side-chain comprising a C₃-C₅₀, C₅-C₅₀, C₈-C₅₀, or C₉-C₅₀ substituted or non-substituted alkyl chain. Examples of branched alkyl chains include isopropyl, sec-butyl, t-butyl, 1,2-dimethylpropyl, 1,1-dimethyl-propyl, 4-methylpentyl, 1-methylpentyl, 2-methylpentyl, 3-methylpentyl, 1,1-dimethylbutyl, 2,2-dimethylbutyl, 3,3-dimethylbutyl, 1,2-dimethylbutyl, 1,3-dimethylbutyl, 1,2,2-trimethylpropyl, 1,1,2-trimethylpropyl, 5-methylhexyl, 1-methylhexyl, 2,2-dimethylpentyl, 3,3-dimethylpentyl, 4,4-dimethylpentyl, 1,2-dimethylpentyl, 1,3-dimethylpentyl, 1,4-dimethylpentyl, 1,2,3-trimethylbutyl, 1,1,2-trimethylbutyl, 1,1,3-trimethylbutyl, 6-methylheptyl, 1-methylheptyl, 1,1,3,3-tetramethylbutyl, 1-, 2-, 3-, 4-, 5-, 6- or 7-methyloctyl, 1-, 2-, 3-, 4- or 5-ethylheptyl, 1-, 2- or 3-propylhexyl, 1-, 2-, 3-, 4-, 5-, 6-, 7- and 8-methylnonyl, 1-, 2-, 3-, 4-, 5- or 6-ethyloctyl, 1-, 2-, 3- or 4-propylheptyl, dimethyloctyl, 1-, 2-, 3-, 4-, 5-, 6-, 7-, 8- or 9-methyldecyl, 1-, 2-, 3-, 4-, 5-, 6- or 7-ethylnonyl, 1-, 2-, 3-, 4- or 5-propyloctyl, 1-, 2- or 3-butylheptyl, 1-pentylhexyl, 1-, 2-, 3-, 4-, 5-, 6-, 7-, 8-, 9- or 10-methylundecyl, 1-, 2-, 3-, 4-, 5-, 6-, 7- or 8-ethyldecyl, 1-, 2-, 3- 4-, 5- or 6-propylnonyl, 1-, 2-, 3- or 4-butyloctyl, 1-, 2-pentylheptyl, branched butyl, pentyl, hexyl, heptyl, octyl, nonyl, decyl, undecyl, dodecyl, tridecyl, tetradecyl, pentadecyl, hexadecyl, heptadecyl, octadecyl, nonoadecyl, eicosyl with one or more branch points at any carbon of the alkyl chain, such as 2 (or 1, or 3, or 4)-ethylhexyl, 2 (or 1, or 3, or 4)-hexyldecyl, 2 (or 1, or 3, or 4)-octyldodecyl, 2 (or 1 or 3, or 4)-butyloctyl, 4 (or 1, or 2, or 3, or 5, or 6)-butyldecyl, 5 (or 1, or 2, or 3, or 4, or 6, or 7)-butylundecyl, 6 (or 1, or 2, or 3, or 4, or 5, or 7, or 8)-butyldodecyl, 12 (or 1, or 2, or 3, or 4, or 5, or 6, or 7, or 8, or 9, or 10, or 11, or 13, or 14)-butyloctadecyl, and the like.

In some embodiments, the A-D-A′-D-A semiconductor comprise the structure:

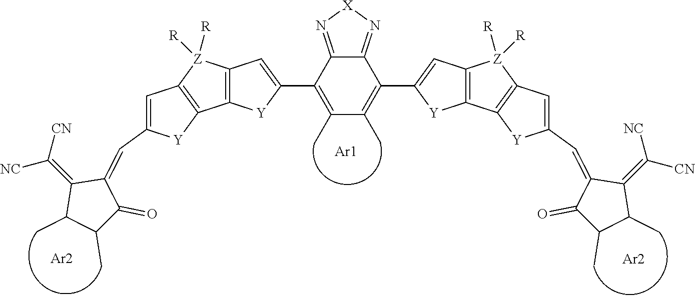

wherein X is O, S, Se or N—R₁, Y is O, S; Z is C, Si, Ge, N; each R and R₁ is independently hydrogen or a substituted or non-substituted alkyl, aryl or alkoxy chain; each Ar1 and Ar2 is independently a substituted or non-substituted aromatic functional group, preferred to be an electron withdrawing aromatic functional group, or each Ar1 and Ar2 is independently nothing and the valence of its respective adjacent ring is completed with hydrogen. In one or more examples each Ar1 and Ar2 may comprise one, two, three or more 5-membered or 6-membered aromatic rings.

In some embodiments, the A-D-A′-D-A semiconductor comprises the structure:

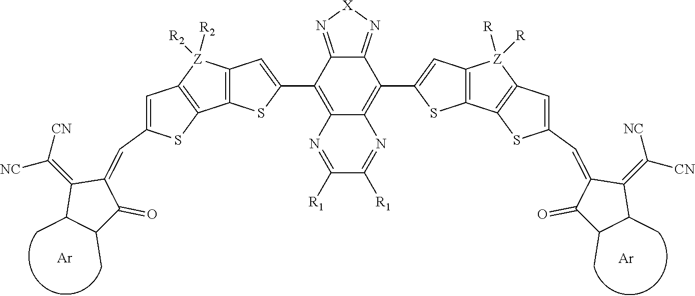

wherein X is O, S, Se or N—R₃; Z is C, Si, Ge, N; each R₁, R₂ and R₃ is independently hydrogen or a substituted or non-substituted alkyl, aryl or alkoxy chain;

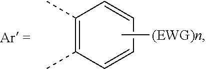

EWG=any electron withdrawing group, wherein EWG can be, but is not limited to F, Cl, Br, I, CN, CF₃, NO₂, sulfonate, ketone, ester, n=1, 2, 3 or 4. Examples of Ar include, but are not limited to, the following:

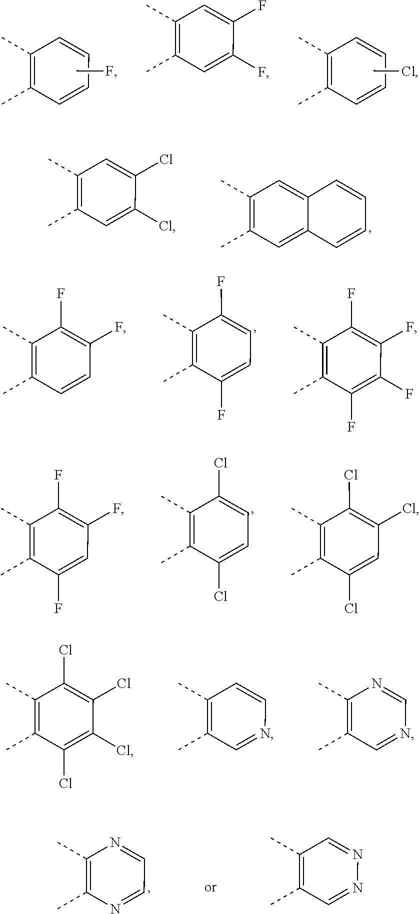

In one or more examples, R₁ is ((2-decyltetradecyl)oxyl)phenyl and R₂ is 2-ethylhexyl.

In one or more embodiments, the A-D-A′-D-A semiconductor comprises the structure:

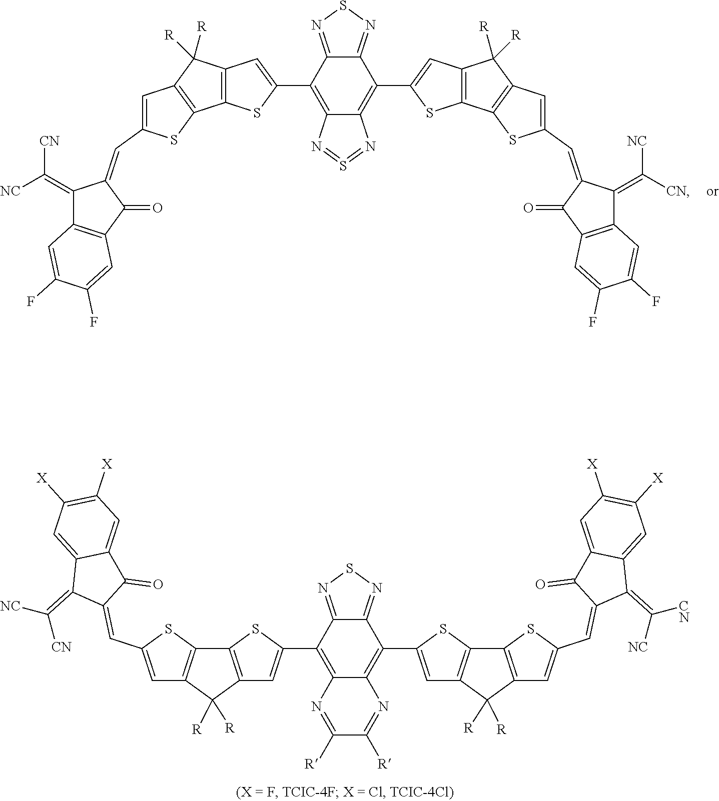

wherein each R, and R′ is independently hydrogen or a substituted or non-substituted alkyl, aryl or alkoxy chain. In one or more examples, R is 2-ethylhexyl, R′ is ((2-decyltetradecyl)oxyl)phenyl. X can be any electron withdrawing group, can be but is not limited to F, Cl, Br, I, CN, CF₃, NO₂, sulfonate, ketone.

In one or more examples of the present invention, the non-fullerene acceptor comprises an A-D-A′-D′-A′-D-A structure, where D′ and D is any strong electron donating unit, including but not limited to, electron donating units, groups and moieties described herein; A and A′ are any strong electron accepting unit, including but not limited to the electron accepting units, groups and moieties described herein; and D and D′, A and A′ can be the same or different.

In one or more embodiments, the A-D-A′-D′-A′-D-A semiconductor comprise the structure:

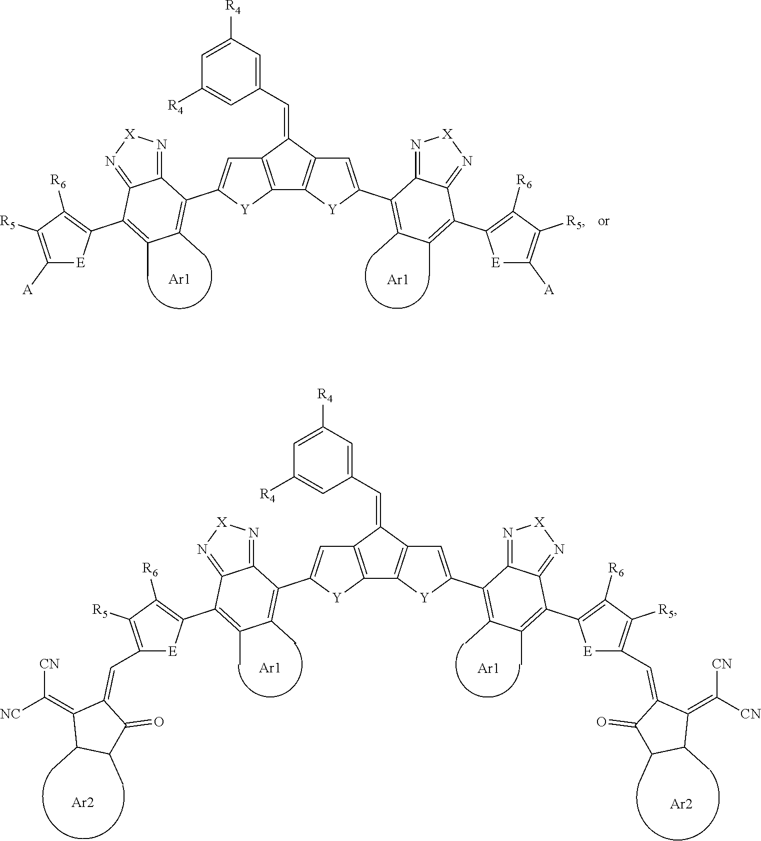

wherein each R₁, R₂, R₃, R₄, R₅ and R₆ is independently hydrogen or a substituted or non-substituted alkyl, aryl or alkoxy chain; each X is independently O, S, Se or N—R₁; each Y is independently O, S, Se or N—R₂; each E is independently O, S, Se, or N—R₃; each Ar1 and Ar2 is independently a substituted or non-substituted aromatic functional group, preferably an electron withdrawing aromatic functional group, or each Ar1 and AR2 is independently nothing and the valence of its respective adjacent ring is completed with hydrogen. In one or more examples, each Ar1 and AR2 may comprise one, two, three or more 5-membered or 6-membered aromatic rings. Each A can be any strong electron accepting unit, group or moiety. The two A units in the A-D-A′-D′-A′-D-A semiconductor can be the same or different.

In one or more examples, each Ar1 can be, but is not limited to, the following aromatic units:

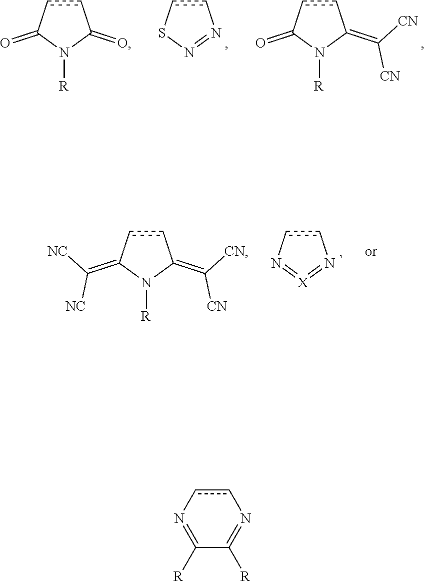

wherein each R and R₁ is independently hydrogen or a substituted or non-substituted alkyl, aryl or alkoxy chain; and each X is independently O, S, Se or N—R₁.

As described above, A is an electron accepting unit (electron acceptor moiety). Examples of A include, but are not limited to, those electron accepting units listed in FIG. 19A-H of U.S. patent application Ser. No. 16/792,000, and those listed in FIGS. 22a-g of U.S. patent application Ser. No. 16/179,294 incorporated by reference herein

In one or more embodiments, each A can be an electron acceptor group, moiety or unit of the following structure:

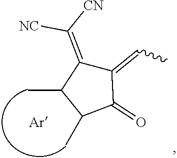

where

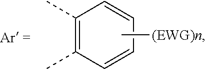

EWG=any electron withdrawing group, where examples of EWG include but are not limited to F, Cl, Br, I, CN, CF₃, NO₂, sulfonate, ketone, ester, n=1, 2, 3 or 4. Examples of Ar′ can be but not limited to the following:

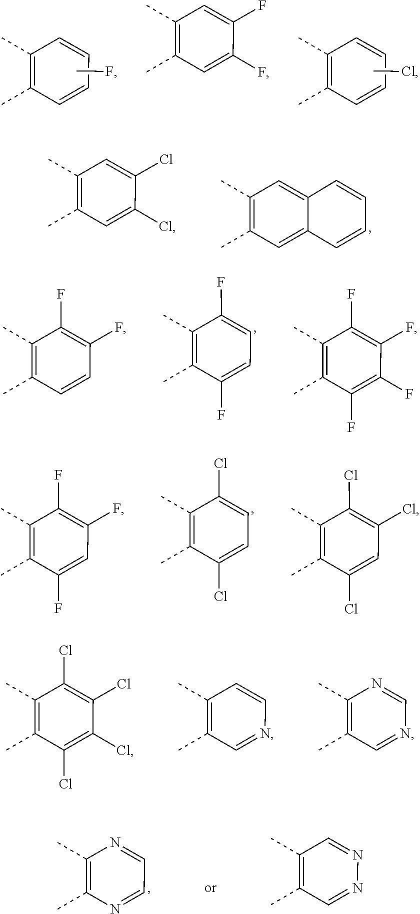

In one or more embodiments, D can be, but is not limited to, the following electron donating units:

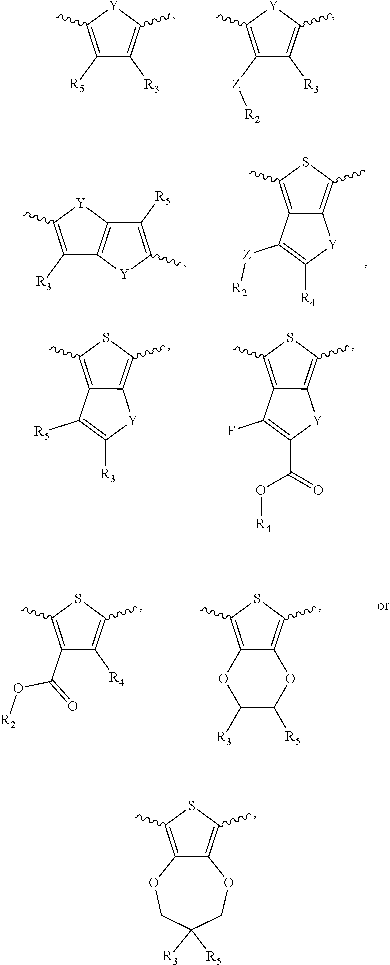

where each R₂, R₃, R₄, R₅, R₆ and R₇ is independently hydrogen or a substituted or non-substituted alkyl, aryl or alkoxy chain; in some embodiments, R₄ is either a hydrogen or the same as Z—R₂; R₅ is either a hydrogen or the same as R₃; Y is O, S, Se, or N—R₆, Z is O, S, Se or N—R₇.

Examples of A include, but are not limited to, those electron accepting units listed in FIG. 19A-H of U.S. patent application Ser. No. 16/792,000, and those listed in FIGS. 22a-g of U.S. patent application Ser. No. 16/179,294, which applications are incorporated by reference herein.

In one or more embodiments, the A-D-A′-D′-A′-D-A semiconductor comprises the structure:

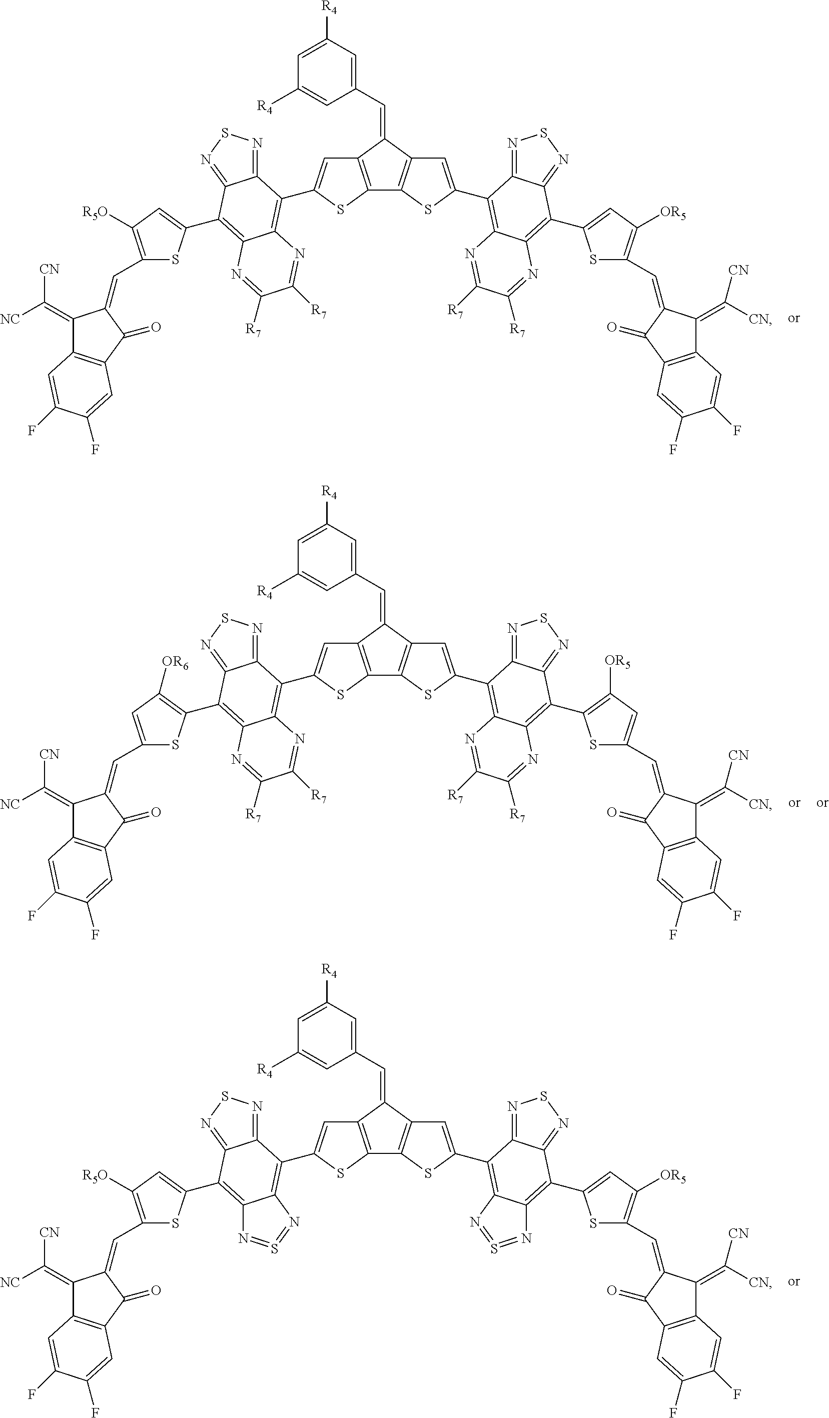

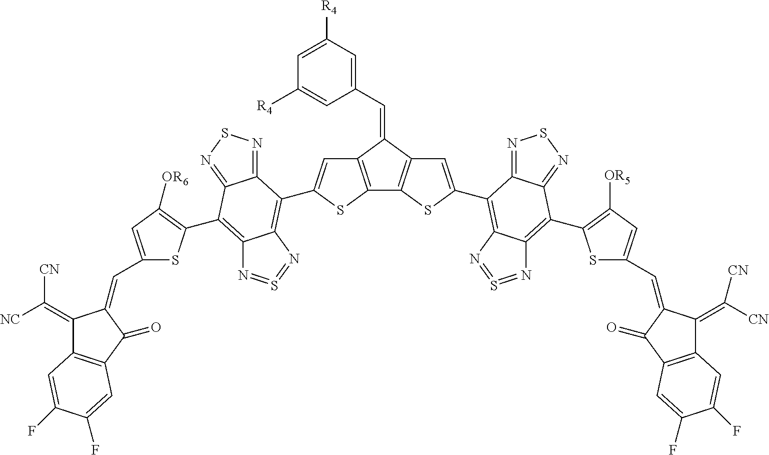

where each R₄ and R₇ is independently hydrogen or a substituted or non-substituted alkyl, aryl or alkoxy chain; and each R₅ and R₆ is independently hydrogen or a substituted or non-substituted alkyl or aryl chain.

Block 1004 represents the end result, a composition of matter comprising the NFA and the donor. In one or more examples, a film comprising the composition of matter may have an absorptivity of at least 0.7 across the entire wavelength range of 1000-1200 nm, wherein the electron acceptor has a bandgap less than 1.0 eV and the donor compound has a bandgap less than 1.45 eV.

Block 1006 represents optionally processing the composition of matter in a device.

In one or more embodiments, the device comprises a heterojunction between the electron acceptor and the organic semiconducting donor compound.

In one or more examples, the device comprises an active region comprising the electron acceptor, wherein the active region outputs electrical current in response to absorbing electromagnetic radiation.

In one or more embodiments, the active region (e.g., in the solar cell or the photodetector) is sensitive to infrared wavelengths (i.e., the bandgap of the acceptor molecule and/or donor molecule are sufficiently low to absorb infrared radiation).

In one or more embodiments, the semiconductor donor compound has a Highest occupied molecular orbital (HOMO) in a range of −4.8 eV to −5.5 eV, a lowest un-occupied molecular orbital (LUMO) in a range of −3.2 eV to −4.0 eV, and a bandgap in a range of 1.0 eV to 2.0 eV.

In one or more embodiments, the semiconductor donor compound has a HOMO in a range of −4.8 eV to −5.5 eV, a LUMO in a range of −3.5 eV to −4.0 eV, and a bandgap in a range of 1.0 eV to 1.4 eV.

In one or more embodiments, the semiconductor donor compound has HOMO in a range of −5.0 eV to −5.3 eV, a LUMO in a range of −3.5 eV to −3.9 eV, and a bandgap in a range of 1.0 eV to 1.3 eV.

In one or more embodiments, the semiconductor donor compound has a bandgap narrower than 1.5 eV.

In one or more embodiments, the semiconductor donor compound has a bandgap narrower than 1.4 eV or narrower than 1.1 eV.

In one or more embodiments, the semiconductor donor compound has a main absorption band between 600 and 1200 nm.

In one or more embodiments, the semiconductor donor compound has a main absorption band between 600 and 900 nm.

In one or more embodiments, the semiconductor donor compound has a main absorption band between 700 and 1100 nm.

In one or more embodiments, the semiconductor donor compound has a maximum extinction coefficient in solution of at least 1×10⁵ M⁻¹ cm⁻¹.

In one or more embodiments, the organic electron acceptor (NFA) has a HOMO in a range of −5.3 eV to −5.7 eV, a LUMO in a range of −4.3 eV to −4.7 eV, and a bandgap less than of 1.0 eV or in a range of 0.8 to 0.99 eV.

In one or more embodiments, the organic electron acceptor (NFA) has a main absorption band between 800 and 1400 nm.

In one or more embodiments, the organic electron acceptor (NFA) has a maximum extinction coefficient in solution of at least 1×10⁵ M⁻¹ cm⁻¹.

In one or more examples, an energetic offset between the donor and acceptor HOMO levels (HOMO_{D}-HOMO_{A}, ΔE_{HOMO}) is no more than 0.3 eV, 0.2 eV or 0.1 eV.

In one or more examples, the device comprising an active region comprising the NFA and the donor has an external quantum efficiency (EQE) over 2% in the wavelength range of 600-1100 nm and a short circuit current density J_{SC} over 3 mA cm⁻².

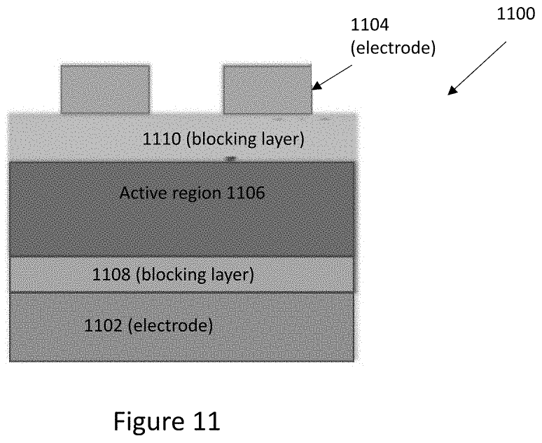

In one or more embodiments (e.g., as illustrated in FIG. 11), the device 1100 comprises an active region 1106 comprising the organic semiconducting donor and the electron acceptor, wherein electron hole pairs comprising holes and electrons are generated in the active region in response to electromagnetic radiation incident on the active region, the electrons are collected in the electron acceptor and are transmitted through to a cathode 1102/1104, and the holes are collected in the organic donor compound and transmitted through to an anode 1102/1104; the cathode is coupled to the acceptor to receive the electrons; and the anode is coupled to the donor to receive the holes; and such that the device outputs current in response to the electromagnetic radiation

In one or more examples, the device comprises a photodetector having an external quantum efficiency (EQE) above 2%, a responsivity of at least 0.01 A/W, and a specific detectivity of at least 10¹¹ Jones across the entire wavelength range of 800-1200 nm of the electromagnetic radiation when the anode is biased at 0V with respect to the cathode.

In one or more embodiments, the device:
has a wide spectral response in the wavelength range of 300-1200 nm, or 300-1400 nm;
has an external quantum efficiency (EQE) over 5% in the wavelength range of 300-1100 nm under an operating voltage of 0V;
has an external quantum efficiency (EQE) over 10% in the wavelength range of 900-1100 nm under an operating voltage of −1V;
has an external quantum efficiency (EQE) over 20% in the wavelength range of 900-1100 nm under an operating voltage of −4V.

The photovoltaic device may have a standard or inverted structure. It may comprise a substrate, a first electrode deposited on the substrate, a second electrode, an optional electron conducting/hole blocking layer deposited either between the first electrode and the active layer, or between the active layer and the second electrode, and an optional hole conducting/electron blocking layer deposited either in between the first electrode and the active layer, or between the active layer and the second electrode.

In one or more examples (e.g., as used to obtain the results shown in FIGS. 2-8), the device 1100, as illustrated in FIG. 11, comprises a cathode 1102; an anode 1104; and the active region 1106 having a thickness between the cathode and the anode; and wherein:

holes and electrons are generated in the active region in response to electromagnetic radiation incident on the active region,

the electrons are collected in the electron acceptor and are transmitted through to the cathode, and

the holes are collected in the electron donor and transmitted through to the anode.

Also illustrated is a hole blocking layer 1108 between the cathode and the active region, and an electron blocking layer 1110 between the anode and the active region.

During operation, either or both the electron donor and the electron acceptor absorb photons to create electron-hole pairs, the electron acceptor (interfacing with the electron donor) receives or collects the electron in the electron hole pair and transports the electron to the cathode interface layer/hole blocking layer and the cathode. The hole is transported by the electron donor to the anode interface layer/electron blocking layer and then the anode.

In one or more examples, the device 1100 comprises an infrared photodetector, comprises a first electrode 1102 (e.g., anode or cathode); a first carrier transport layer 1108; an active layer 1106, wherein the first carrier transport layer (e.g., hole blocking layer or electron blocking layer) is between the first electrode and the active layer; a second carrier transport layer 1110, wherein the active layer is between the first carrier transport layer and the second carrier transport layer; and a second electrode 1104 (e.g., anode or cathode) on the second carrier transport layer (e.g., hole blocking layer or electron blocking layer).

Examples of a substrate include, but are not limited to, a flexible substrate, a plastic substrate, a polymer substrate, a metal substrate, a silicon substrate, or a glass substrate. In one or more embodiments, the flexible substrate is at least one film or foil selected from a polyimide film, a polyether ether ketone (PEEK) film, a polyethylene terephthalate (PET) film, a polyethylene naphthalate (PEN) film, a polytetrafluoroethylene (PTFE) film, a polyester film, a metal foil, a flexible glass film, and a hybrid glass film. Examples of cathode interface layer include, but are not limited to ZnO and/or ITO. The ZnO can include multiple layers (e.g., two layers) and have a surface roughness of less than 5 nm over an area of 0.2 cm².

Examples of anode interface layer include, but are not limited to MoOx having a thickness in a range of 5-150 nm. Further examples include, but are not limited to, the hole transporting/conducting layer material selected from, but not limited to, the group comprising or consisting of poly(3,4-ethylenedioxythiophene): polystyrene sulfonate (PEDOT:PSS), p-type organic small molecule semiconductors such as Spiro-MeOTAD, pentacene, biscarbazolylbenzene, oligomer semiconductors, polymer semiconductors such as PTAA, poly(3-hexylthiophene-2,5-diyl) (P3HT), donor-acceptor copolymer semiconductors such as PCPDTBT, PCDTBT, conjugated small molecule electrolytes, conjugated oligomer electrolytes, conjugated polymer electrolytes, metal oxides such as CuI, CuBr, CuSCN, Cu₂O, CuO or CIS. VOₓ, NbOₓ, MoOₓ, WOₓ, NiOₓ, where x is 3 or less than 3, or other main group or transition metal oxides and a compound as shown in FIG. 1 of U.S. Ser. No. 14/954,131.

Examples of cathode material include, but are not limited to, ITO. In further examples, the electron transporting/conducting layer material is selected from, but not limited to, the group comprising or consisting of TiO₂, ZnO, SnO, SnO₂, SiO₂, CeO₂, ZrO₂, CdSe, WO₃, ZnSnO₄, PbI₂, SrTiO₃, LiF, Li₂CO₃, fullerene based electron acceptors (C₆₀, C₇₀, PC₆₁BM, PC₇₁BM, ICBA), borane based electron acceptors (3TPYMB), Bathocuproine (BCP), bathophenanthroline (Bphen), ITIC type of non-fullerene acceptors, NDI and PDI based non-fullerene acceptors, and the combination of above (double layer). The electron transporting layer may have a thickness of 2 nm to 500 nm, preferably a thickness of 20 nm to 200 nm, more preferably a thickness of 20-50 nm, or 50 nm to 100 nm.

Examples of cathode and anode materials include, but are not limited to, a metal or at least one material selected from gold, aluminum, copper, silver, silver paste, palladium, platinum, nickel, a combination/bilayer of metal and molybdenum oxide or molybdenum (wherein the MoOx is an interlayer), a liquid metal (e.g., mercury alloy, eutectic gallium indium), a transparent conductive layer, carbon nanotubes, graphene, carbon paste, PEDOT:PSS, and a conjugated polyelectrolyte.

In one or more embodiments, the electrodes, anode, cathode, interface layers, electron transporting/hole blocking layers, hole transporting/electron blocking layers of the electronic device can be transparent or semitransparent.

The active layer, electron transporting/hole blocking layers, hole transporting/electron blocking layers of the electronic device may be deposited by solution casting or vapor deposition. Illustrative thin film deposition methods include a spin coating method, a casting method, a microgravure coating method, a gravure coating method, a bar coating method, a roll coating method, a blade coating method, a wire bar coating method, a dip coating method, a spray coating method, a free span coating method, a dye coating method, a screen printing method, a flexo printing method, an offset printing method, an inkjet printing method, a dispenser printing method, a nozzle coating method and a capillary coating method, for forming a film from a solution.

Possible Modifications and Variations

Non-fullerene acceptor materials were designed and synthesized with different chemical structures to tune chemical properties for narrower bandgaps and higher device performance. In addition, the device performance can be improved through further morphology control of the active layer. Further device optimization includes, but is not limited to, optimizing the donor/acceptor ratio, the solvent solution concentration, processing additive types and amounts, film deposition methods (spin coating, blade coating, drop casting etc.), film deposition temperature, film thickness, buffer layers (electron transporting layer, hole transporting layer).

In addition, the above systems can be applied to various organic electronic devices including organic solar cells, organic field effect transistor and organic sensor. Organic photodetectors (OPDs) with NIR responsivity have plenty of applications such as image sensing, night surveillance, optical communication, and health monitoring.

Advantages and Improvements

Conventional photodetectors are based on crystalline inorganic semiconductor materials such as silicon and epitaxial semiconductors grown on planar and rigid substrates (wafers).^{[10-11]} On the other hand, organic semiconductors (n-conjugated molecules and polymers) have high extinction coefficients, arise from the large wavefunction overlap between the electronic ground state and the lowest excited state, which result in strong light absorption in thin films.^{[14]}

NIR non-fullerene acceptors are a strategy key to achieve high-transparent device and high-detectivity in range of NIR wavelength (over 780 nm). The present disclosure describes desirable compositions of NIR donors and NIR non-fullerene acceptors for organic solar cells and photodetectors with demonstration of their device performance. In the examples described herein, NIR absorbing donor (PM2) and ultra-narrow bandgap NIR-non fullerene acceptors (BCIC-4F, TCIC-4F and TCIC-4Cl) were synthesized and characterized for organic solar cell and organic photodetector structures based on a donor:acceptor heterojunction which can separate excitons and generate charges.^{[15]}. Since PM2 polymer has narrow energy bandgap of ˜1.41 eV and absorbs the sunlight at wavelengths up to ˜900 nm, compositions with NIR non-fullerene acceptors exhibit broader NIR light absorption coupled with high transparency at wavelengths detectable by the human naked eye and superior performance in NIR range. NIR organic optoelectronic applications that can leverage this strong absorption in the near-infrared region include state of the art internet of things (IoT) applications, health monitoring (e.g., unobtrusive photodetectors that can be integrated in/on the human body, such as healthcare devices operating by continuous detection of physiological signals or small electronic chips^{[12-13]}), and lightweight and conformal image sensors with color or infrared sensitivity for applications in wearable electronics, prosthetics, robotics, and automotive applications.

### REFERENCES

The following references are incorporated by reference herein.
1. J. Lee, S.-J. Ko, M. Seifrid, H. Lee, B. R. Luginbuhl, A. Karki, M. Ford, K. Rosenthal, K. Cho, T.-Q. Nguyen, G. C. Bazan, Advanced Energy Materials 2018, 8, 1801212.
2. Y. Liu, M. Li, J. Yang, W. Xue, S. Feng, J. Song, Z. Tang, W. Ma, Z. Bo, Advanced Energy Materials 2019, 9, 1901280.
3. C. M. Cardona, W. Li, A. E. Kaifer, D. Stockdale, G. C. Bazan, Advanced Materials 2011, 23, 2367.
4. Yankang Yang, Zhi-Guo Zhang, Haijun Bin, Shanshan Chen, Liang Gao, Lingwei Xue, Changduk Yang, and Yongfang Li, J. Am. Chem. Soc. 2016, 138, 15011-15018
5. Yuze Lin, Jiayu Wang, Zhi-Guo Zhang, Huitao Bai, Yongfang Li, Daoben Zhu, and Xiaowei Zhan, Adv. Mater. 2015, 27, 1170-1174
6. Xin Song, Nicola Gasparini, Long Ye, Huifeng Yao, Jianhui Hou, Harald Ade, and Derya Baran, ACS Energy Lett. 2018, 3, 669-676
7. Hui Zhang, Sandra Jenatsch, Jelissa De Jonghe, Frank Niiesch, Roland Steim, Anna C. Véron and Roland Hany, Scientific Reports, 2015, 5, 9493
8. Cenqi Yan, Stephen Barlow, Zhaohui Wang, He Yan, Alex K.-Y. Jen, Seth R. Marder and Xiaowei Zhan Nature Reviews Materials, 2018, 3, 18003
9. Guanghong Liu, Tengfei Li, Xiaowei Zhan, Hongbin Wu, and Yong Cao, ACS Appl. Mater. Interfaces, 2020, 12, 15, 17769-17775
10. Helen Bristow, Karl J. Thorley, Andrew J. P. White, Andrew Wadsworth, Maxime Babics, Zeinab Hamid, Weimin Zhang, Alexandra F. Paterson, Jan Kosco, Julianna Panidi, Thomas D. Anthopoulos, Iain McCulloch, Adv. Electron. Mater. 2019, 5, 1900344
11. N. Martino, D. Ghezzi, F. Benfenati, G. Lanzaniab and M. R. Antognazza., J. Mater. Chem. B 2013, 1, 3768-3780
12. Sungjun Park, Kenjiro Fukuda, Ming Wang, Chulhyo Lee, Tomoyuki Yokota, Hanbit Jin, Hiroaki Jinno, Hiroki Kimura, Peter Zalar, Naoji Matsuhisa, ShinjiroUmezu, Guillermo C. Bazan, Takao Someya. Adv. Mater. 2018, 30, 1802359
13. Z. Huang, J. E. Carey, M. Liu, X. Guo, E. Mazur and J. C. Campbell, Appl. Phys. Lett., 2006, 89, 033506
14 Dae-Myeong Geum, SangHyeon Kim, Seong Kwang Kim, SooSeok Kang, JiHoon Kyhm, Jindong Song, Won Jun Choi, Euijoon Yoon, Scientific Reports, 2019, 9, 18661
15. J. Allen, Physiol. Meas. 2007, 28, R₁.
16. Y. Khan, A. E. Ostfeld, C. M. Lochner, A. Pierre, A. C. Arias, Adv. Mater. 2016, 28, 4373.
17. William Barford1 and Max Marcus, J. Chem. Phys, 2017, 146, 130902.
18. Dezhi Yang, Dongge Ma, Adv. Optical Mater. 2019, 7, 1800522.

### CONCLUSION

This concludes the description of synthesis route, the optical and electrical properties of NIR absorbing materials; donor polymer and three ultra-narrow bandgap NIR-NFAs (e.g., BCIC-4F and TCIC-4F). Also, this describes the device structure and methods of the device fabrication, with photovoltaic and photodetector performances. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

1. A composition of matter useful as an electron acceptor, comprising:
an organic semiconducting compound having an A-D-A′-D-A structure or an A-D-A′-D′-A′-D-A structure, wherein:
D is a first donor moiety;
D′ is a second electron donor moiety;
A is a first electron acceptor moiety; and
A′ is a second electron acceptor moiety.

2. The composition of matter of claim 1, wherein the organic semiconducting compound has the structure: 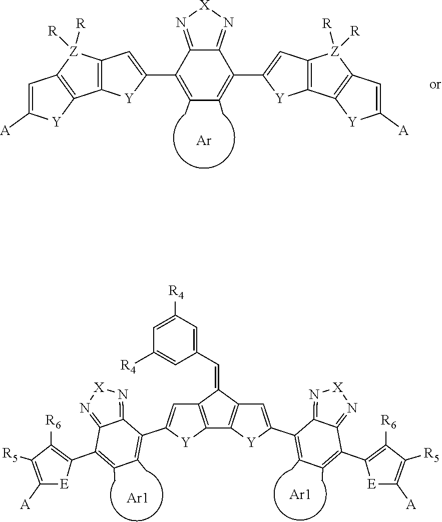
Ar or Ar1 comprise an aromatic functional group or hydrogen,
X is O, S, Se or N—R₁;
Y is O, S, Se, or N—R₂; Z is C, Si, Ge, N or P; E is O, S, Se, or N—R₃; and
each R, R₁, R₂, R₃, R₄, R₅, and R₆ is independently hydrogen or a substituted or non-substituted alkyl, aryl or alkoxy chain.

3. The composition of matter of claim 1, wherein the organic semiconducting compound comprises the structure: 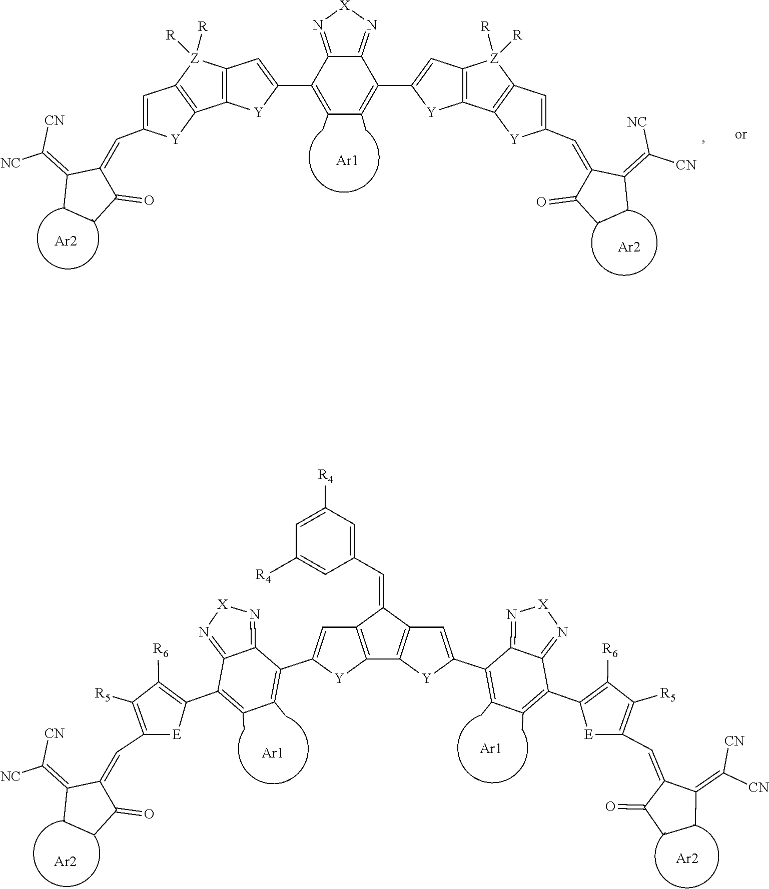
wherein X is O, S, Se or N—R₁, Y is O, S; Z is C, Si, Ge, N; E is O, S; each R R₁, R₄, R₅ and R₆ is independently hydrogen or a substituted or non-substituted alkyl, aryl or alkoxy, chain; and each Ar1 and Ar2 is independently a substituted or non-substituted aromatic functional group comprising an electron withdrawing aromatic functional group.

4. The composition of matter of claim 3, wherein each Ar2 is independently one of the following:

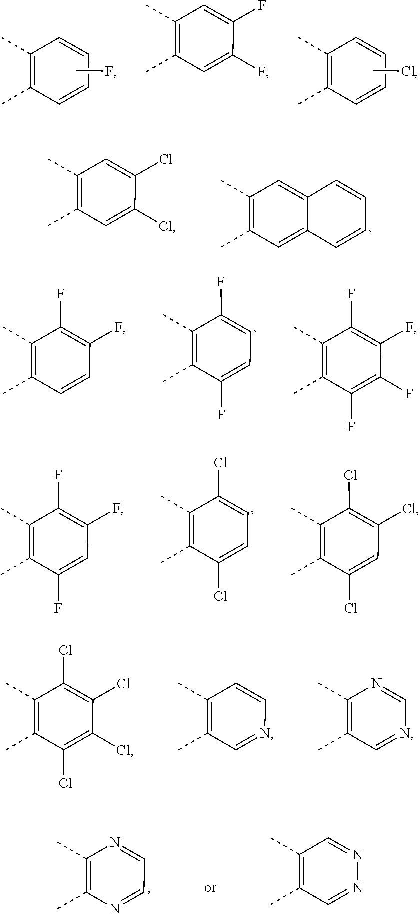

5. The composition of matter of claim 1, having the A-D-A′-D′-A′-D-A structure wherein:
A′ is: 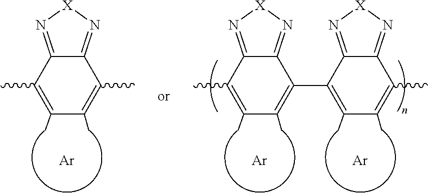
D′ is: 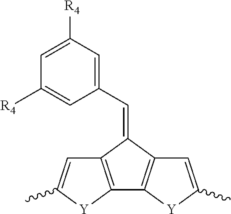
Ar is one of the following: 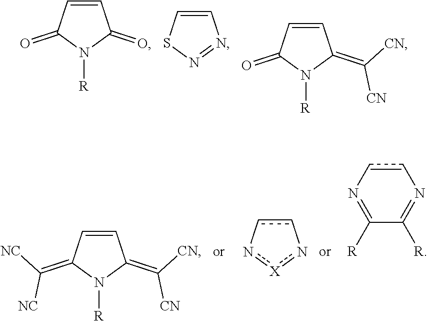
D is independently one of the following: 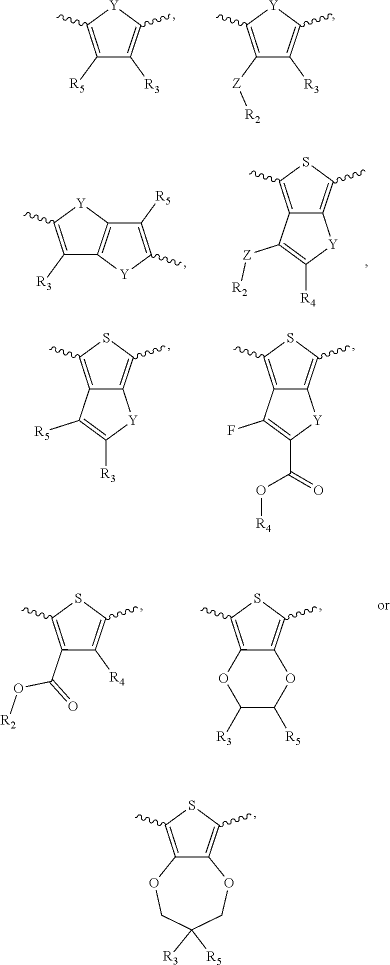
where each R, R₂, R₃, R₄, R₅ is independently hydrogen or a substituted or non-substituted alkyl, aryl or alkoxy chain.

6. The composition of matter of claim 1, wherein the organic semiconducting compound has the structure: 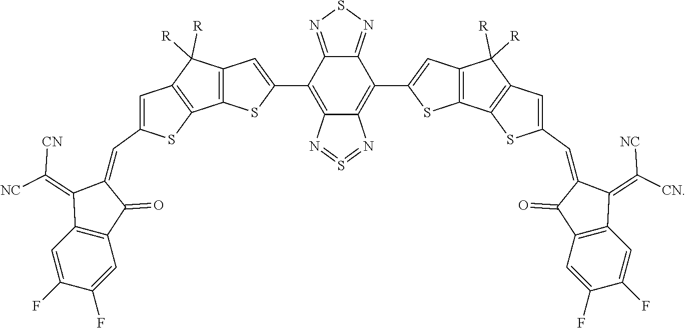
wherein each R is independently hydrogen or a substituted or non-substituted alkyl, aryl or alkoxy chain.

7. The composition of matter of claim 1, wherein the organic semiconducting compound has the structure: 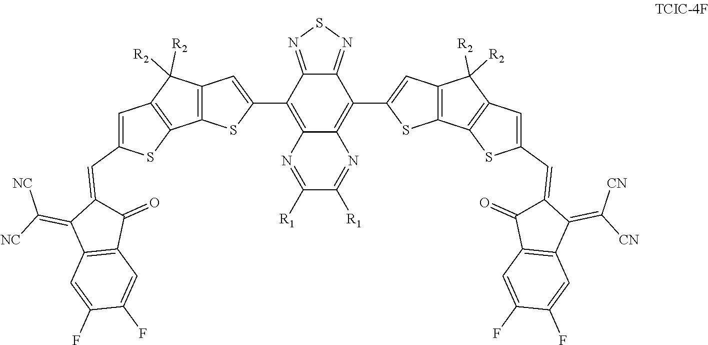
wherein each R₁ and R₂ is independently hydrogen or a substituted or non-substituted alkyl, aryl or alkoxy chain.

8. The composition of matter of claim 1, wherein the organic semiconducting compound is: 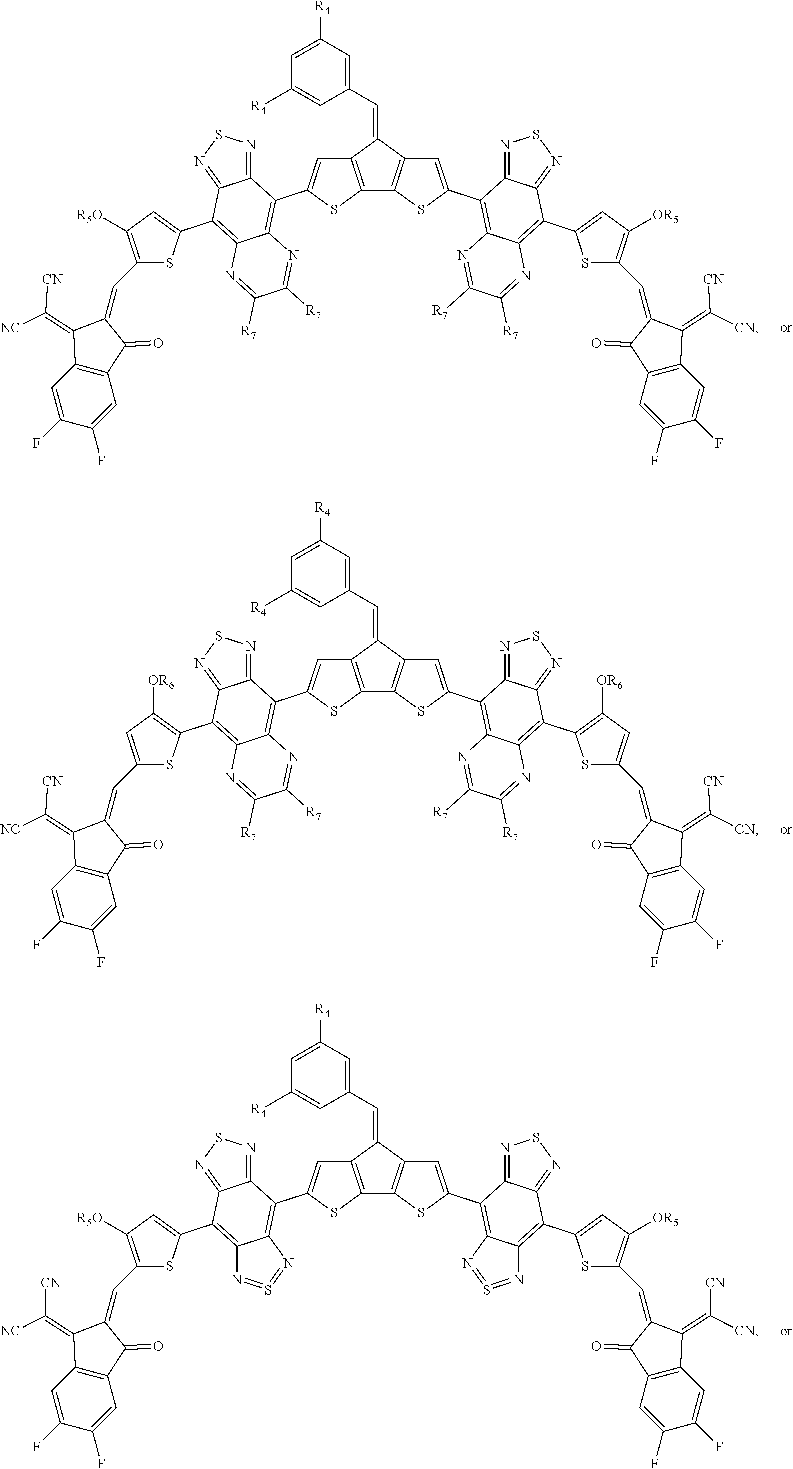 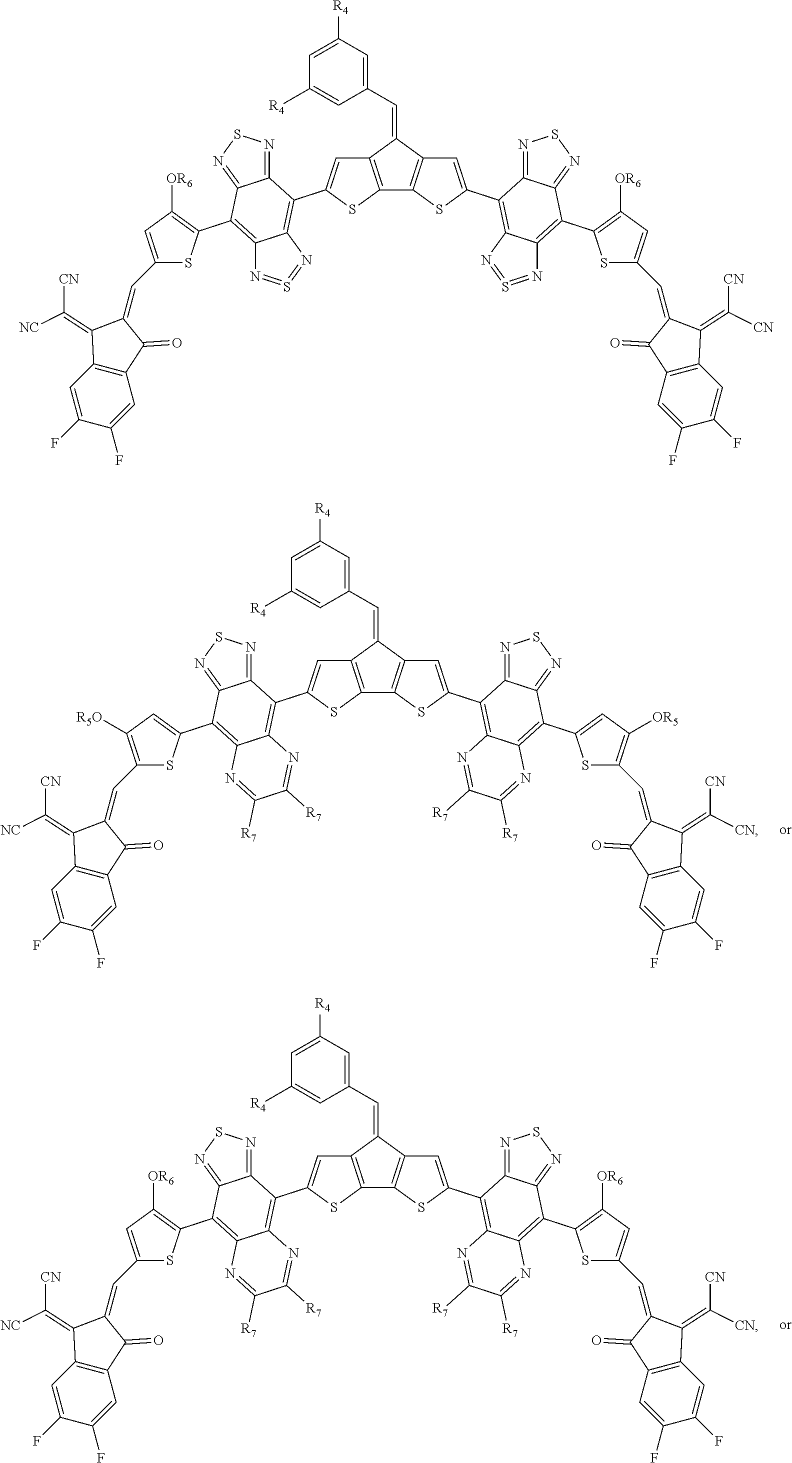 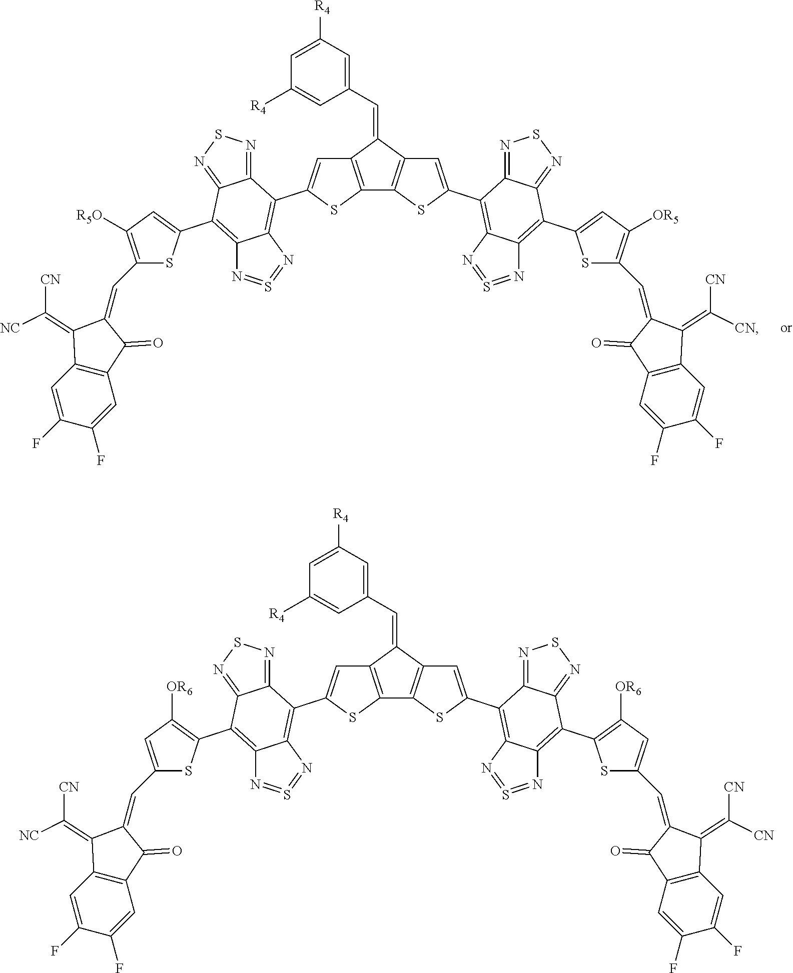
where each R₄ and R₇ is independently hydrogen or a substituted or non-substituted alkyl, aryl or alkoxy chain; and each R₅ and R₆, is independently hydrogen or a substituted or non-substituted alkyl or aryl chain.

9. The composition of matter of claim 1, further comprising an organic semiconducting donor combined with the electron acceptor.

10. The composition of matter of claim 9, wherein the organic semiconducting donor comprises:
a semiconducting compound of the structure (and isomers thereof): 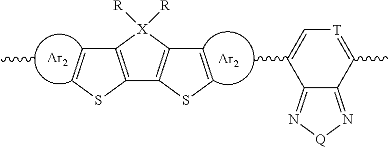
wherein:
each Ar₂ is independently a substituted or non-substituted aromatic functional group, or Ar₂ is nothing and the valence of the ring is completed with hydrogen;
each Q is independently O, S Se, or N—R₄;
each R and R₄ is independently hydrogen or a substituted or non-substituted alkyl, aryl, alkoxy or thioether chain;
T is N, C—F, or C—Cl; and
X is C, Si, Ge, N or P, or
the semiconducting compound of the structure: 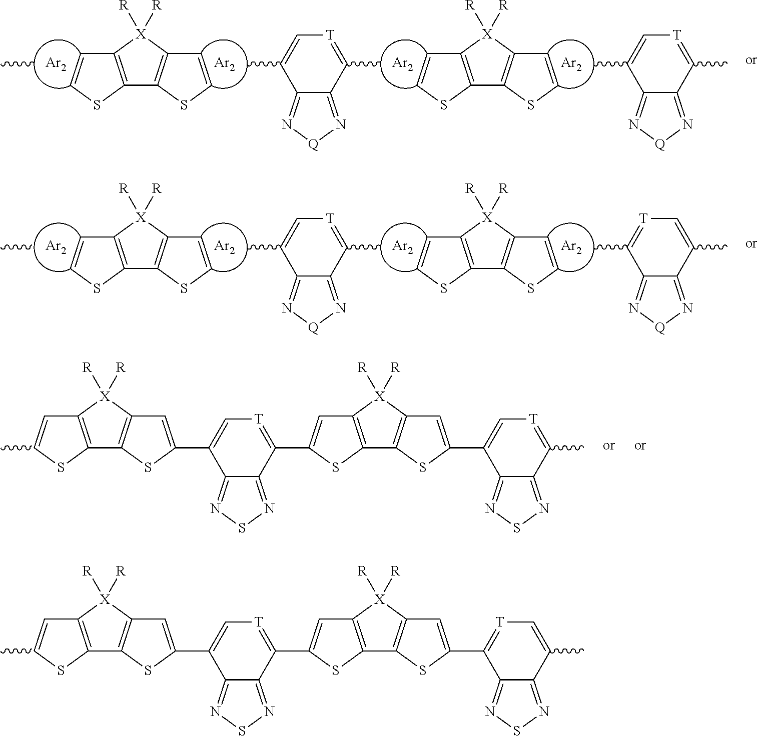
each Ar₂ is independently a substituted or non-substituted aromatic functional group, or Ar₂ is nothing and the valence of the ring is completed with hydrogen;
each Q is independently O, S Se, or N—R₄;
each R and R₄ is independently hydrogen or a substituted or non-substituted alkyl, aryl, alkoxy or thioether chain;
T is N, C—F, or C—Cl; and
X is C, Si, Ge, N or P,
or the semiconducting compound of the structure: 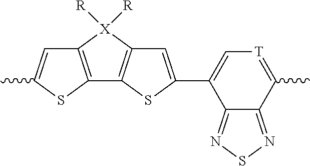
wherein:
Q is O, S, Se, N—R₄,
each R, R₄ is independently hydrogen or a substituted or non-substituted alkyl, aryl, alkoxy or thioether chain;
T is N, C—F, or C—Cl; and
X is C, Si, Ge, N or P,
or the organic semiconducting donor comprises the structure: 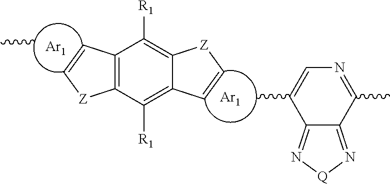
wherein:
each Ar₁ is independently a substituted or non-substituted aromatic functional group, or each Ar₁ is nothing and the valence of the ring is completed with hydrogen,
each Z is independently O, S, Se, or N—R₄;
each R₁, R₄ is independently hydrogen or a substituted or non-substituted alkyl, aryl, alkoxy or thioether chain; and
each Q is independently O, S Se, or N—R₄,
or
the organic semiconducting donor comprises the structure: 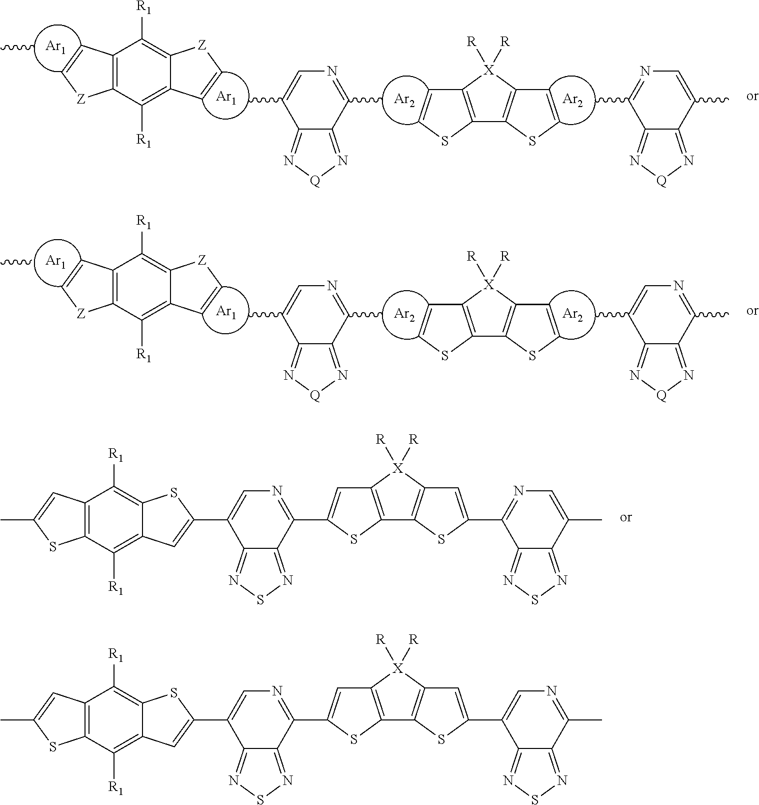
each Ar₁ and Ar₂ is independently a substituted or non-substituted aromatic functional group, or each Ar₁ and Ar2 is independently nothing and the valence of the ring is completed with hydrogen,
each Z is independently O, S, Se, or N—R₄;
each R₁, R₄ is independently hydrogen or a substituted or non-substituted alkyl, aryl, alkoxy or thioether chain; and
each Q is independently O, S Se, or N—R₄.

11. The composition of matter of claim 10, wherein the electron acceptor has a bandgap less than or equal to the bandgap of the organic semiconducting donor.

12. The composition of matter of claim 11, wherein the organic semiconducting donor comprises a semiconducting polymer.

13. The composition of matter of claim 9, wherein the organic semiconducting donor comprises a semiconducting polymer having the structure:

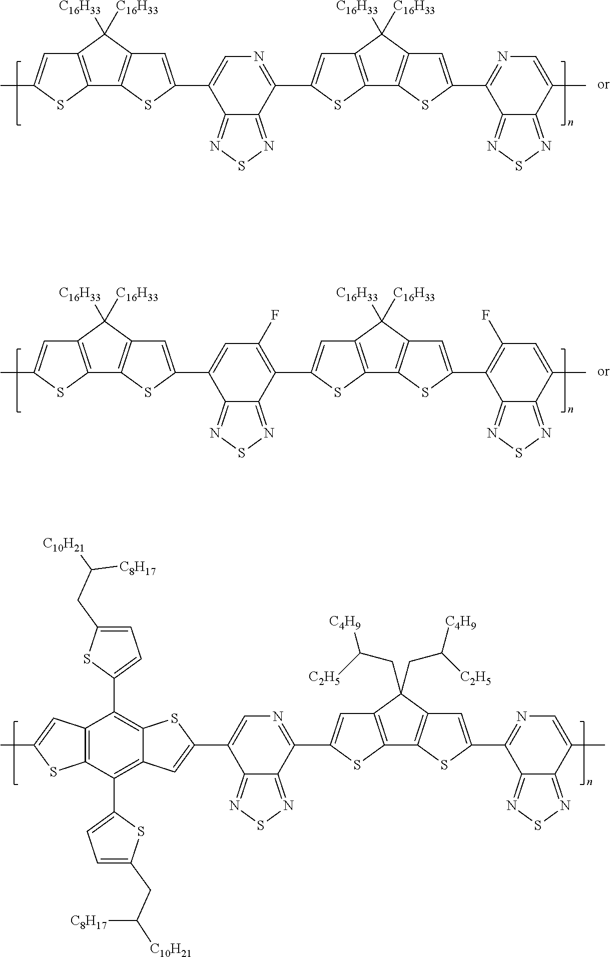

14. The composition of matter of claim 9, wherein the organic semiconducting donor comprises:

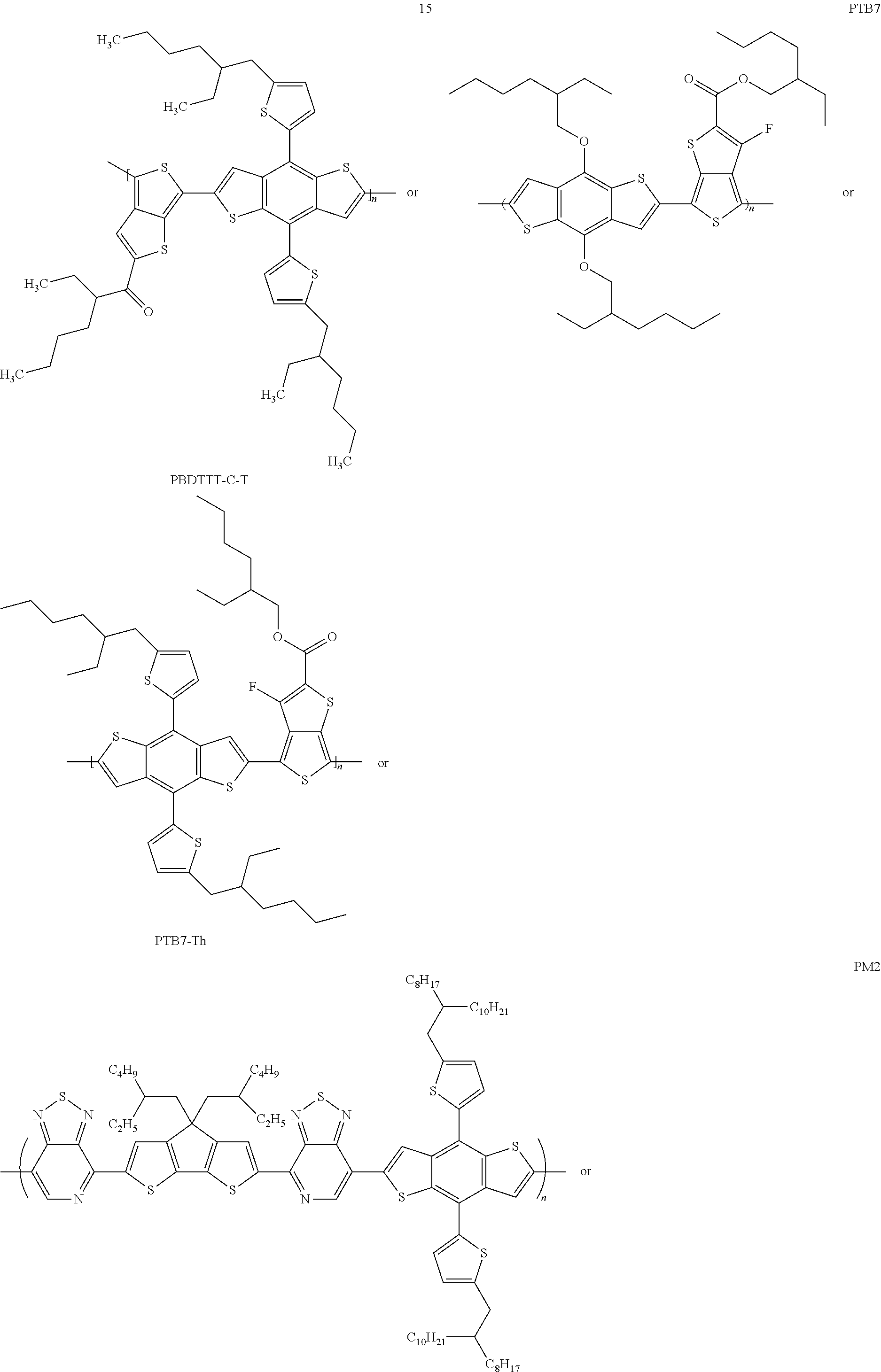

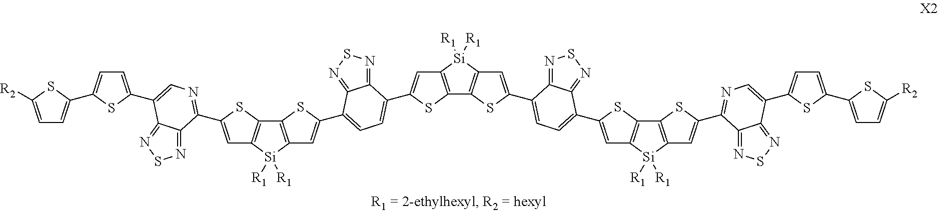

15. A film comprising the composition of matter of claim 9, having an absorptivity of at least 0.7 across the entire wavelength range of 1000-1200 nm, the electron acceptor has a bandgap less than 1.0 eV and the donor compound has a bandgap less than 1.45 eV.

16. A device comprising a heterojunction between the electron acceptor and the organic semiconducting donor compound of claim 9.

17. A photodetector or solar cell device comprising the composition of matter of claim 9, further comprising:
an active region comprising the organic semiconducting donor and the electron acceptor, wherein electron hole pairs comprising holes and electrons are generated in the active region in response to electromagnetic radiation incident on the active region, the electrons are collected in the electron acceptor and are transmitted through to a cathode, and the holes are collected in the organic donor compound and transmitted through to an anode;
the cathode coupled to the electron acceptor to receive the electrons; and
the anode coupled to the organic semiconducting donor to receive the holes; and such that
the device outputs current in response to the electromagnetic radiation.

18. The device of claim 17, wherein:
the device comprises the photodetector having an external quantum efficiency (EQE) above 2%, a responsivity of at least 0.01 A/W, and a specific detectivity of at least 10¹¹ Jones across the entire wavelength range of 800-1200 nm of the electromagnetic radiation when the anode is biased at 0V with respect to the cathode.

19. The device of any of claim 18, wherein the photodetector comprises an infrared photodetector, comprising:
a first electrode comprising the cathode;
a first carrier transport layer;
the active region comprising the composition of matter, wherein the first carrier transport layer is between the first electrode and the active region;
a second carrier transport layer, wherein the active region is between the first carrier transport layer and the second carrier transport layer; and
the second electrode comprising the anode on the second carrier transport layer.

20. An organic device, comprising:
an active region comprising the electron acceptor of claim 1, wherein the active region outputs electrical current in response to absorbing electromagnetic radiation.
